(19) United States
(12) Patent Application Publication
(10) Pub. No.: US 2010/0265981 A1
(43) Pub. Date: Oct. 21, 2010

(54) NITRIDE-BASED SEMICONDUCTOR LIGHT-EMITTING DIODE, NITRIDE-BASED SEMICONDUCTOR LASER DEVICE, METHOD OF MANUFACTURING THE SAME, AND METHOD OF FORMING NITRIDE-BASED SEMICONDUCTOR LAYER

(75) Inventors: Ryoji Hiroyama, Kyoto (JP); Yasuto Miyake, Osaka (JP); Yasumitsu Kunoh, Tottori (JP); Yasuyuki Bessho, Kyoto (JP); Masayuki Hata, Osaka (JP)

Correspondence Address: DITTHAVONG MORI & STEINER, P.C., 918 Prince Street, Alexandria, VA, 22314, US

(73) Assignee: Sanyo Electric Co., Ltd., Moriguchi-shi, Osaka (JP)

(21) Appl. No.: 12/809,770

(22) PCT Filed: Dec. 12, 2008
(86) PCT No.: PCT/JP2008/072618

§ 371 Date: Jun. 21, 2010

(30) Foreign Application Priority Data
Dec. 21, 2007 (JP) 2007-331097
Jan. 11, 2008 (JP) 2008-004168
Jan. 15, 2008 (JP) 2008-006225

(51) Int. Cl. H01S 5/323; H01L 33/30; H01L 33/00; H01L 21/20; H01L 33/10

(52) U.S. Cl. 372/49.01; 257/94; 438/42; 438/478; 438/31; 257/103; 257/E33.023; 257/E33.005; 257/E33.067; 257/E21.09

(57) ABSTRACT

A nitride-based semiconductor light-emitting diode capable of suppressing complication of a manufacturing process while improving light extraction efficiency from a light-emitting layer and further improving flatness of a semiconductor layer is obtained. This nitride-based semiconductor light-emitting diode (30) includes a substrate (11) formed with a recess portion (21) on a main surface and a nitride-based semiconductor layer (12) having a light-emitting layer (14) on the main surface and including a first side surface (12a) having a (000-1) plane formed to start from a first inner side surface (21a) of the recess portion and a second side surface (12b) formed at a region opposite to the first side surface with the light-emitting layer therebetween to start from a second inner side surface (21b) of the recess portion on the main surface.

### TECHNICAL FIELD

The present invention relates to a nitride-based semiconductor light-emitting diode, a nitride-based semiconductor laser device, a method of manufacturing the same, and a method of forming a nitride-based semiconductor layer.

### BACKGROUND ART

A light-emitting diode (LED) made of a nitride-based material such as gallium nitride is put to practical use in general. In recent years, in a light-emitting device formed on a polar face ((0001) plane) of a GaN substrate, an LED in which a light-emitting device layer is formed on a nonpolar face (m-plane (1-100) plane, a-plane (11-20) plane, etc.) of the GaN substrate or the like in the light of decrease of luminous efficiency due to an influence of a large piezoelectric field and a method of the same is proposed in Japanese Patent Laying-Open Nos. 8-64912 and 2001-24222.

A semiconductor light-emitting device (LED) having a light-emitting part constituted by a nitride-based semiconductor layer on a sapphire substrate and a method of the same are disclosed in Japanese Patent Laying-Open No. 8-64912. In the semiconductor light-emitting device described in this Japanese Patent Laying-Open No. 8-64912, a side surface ((0001) crystal plane) perpendicular to a main surface of the sapphire substrate is formed by etching in the nitride-based semiconductor layer, whereby light laterally dispersing inside the light-emitting part can be extracted also through the side surface of the nitride-based semiconductor layer.

A nitride-based semiconductor light-emitting device (LED) having a light-emitting layer constituted by a nitride-based semiconductor layer on a sapphire substrate and a method of the same are disclosed in Japanese Patent Laying-Open No. 2001-24222. In the nitride-based semiconductor light-emitting device described in this Japanese Patent Laying-Open No. 2001-24222, a plurality of recess portions are formed by etching in the nitride-based semiconductor layer, whereby light laterally dispersing inside the light-emitting device can be extracted also through side surfaces of the recess portions of the nitride-based semiconductor layer.

However, the semiconductor light-emitting devices (LED) and the methods of the same disclosed in Japanese Patent Laying-Open Nos. 8-64912 and 2001-24222 require a step of forming the side surface or the plurality of recess portions by etching the nitride-based semiconductor layer on the substrate in a manufacturing process, and hence there is such a problem that the manufacturing process is complicated. The step of forming the side surface (see Japanese Patent Laying-Open No. 8-64912) or the plurality of recess portions (see Japanese Patent Laying-Open No. 2001-24222) for extracting the light requires use of dry etching, and hence the light-emitting part (light-emitting layer) or the like is conceivably easy to be damaged. In this case, there is also such a problem that light extraction efficiency from the light-emitting layer is reduced.

Further, in each of the semiconductor light-emitting devices and the methods of the same disclosed in Japanese Patent Laying-Open Nos. 8-64912 and 2001-24222, the nitride-based semiconductor layer is crystal-grown on a flat main surface of the sapphire substrate to be formed in the manufacturing process, and hence flatness of an upper surface (main surface) of the semiconductor layer is ensured to some extent in a process of the crystal growth. However, in each of the semiconductor light-emitting devices and the methods of the same disclosed in Japanese Patent Laying-Open Nos. 8-64912 and 2001-24222, there is such a problem that it is difficult to further improve flatness of the semiconductor layer.

### DISCLOSURE OF THE INVENTION

The present invention has been proposed in order to solve the aforementioned problems, and an object of the present invention is to provide a nitride-based semiconductor light-emitting diode capable of suppressing complication of a manufacturing process while improving light extraction efficiency from a light-emitting layer and further improving flatness of a semiconductor layer.

A nitride-based semiconductor light-emitting diode according to a first aspect of the present invention comprises a substrate formed with a recess portion on a main surface and a nitride-based semiconductor layer having a light-emitting layer on the main surface and including a first side surface having a (000-1) plane formed to start from a first inner side surface of the recess portion and a second side surface formed at a region opposite to the first side surface with the light-emitting layer therebetween to start from a second inner side surface of the recess portion on the main surface.

A nitride-based semiconductor laser device according to a second aspect of the present invention comprises a nitride-based semiconductor device layer formed on a main surface of a substrate and having a light-emitting layer, a first cavity facet formed at an end of the nitride-based semiconductor device layer and a reflection surface formed at a region opposed to the first cavity facet, having a (000-1) plane or a {A+B, A, −2A−B, 2A+B} plane (A and B satisfy A≧0 and B≧0, and at least either one of A and B is a nonzero integer) extending to be inclined at a prescribed angle with respect to at least the main surface.

A method of forming a nitride-based semiconductor layer according to a third aspect of the present invention comprises steps of forming a recess portion on a main surface of a substrate and forming a nitride-based semiconductor layer having a first side surface having a (000-1) plane starting from a first inner side surface of the recess portion on the main surface.

A method of manufacturing a nitride-based semiconductor light-emitting diode according to a fourth aspect of the present invention comprises steps of forming recess portions on a main surface of a substrate and forming a nitride-based semiconductor layer on the main surface by having a light-emitting layer on the main surface and by including first side surfaces having (000-1) planes starting from first inner side surfaces of the recess portions and second side surfaces starting from second inner side surfaces of the recess portions on regions opposed to the first side surfaces on the main surface.

A method of manufacturing a nitride-based semiconductor laser device according to a fifth aspect of the present invention comprises steps of forming a first cavity facet on an end of a nitride-based semiconductor device layer formed on a main surface of and having a light-emitting layer forming a reflection surface on a region opposed to the first cavity facet, by a (000-1) plane extending to be inclined at a prescribed angle with respect to the main surface or a {A+B, A, −2A−B, 2A+B} plane (A and B satisfy A≧0 and B≧0, and at least either one of A and B is a nonzero integer) and forming a second cavity facet extending in a direction substantially perpendicular to the main surface on an end opposite to the first cavity facet.

### BRIEF DESCRIPTION OF THE DRAWINGS

FIG. 1 A sectional view for schematically illustrating a structure of a light-emitting diode chip according to the present invention.

FIG. 2 A diagram showing a range of a crystal orientation of a nitride-based semiconductor and a normal direction of a main surface of a substrate in a case of forming a nitride-based semiconductor light-emitting device through a manufacturing process of the present invention.

FIG. 3 A sectional view showing a structure of a light-emitting diode chip according to a first embodiment of the present invention.

FIG. 4 A plan view for illustrating a manufacturing process of the light-emitting diode chip according to the first embodiment shown in FIG. 3.

FIG. 5 A sectional view for illustrating the manufacturing process of the light-emitting diode chip according to the first embodiment shown in FIG. 3.

FIG. 6 A sectional view for illustrating the manufacturing process of the light-emitting diode chip according to the first embodiment shown in FIG. 3.

FIG. 7 A sectional view showing a structure of a light-emitting diode chip according to a second embodiment of the present invention.

FIG. 8 A sectional view for illustrating a manufacturing process of the light-emitting diode chip according to the second embodiment shown in FIG. 7.

FIG. 9 A plan view for illustrating the manufacturing process of the light-emitting diode chip according to the second embodiment shown in FIG. 7.

FIG. 10 A sectional view for illustrating the manufacturing process of the light-emitting diode chip according to the second embodiment shown in FIG. 7.

FIG. 11 A sectional view showing a structure of a light-emitting diode chip according to a third embodiment of the present invention.

FIG. 12 A plan view for illustrating a manufacturing process of the light-emitting diode chip according to the third embodiment shown in FIG. 11.

FIG. 13 A plan view for illustrating the manufacturing process of the light-emitting diode chip according to the third embodiment shown in FIG. 11.

FIG. 14 A sectional view showing a structure of a light-emitting diode chip according to a fourth embodiment of the present invention.

FIG. 15 A sectional view for illustrating a manufacturing process of the light-emitting diode chip according to the fourth embodiment shown in FIG. 14.

FIG. 16 A photomicrograph of a state of crystal growth of a nitride-based semiconductor layer on an n-type GaN substrate in a manufacturing process according to the fourth embodiment shown in FIG. 14, observed with a scanning electron microscope.

FIG. 17 A photomicrograph of the state of the crystal growth of the nitride-based semiconductor layer on the n-type GaN substrate in the manufacturing process according to the fourth embodiment shown in FIG. 14, observed with the scanning electron microscope.

FIG. 18 A sectional view showing a structure of a light-emitting diode chip according to a fifth embodiment of the present invention.

FIG. 19 A perspective view showing a structure of a surface emission type nitride-based semiconductor laser device according to a sixth embodiment of the present invention.

FIG. 20 A sectional view showing the structure of the surface emission type nitride-based semiconductor laser device according to the sixth embodiment shown in FIG. 19.

FIG. 21 A sectional view showing the structure of the surface emission type nitride-based semiconductor laser device according to the sixth embodiment shown in FIG. 19.

FIG. 22 A sectional view for illustrating a manufacturing process of the surface emission type nitride-based semiconductor laser device according to the sixth embodiment shown in FIG. 19.

FIG. 23 A plan view for illustrating the manufacturing process of the surface emission type nitride-based semiconductor laser device according to the sixth embodiment shown in FIG. 19.

FIG. 24 A sectional view for illustrating the manufacturing process of the surface emission type nitride-based semiconductor laser device according to the sixth embodiment shown in FIG. 19.

FIG. 25 A sectional view for illustrating the manufacturing process of the surface emission type nitride-based semiconductor laser device according to the sixth embodiment shown in FIG. 19.

FIG. 26 A sectional view showing a structure of a surface emission type nitride-based semiconductor laser device according to a seventh embodiment of the present invention.

FIG. 27 A sectional view for illustrating a manufacturing process of the surface emission type nitride-based semiconductor laser device according to the seventh embodiment shown in FIG. 26.

FIG. 28 A sectional view showing a structure of a surface emission type nitride-based semiconductor laser device according to an eighth embodiment of the present invention.

FIG. 29 A sectional view for illustrating a manufacturing process of the surface emission type nitride-based semiconductor laser device according to the eighth embodiment shown in FIG. 28.

FIG. 30 A sectional view for illustrating the manufacturing process of the surface emission type nitride-based semiconductor laser device according to the eighth embodiment shown in FIG. 28.

FIG. 31 A sectional view showing a structure of a surface emission type nitride-based semiconductor laser device according to a modification of an eighth embodiment of the present invention.

FIG. 32 A sectional view for illustrating a manufacturing process of the surface emission type nitride-based semiconductor laser device according to the modification of the eighth embodiment shown in FIG. 31.

FIG. 33 A sectional view showing a structure of a surface emission type nitride-based semiconductor laser device according to a ninth embodiment of the present invention.

FIG. 34 A sectional view for illustrating a manufacturing process of the surface emission type nitride-based semiconductor laser device according to the ninth embodiment shown in FIG. 33.

FIG. 35 A sectional view for illustrating the manufacturing process of the surface emission type nitride-based semiconductor laser device according to the ninth embodiment shown in FIG. 33.

FIG. 36 A sectional view showing a structure in which a surface emission type nitride-based semiconductor laser device according to a tenth embodiment of the present invention and a monitor PD-equipped submount are combined.

FIG. 37 A perspective view showing a structure of a surface-emitting laser array according to an eleventh embodiment of the present invention.

FIG. 38 A perspective view showing a structure of a nitride-based semiconductor laser device according to a twelfth embodiment of the present invention.

FIG. 39 A sectional view showing the structure of the nitride-based semiconductor laser device shown in FIG. 38.

FIG. 40 A sectional view for illustrating a manufacturing process of the nitride-based semiconductor laser device according to the twelfth embodiment shown in FIG. 38.

FIG. 41 A sectional view for illustrating the manufacturing process of the nitride-based semiconductor laser device according to the twelfth embodiment shown in FIG. 38.

FIG. 42 A sectional view for illustrating the manufacturing process of the nitride-based semiconductor laser device according to the twelfth embodiment shown in FIG. 38.

FIG. 43 A sectional view showing a structure of a nitride-based semiconductor laser device according to a thirteenth embodiment of the present invention.

FIG. 44 A sectional view for illustrating a manufacturing process of the nitride-based semiconductor laser device according to the thirteenth embodiment shown in FIG. 43.

FIG. 45 A plan view for illustrating a manufacturing process of a nitride-based semiconductor laser device according to a modification of the thirteenth embodiment shown in FIG. 43.

FIG. 46 A plan view for illustrating the manufacturing process of the nitride-based semiconductor laser device according to the modification of the thirteenth embodiment shown in FIG. 45.

FIG. 47 A perspective view showing a structure of a nitride-based semiconductor laser device formed by a forming method according to a fourteenth embodiment of the present invention.

FIG. 48 A sectional view taken along a cavity direction of the semiconductor laser device, for illustrating a structure of the nitride-based semiconductor laser device shown in FIG. 47.

FIG. 49 A sectional view for illustrating a manufacturing process of the nitride-based semiconductor laser device according to the fourteenth embodiment shown in FIG. 47.

FIG. 50 A sectional view for illustrating the manufacturing process of the nitride-based semiconductor laser device according to the fourteenth embodiment shown in FIG. 47.

FIG. 51 A sectional view showing a structure of a nitride-based semiconductor laser device formed by a forming method according to a fifteenth embodiment of the present invention.

FIG. 52 A sectional view for illustrating a manufacturing process of the nitride-based semiconductor laser device according to the fifteenth embodiment shown in FIG. 51.

FIG. 53 A sectional view for illustrating the manufacturing process of the nitride-based semiconductor laser device according to the fifteenth embodiment shown in FIG. 51.

FIG. 54 A sectional view showing a structure of a nitride-based semiconductor laser device formed by a forming method according to a sixteenth embodiment of the present invention.

FIG. 55 A sectional view for illustrating a manufacturing process of the nitride-based semiconductor laser device according to the sixteenth embodiment shown in FIG. 54.

FIG. 56 A sectional view showing a structure of a light-emitting diode chip formed by a forming method according to a seventeenth embodiment of the present invention.

### BEST MODES FOR CARRYING OUT THE INVENTION

Embodiments of the present invention will be hereinafter described with reference to the drawings.

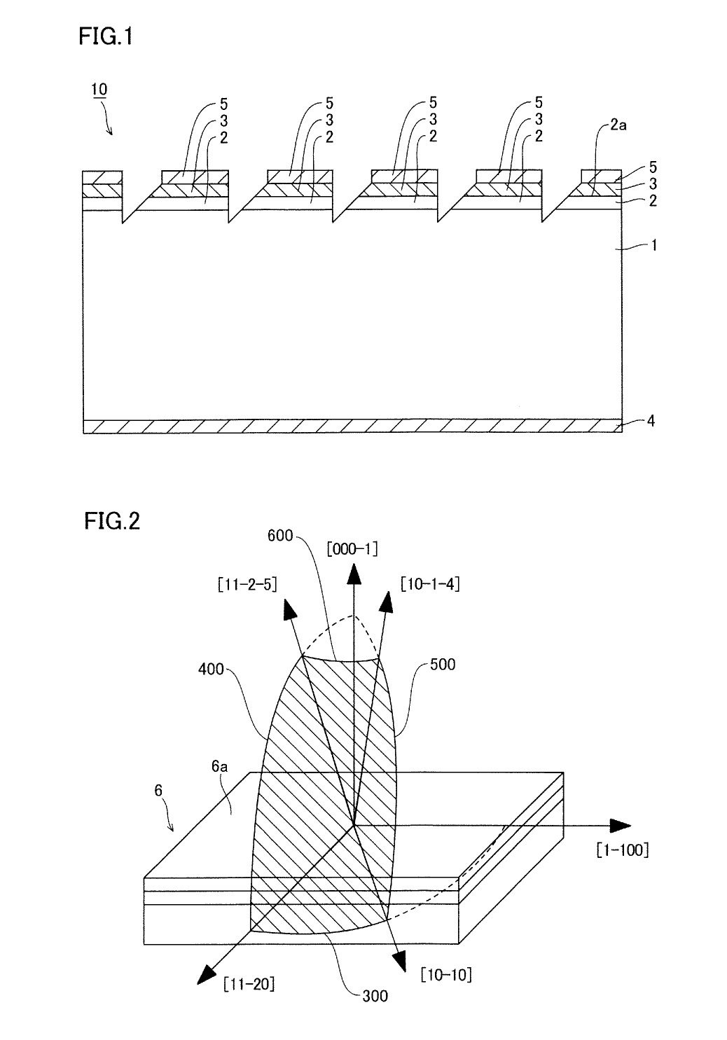

Concepts of the embodiments will be described with reference to FIG. 1 before specifically describing the embodiments of the present invention.

A nitride-based semiconductor light-emitting diode according to a first mode comprises a substrate formed with a recess portion on a main surface and a nitride-based semiconductor layer having a light-emitting layer on the main surface and including a first side surface having a (000-1) plane formed to start from a first inner side surface of the recess portion and a second side surface formed at a region opposite to the first side surface with the light-emitting layer therebetween to start from a second inner side surface of the recess portion on the main surface.

As hereinabove described, the nitride-based semiconductor light-emitting diode according to the first mode comprises the substrate formed with the recess portion on the main surface and the nitride-based semiconductor layer including the first side surface having the (000-1) plane formed to start from the first inner side surface of the recess portion and the second side surface formed to start from the second inner side surface of the recess portion on the main surface of the substrate, whereby the nitride-based semiconductor layer is formed with the first side surface and the second side surface starting from the inner side surfaces of the recess portion previously formed on the substrate. In other words, no etching is required in a manufacturing process dissimilarly to a case of forming the aforementioned first side surface or second side surface by etching the nitride-based semiconductor layer stacked on a flat substrate with no recess portion, and hence the manufacturing process of the nitride-based semiconductor light-emitting diode can be inhibited from complication. The first side surface and the second side surface of the nitride-based semiconductor layer are not formed by dry etching or the like, and hence the light-emitting layer and the like are difficult to be damaged in the manufacturing process. Thus, light extraction efficiency from the light-emitting layer can be improved.

The nitride-based semiconductor light-emitting diode comprises the substrate formed with the recess portion on the main surface and the nitride-based semiconductor layer including the first side surface having the (000-1) plane formed to start from the first inner side surface of the recess portion and the second side surface formed to start from the second inner side surface of the recess portion on the main surface of the substrate, whereby when the nitride-based semiconductor layer is crystal-grown on the substrate, growth rates of forming the first and second side surfaces starting from the first and second inner side surfaces of the recess portion are slower than a growth rate of growing an upper surface (main surface of the nitride-based semiconductor layer) of the growth layer, and hence the upper surface (main surface) of the growth layer is grown while maintaining flatness. Thus, flatness of the surface of the semiconductor layer having the light-emitting layer can be further improved as compared with surfaces of a growth layer of a nitride-based semiconductor layer with no facet formed by the aforementioned first and second side surfaces. This reason is as follows. A surface energy of a plane having a slow growth rate such as the (000-1) plane is conceivably small, whereas a surface energy of a plane having a fast growth rate such as the (1-100) plane is conceivably large. The smaller a surface energy of a surface during crystal growth is, the more the surface is stable, and hence a plane having a smaller surface energy than the (1-100) plane, other than the (1-100) plane is easy to come out when performing crystal growth by employing only the aforementioned (1-100) plane as a growth surface. Consequently, flatness of the growth surface (main surface) is easy to be destroyed. In the present invention, on the other hand, the (000-1) plane having a smaller surface energy than the (1-100) plane and the like grown as the main surface, for example is grown, and hence a surface energy of the growth surface (main surface) can be reduced as compared with a case of performing crystal growth by employing only the aforementioned (1-100) plane as a growth surface. Thus, flatness of the growth surface is conceivably improved.

In the aforementioned nitride-based semiconductor light-emitting diode according to the first mode, the first inner side surface preferably includes the (000-1) plane. According to this structure, the (000-1) plane of the nitride-based semiconductor layer is formed to start from the first inner side surface of the recess portion having the (000-1) plane when forming the nitride-based semiconductor layer having the first side surface having the (000-1) plane on the main surface of the substrate, and hence the first side surface having the (000-1) plane can be easily formed on the substrate.

In the aforementioned nitride-based semiconductor light-emitting diode according to the first mode, the first and second side surfaces preferably have crystal growth facets of the nitride-based semiconductor layer. According to this structure, two types of the facets of the aforementioned first and second side surfaces can be formed simultaneously with the crystal growth of the nitride-based semiconductor layer. The crystal growth facets include not only a facet formed by being grown in a normal direction of the facet but also a facet coming out in crystal growth.

In the aforementioned nitride-based semiconductor light-emitting diode according to the first mode, the second side surface preferably has a {A+B, A, −2A−B, 2A+B} plane (A and B satisfy A≧0 and B≧0, and at least either one of A and B is a nonzero integer). According to this structure, the surface (upper surface) of the growth layer in forming the second side surface having the {A+B, A−B, −2A, 2A+B} plane on the substrate can be reliably formed to have flatness as compared with a surface (main surface) of a growth layer of the nitride-based semiconductor layer in forming side surfaces (facets) which are not the {A+B, A, −2A−B, 2A+B} planes on the substrate. A growth rate of the {A+B, A, −2A−B, 2A+B} plane is slower than the growth rate of the main surface of the nitride-based semiconductor layer, and hence the second side surface can be easily formed by crystal growth.

In the aforementioned nitride-based semiconductor light-emitting diode according to the first mode, the substrate is preferably formed by a nitride-based semiconductor. According to this structure, the nitride-based semiconductor layer having the first side surface having the (000-1) plane and the second side surface having the {A+B, A, −2A−B, 2A+B} plane can be easily formed by utilizing crystal growth of the nitride-based semiconductor layer on the substrate made of a nitride-based semiconductor.

In the aforementioned nitride-based semiconductor light-emitting diode according to the first mode, at least either the first or second side surface preferably forms an obtuse angle with respect to the main surface. According to this structure, a region (upper region of the recess portion of the substrate) where the first and second side surfaces of the nitride-based semiconductor layer are opposed is formed to broaden from the substrate toward the upper surface of the nitride-based semiconductor layer, and hence light from the light-emitting layer can be easily extracted not only through the upper surface of the nitride-based semiconductor layer but also through the first or second side surface inclined with respect to the main surface of the substrate. Thus, luminous efficiency of the nitride-based semiconductor light-emitting diode can be further improved.

In the aforementioned nitride-based semiconductor light-emitting diode according to the first mode, the substrate preferably includes a base substrate and an underlayer made of AlGaN formed on the base substrate, and c₁ and c₂ satisfy relation of c₁>c₂, where lattice constants of the base substrate and the underlayer are c₁ and c₂ respectively, and the first and second side surfaces are formed to start from respective inner side surfaces, formed to extend substantially parallel to a (0001) plane of the underlayer and the main surface, of a crack. According to this structure, the lattice constant c₂ of the underlayer is smaller than the lattice constant c₁ of the base substrate (c₁>c₂) when the underlayer made of AlGaN is formed on the base substrate, and hence tensile stress is caused inside the underlayer in response to the lattice constant c₁ of the base substrate. Consequently, when a thickness of the underlayer is at least a prescribed thickness, the underlayer cannot withstand this tensile stress and hence the crack is formed in the underlayer. Thus, the inner side surface (first inner side surface of the recess portion) having the (000-1) plane which is the basis for forming the first side surface ((000-1) plane) of the nitride-based semiconductor layer on the underlayer can be easily formed in the underlayer.

A nitride-based semiconductor laser device according to a second mode comprises a nitride-based semiconductor device layer formed on a main surface of a substrate and having a light-emitting layer, a first cavity facet formed at an end of the nitride-based semiconductor device layer having the light-emitting layer and a reflection surface formed at a region opposed to the first cavity facet, having a (000-1) plane or a {A+B, A, −2A−B, 2A+B} plane (A and B satisfy A≧0 and B≧0, and at least either one of A and B is a nonzero integer) extending to be inclined at a prescribed angle with respect to at least the main surface.

As hereinabove described, the nitride-based semiconductor laser device according to the second mode comprises the reflection surface formed at the region opposed to the first cavity facet, having the (000-1) plane or the {A+B, A, −2A−B, 2A+B} plane extending to be inclined at the prescribed angle with respect to at least the main surface, whereby a reflection facet having the aforementioned plain orientation has flatness so that a laser beam emitted from the first cavity facet can be emitted outside by uniformly changing an emission direction without scattering by the reflection surface 100c. Therefore, reduction in luminous efficiency of the semiconductor laser device can be suppressed.

In the aforementioned nitride-based semiconductor laser device according to the second mode, the substrate preferably has a recess portion formed on the main surface, and the reflection surface preferably has a crystal growth facet of the nitride-based semiconductor device layer formed to start from an inner side surface of the recess portion. According to this structure, when the nitride-based semiconductor device layer is crystal-grown on the substrate, a growth rate of forming the reflection surface having a facet starting from the inner side surface of the recess portion is slower than a growth rate of growing an upper surface (main surface of the nitride-based semiconductor device layer) of the growth layer, and hence the upper surface (main surface) of the growth layer is grown while maintaining flatness. Thus, flatness of the surface (main surface) of the semiconductor layer having the light-emitting layer can be further improved as compared with surfaces of a growth layer of a nitride-based semiconductor device layer with no recess portion previously formed on the substrate.

The aforementioned nitride-based semiconductor laser device according to the second mode preferably further comprises a second cavity facet formed at an end opposite to the first cavity facet and extending in a direction substantially perpendicular to the main surface. According to this structure, the nitride-based semiconductor device layer having the first cavity facet and the second cavity facet opposite to the first cavity facet as a pair of the cavity facets can be formed.

In the aforementioned nitride-based semiconductor laser device according to the second mode, the substrate is preferably formed by a nitride-based semiconductor. According to this structure, the nitride-based semiconductor device layer having the first cavity facet having the (000-1) plane or the {A+B, A, −2A−B, 2A+B} plane can be easily formed by utilizing crystal growth of the nitride-based semiconductor device layer on the substrate made of a nitride-based semiconductor.

In the aforementioned nitride-based semiconductor laser device according to the second mode, a laser beam emitted from the first cavity facet is preferably introduced into an optical sensor for a monitor of the laser beam by changing an emission direction to a direction intersecting with an emission direction of the laser beam from the light-emitting layer, by the reflection surface. According to this structure, the laser beam (sample light monitoring a laser beam intensity of a facet emission laser device) where light scattering is suppressed by the reflection surface having excellent flatness due to a facet formed in crystal growth can be guided to an optical sensor, and hence the laser beam intensity can be more precisely measured.

In the aforementioned nitride-based semiconductor laser device according to the second mode, being a surface emission type laser, an emission direction of a laser beam emitted from the first cavity facet is changed to a direction intersecting with an emission direction of the laser beam from the light-emitting layer, by the reflection surface. According to this structure, the laser beam where light scattering is suppressed by the reflection surface having excellent flatness due to a facet formed in crystal growth can be emitted, and hence the surface emission type laser having improved luminous efficiency can be formed.

A method of forming a nitride-based semiconductor layer according to a third mode comprises steps of forming a recess portion on a main surface of a substrate and forming a nitride-based semiconductor layer having a first side surface having a (000-1) plane starting from a first inner side surface of the recess portion on the main surface.

As hereinabove described, the method of forming the nitride-based semiconductor layer according to the third mode comprises the steps of forming the recess portion on the main surface of the substrate and forming the nitride-based semiconductor layer having the first side surface having the (000-1) plane starting from the first inner side surface of the recess portion, whereby when the nitride-based semiconductor layer is crystal-grown on the substrate, a growth rate of forming the (000-1) plane starting from the first inner side surface of the recess portion is slower than a growth rate of growing an upper surface (main surface of the nitride-based semiconductor layer) of the growth layer, and hence the upper surface (main surface) of the growth layer is grown while maintaining flatness. Thus, flatness of the surface of the semiconductor layer having the light-emitting layer can be further improved as compared with surfaces of a growth layer of a nitride-based semiconductor layer with no (000-1) facet. Further, the method of forming the nitride-based semiconductor layer according to the third mode comprises the step of forming the nitride-based semiconductor layer having the first side surface having the (000-1) plane starting from the first inner side surface of the recess portion, whereby not only the upper surface of the growth layer but also the first side surface can be formed as flat facets having the (000-1) planes. Therefore, the nitride-based semiconductor layer (light-emitting layer) having cavity facets having the (000-1) planes can be formed with no cleavage step by applying the method of forming a nitride-base semiconductor layer of this invention to a method of forming a semiconductor laser device.

The facets of the (000-1) planes in the structure of pairs of the cavity facets (combination of the (0001) and (000-1) planes) extending in a direction perpendicular to a [0001] direction can be easily formed by utilizing crystal growth of the nitride-based semiconductor layer when gains of the semiconductor laser is improved by forming optical waveguides along the [0001] direction of the nitride-based semiconductor layer, by applying the aforementioned forming method according to the third mode to a case where a laser device layer made of a nitride-based semiconductor layer is formed on a substrate having a main surface of an m-plane ((1-100) plane) or an a-plane ((11-20) plane).

In the aforementioned method of forming the nitride-based semiconductor layer according to the third mode, the step of forming the nitride-based semiconductor layer preferably includes a step of forming the nitride-based semiconductor layer having a second side surface starting from a second inner side surface of the recess portion on a region opposed to the first side surface. According to this structure, when the nitride-based semiconductor layer is crystal-grown on the substrate, a growth rate of forming the second side surfaces starting from the second inner side surface of the recess portion is slower than a growth rate of growing an upper surface (main surface of the nitride-based semiconductor layer) of the growth layer, and hence the upper surface (main surface) of the growth layer is grown while maintaining flatness. Thus, flatness of the surface of the semiconductor layer having the light-emitting layer can be further improved as compared with surfaces of a growth layer of a nitride-based semiconductor layer with no aforementioned first and second side surfaces. Further, not only the surface (upper surface) of the growth layer but also the second side surface can be formed as facets having flatness, and hence the nitride-based semiconductor layer (light-emitting layer) having a cavity facet having the second side surface can be formed with no cleavage step.

In the aforementioned structure including the step of forming the nitride-based semiconductor layer having the second side surface on the region opposed to the first side surface, the first inner side surface of the recess portion preferably includes the (000-1) plane. According to this structure, the (000-1) plane of the semiconductor layer is formed to start from the first inner side surface of the recess portion having the (000-1) plane when forming the nitride-based semiconductor layer having the first side surface having the (000-1) plane on the main surface of the substrate, and hence the first side surface having the (000-1) plane can be easily formed on the substrate.

In the aforementioned structure including the step of forming the nitride-based semiconductor layer having the second side surface on the region opposed to the first side surface, the first and second side surfaces preferably have crystal growth facets of the nitride-based semiconductor layer. According to this structure, two types of the facets of the aforementioned first and second side surfaces can be formed simultaneously with the crystal growth of the nitride-based semiconductor layer.

In the aforementioned structure including the step of forming the nitride-based semiconductor layer having the second side surface on the region opposed to the first side surface, the second side surface preferably has a {A+B, A, −2A−B, 2A+B} plane (A and B satisfy A≧0 and B≧0, and at least either one of A and B is a nonzero integer). According to this structure, the surface (upper surface) of the growth layer in forming the second side surface having the {A+B, A, −2A−B, 2A+B} plane on the substrate can be reliably formed to have flatness as compared with a surface (main surface) of a growth layer of the nitride-based semiconductor layer in forming side surfaces (facets) which are not the {A+B, A, −2A−B, 2A+B} planes on the substrate. A growth rate of the {A+B, A, −2A−B, 2A+B} plane is slower than the growth rate of the main surface of the nitride-based semiconductor layer, and hence the second side surface can be easily formed by crystal growth.

In the aforementioned method of forming the nitride-based semiconductor layer according to the third mode, the substrate is preferably formed by a nitride-based semiconductor. According to this structure, the nitride-based semiconductor layer having the first side surface having the (000-1) plane and the second side surface having the {A+B, A, −2A−B, 2A+B} plane can be easily formed by utilizing crystal growth of the nitride-based semiconductor layer on the substrate made of a nitride-based semiconductor.

In the aforementioned structure including the step of forming the nitride-based semiconductor layer having the second side surface on the region opposed to the first side surface, either the first or second side surface is preferably substantially perpendicular to the main surface. According to this structure, the nitride-based semiconductor layer (light-emitting layer) having a cavity facet having either the first or second side surface can be easily formed with no cleavage step.

In the aforementioned structure including the step of forming the nitride-based semiconductor layer having the second side surface on the region opposed to the first side surface, at least either the first or second side surface preferably forms an obtuse angle with respect to a main surface of the nitride-based semiconductor layer. According to this structure, the nitride-based semiconductor layer having flatness can be easily formed when the nitride-based semiconductor layer is crystal-grown on the substrate.

In the aforementioned method of forming the nitride-based semiconductor layer according to the third mode, the substrate preferably includes a base substrate and an underlayer made of AlGaN formed on the base substrate, and c₁ and c₂ satisfy relation of c₁>c₂, where lattice constants of the base substrate and the underlayer are c₁ and c₂ respectively. According to this structure, the lattice constant c₂ of the underlayer is smaller than the lattice constant c₁ of the base substrate (c₁>c₂) when the underlayer made of AlGaN is formed on the base substrate, and hence tensile stress is caused inside the underlayer in response to the lattice constant c₁ of the base substrate. Consequently, when a thickness of the underlayer is at least a prescribed thickness, the underlayer cannot withstand this tensile stress and hence the crack is formed along the (000-1) plane on the underlayer. Thus, the inner side surface (first inner side surface of the recess portion) having the (000-1) plane which is the basis for forming the first side surface ((000-1) plane) of the nitride-based semiconductor layer on the underlayer can be easily formed in the underlayer.

A method of manufacturing a nitride-based semiconductor light-emitting diode according to a fourth mode comprises steps of forming recess portions on a main surface of a substrate and forming a nitride-based semiconductor layer on the main surface by having a light-emitting layer on the main surface and by including first side surfaces having (000-1) planes starting from first inner side surfaces of the recess portions and second side surfaces starting from second inner side surfaces of the recess portions on regions opposed to the first side surfaces on the main surface.

The method of manufacturing the nitride-based semiconductor light-emitting diode according to the fourth mode comprises the steps of forming the recess portions on the main surface of the substrate and forming the nitride-based semiconductor layer on the main surface by including the first side surfaces having the (000-1) planes starting from the first inner side surfaces of the recess portions and the second side surfaces starting from the second inner side surfaces of the recess portions on the main surface, whereby the nitride-based semiconductor layer is formed with the first side surfaces and the second side surfaces starting from the inner side surfaces of the recess portion previously formed on the substrate. In other words, no etching is required in a manufacturing process dissimilarly to a case of forming the aforementioned first side surfaces or second side surfaces by etching the nitride-based semiconductor layer stacked on a flat substrate with no recess portion, and hence the manufacturing process of the nitride-based semiconductor light-emitting diode can be inhibited from complication. The first side surfaces and the second side surfaces of the nitride-based semiconductor layer are not formed by dry etching or the like, and hence the light-emitting layer and the like are difficult to be damaged in the manufacturing process. Thus, light extraction efficiency from the light-emitting layer can be improved.

Further, the method of manufacturing the nitride-based semiconductor light-emitting diode according to the fourth mode comprises the steps of forming the recess portions on the main surface of the substrate and forming the nitride-based semiconductor layer on the main surface by including the first side surfaces having the (000-1) planes starting from the first inner side surfaces of the recess portions and the second side surfaces starting from the second inner side surfaces of the recess portions on the main surface, whereby growth rates of forming the first and second side surfaces starting from the first and second inner side surfaces of the recess portion are slower than a growth rate of growing an upper surface (main surface of the nitride-based semiconductor layer) of the growth layer, and hence the upper surface (main surface) of the growth layer is grown while maintaining flatness. Thus, flatness of the surface of the semiconductor layer having the light-emitting layer can be further improved as compared with surfaces of a growth layer of a nitride-based semiconductor layer with no facet having the aforementioned first and second side surfaces.

A method of manufacturing a nitride-based semiconductor laser device according to a fifth mode comprises steps of forming a first cavity facet on an end of a nitride-based semiconductor device layer formed on a main surface and having a light-emitting layer, forming a reflection surface on a region opposed to the first cavity facet, by a (000-1) plane extending to be inclined at a prescribed angle with respect to the main surface or a {A+B, A, −2A−B, 2A+B} plane (A and B satisfy A≧0 and B≧0, and at least either one of A and B is a nonzero integer), and forming a second cavity facet extending in a direction substantially perpendicular to the main surface on an end opposite to the first cavity facet.

As hereinabove described, the method of manufacturing the nitride-based semiconductor laser device according to the fifth mode comprises the steps of forming the first cavity facet on the end of the nitride-based semiconductor device layer having the light-emitting layer and forming the reflection surface on the region opposed to the first cavity facet, by the (000-1) plane extending to be inclined at the prescribed angle with respect to the main surface or the {A+B, A, −2A−B, 2A+B} plane, whereby excellent flatness is obtained in a reflection facet having the aforementioned plain orientation dissimilarly to a case of forming a inclined reflection surface having small unevenness by ion beam etching, for example. Thus, a laser beam emitted from the first cavity facet can be emitted outside by uniformly changing an emission direction without scattering by the reflection surface so that the semiconductor laser device in which reduction in luminous efficiency is suppressed can be formed. Further, the reflection surface inclined with respect to the first cavity facet is formed in simultaneously the crystal growth of the nitride-based semiconductor device layer so that a manufacturing process of the semiconductor laser device can be inhibited from complication dissimilarly to a case of growing a flat semiconductor device layer on the substrate and thereafter forming the reflection facet inclined at a prescribed angle with respect to a cavity facet (light-emitting surface side, for example) by ion beam etching or the like, for example.

In the aforementioned method of manufacturing the nitride-based semiconductor laser device according to the fifth mode, the step of forming the first cavity facet and the step of forming the second cavity facet preferably include a step of forming at least either the first cavity facet or the second cavity facet by crystal growth of the nitride-based semiconductor device layer and a step of forming at least either the second cavity facet or the first cavity facet by etching. According to this structure, a facet of the nitride-based semiconductor device layer can be formed by crystal growth and a facet of the nitride-based semiconductor device layer can be formed by etching so that the cavity facet (first cavity facet or second cavity facet) can be easily formed at an end of a region including the light-emitting layer of the nitride-based semiconductor device layer formed on a substrate with poor cleavage such as a GaN substrate. Further, the cavity facet (first cavity facet or second cavity facet) extending in a direction substantially perpendicular to the main surface can be easily formed by controlling crystal growth and etching conditions.

A structure of a light-emitting diode chip 10, which is an example of a nitride-based semiconductor light-emitting device of the present invention, will be now schematically described.

The light-emitting diode chip 10 is formed with a light-emitting layer 2 on a first semiconductor 1, as shown in FIG. 1. A second semiconductor 3 is formed on the light-emitting layer 2. A first electrode 4 is formed on a lower surface of the first semiconductor 1, and a second electrode 5 is formed on the second semiconductor 3. The first semiconductor 1 is examples of the “substrate” and the “nitride-based semiconductor layer” in the present invention, and the light-emitting layer 2 and the second semiconductor 3 are each an example of the “nitride-based semiconductor layer” in the present invention.

In general, the light-emitting layer 2 having a band gap smaller than band gaps of the first and second semiconductors 1 and 3 is formed between the first and second semiconductors 1 and 3 for forming a double hetero structure, so that carriers can be likely to be confined in the light-emitting layer 2 and luminous efficiency of the light-emitting diode chip 10 can be improved. The light-emitting layer 2 is formed to have a single quantum well (SQW) structure or a multiple quantum well (MQW) structure, whereby luminous efficiency can be further improved. In the case of these quantum well structures, a thickness of a well layer is small, and hence deterioration of crystallinity of the well layer can be suppressed also when the well layer has strain. Deterioration of crystallinity is suppressed also when the well layer has compressive strain in the in-plane directions of a main surface 2a of the light-emitting layer 2 or has tensile strain in the in-plane directions thereof. The light-emitting layer 2 may be undoped or doped.

In the present invention, the first semiconductor 1 may be formed by a substrate or a semiconductor layer, or may be formed by both of the substrate and the semiconductor layer. When the first semiconductor 1 is formed by both of the substrate and the semiconductor layer, the substrate is formed on a side of the first semiconductor 1 opposite to a side formed with the second semiconductor 3 (lower side of the first semiconductor 1). The substrate may be formed by a growth substrate or may be employed as a support substrate for supporting the semiconductor layer on a growth surface (main surface) of the semiconductor layer after growing the semiconductor layer.

A GaN substrate or an α-SiC substrate can be employed as the substrate. A nitride-based semiconductor layer having the same main surface as the substrate is formed on the GaN substrate and the α-SiC substrate. For example, nitride-based semiconductor layers having main surfaces having an a-plane and an m-plane are formed on the a-plane and the m-plane of the α-SiC substrate, respectively. An r-plane sapphire substrate formed with a nitride-based semiconductor having a main surface having the a-plane may be employed as the substrate. A LiAlO₂ substrate or a LiGaO₂ substrate formed with the nitride-based semiconductor layers having the main surfaces having the a-plane and the m-plane can be employed as the substrate.

In the p-n junction light-emitting diode chip 10, the first and second semiconductors 1 and 3 have different conductivity types. The first semiconductor 1 may be the p-type and the second semiconductor 3 may be the n-type, or the first semiconductor 1 may be the n-type and the second semiconductor 3 may be the p-type.

The first and second semiconductors 1 and 3 may include cladding layers having band gaps larger than that of the light-emitting layer 2. Further, each of the first and second semiconductors 1 and 3 may include a cladding layer and a contact layer successively from the light-emitting layer 2. In this case, the contact layer preferably has a smaller band gap than the cladding layer.

In the light-emitting layer 2 of the quantum well, GaInN can be employed as a well layer, and AlGaN, GaN and GaInN having band gaps larger than that of the well layer can be employed as the barrier layer. GaN and AlGaN can be employed as the cladding layer and the contact layer.

The second electrode 5 may be formed on a part of a region on the second semiconductor 3. In a case where the light-emitting diode chip 10 is a light-emitting diode, an electrode formed on a light-emission side (upper side) (second electrode 5, in this case) preferably has translucence.

A plain orientation of a substrate in forming a nitride-based semiconductor light-emitting device by a manufacturing process of the present invention will be now described with reference to FIG. 2.

As shown in FIG. 2, a normal direction of a main surface 6a of a substrate 6 is in an area (region hatched by slant lines) enclosed with a line 600 connecting a [11-20] direction and a substantially [10-10] direction ([C+D, C, −2C−D, 0] direction (C and D satisfy C≧0 and D≧0, and at least either one of C and D is a nonzero integer)), a line 700 connecting the [11-20] direction and a substantially [11-2-5] direction ([1, 1, −2, −E] direction (0≦E≦5c)), a line 800 connecting a [10-10] direction and a substantially [10-1-4] direction ([1, −1, 0, −F] direction (0≦F≦4)), and a line 900 connecting a substantially [11-2-5] direction and a substantially [10-1-4] direction ([G+H, G, −2G−H, −5G−4H] direction (G and H satisfy G≧0 and H≧0, and at least either one of G and H is a nonzero integer)).

Embodiments of the present invention will be hereinafter described with reference to the drawings.

### First Embodiment

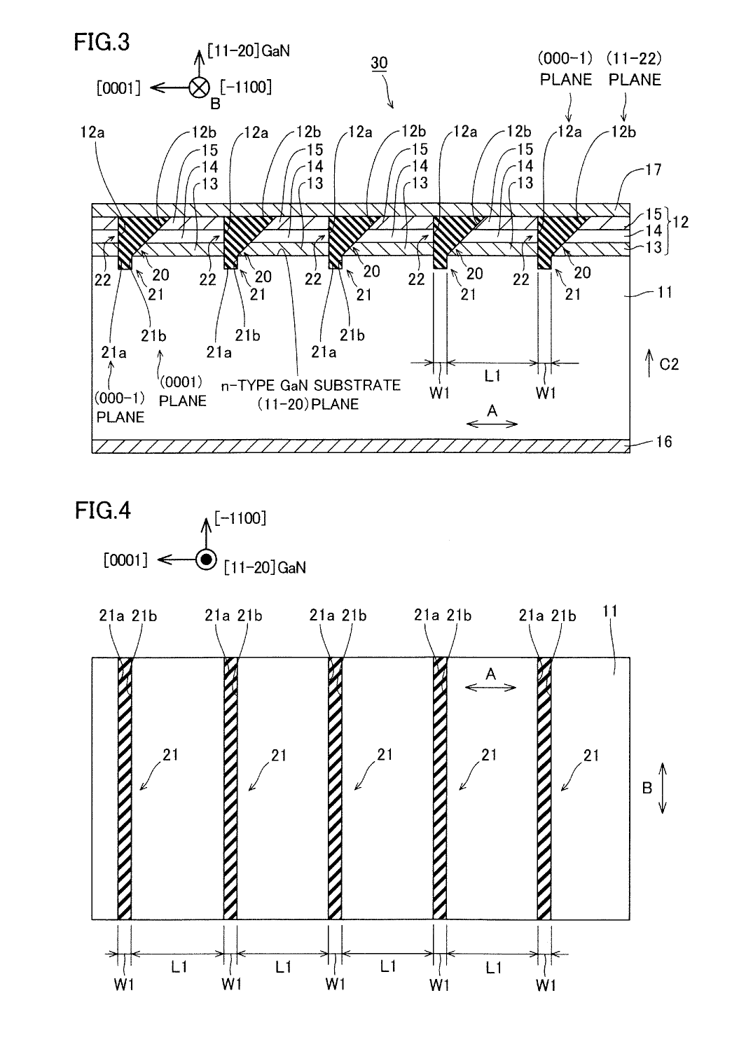

A structure of a light-emitting diode chip 30 according to a first embodiment will be now described with reference to FIG. 3.

The light-emitting diode chip 30 according to the first embodiment is constituted by a wurtzite structure nitride-based semiconductor having an a-plane ((11-20) plane) as a main surface. The shape of the light-emitting diode chip 30 is a square shape, a rectangular shape, a rhombus shape, a parallelogram shape or the like in plan view (as viewed from an upper side of the light-emitting diode chip 30).

As shown in FIG. 3, in the light-emitting diode chip 30, a light-emitting device layer 12 is formed on an n-type GaN substrate 11 having a thickness of about 100 μm. A light-emitting layer 14 consisting of an MQW structure formed by stacking an n-type cladding layer 13 made of n-type Al_{0.03}Ga_{0.97}N having a thickness of about 0.5 μm, a well layer of Ga_{0.7}In_{0.3}N having a thickness of about 2 nm and a barrier layer made of Ga_{0.9}In_{0.1}N is formed in the light-emitting device layer 12. A p-type cladding layer 15 doubling as a p-type contact layer made of p-type GaN having a thickness of about 0.2 μm is formed on the light-emitting layer 14. The n-type GaN substrate 11 is an example of the “substrate” in the present invention, and the light-emitting device layer 12, the n-type cladding layer 13, the light-emitting layer 14 and the p-type cladding layer 15 are each an example of the “nitride-based semiconductor layer” in the present invention.

According to the first embodiment, recess portions 20 are formed from the n-type cladding layer 13 to the p-type cladding layer 15 and have facets 12a formed in crystal growth and having (000-1) planes, of the light-emitting device layer 12 and facets 12b formed in crystal growth and having (11-22) planes, of the light-emitting device layer 12. The facet 12a is examples of the “first side surface” and the “crystal growth facet” in the present invention, and the facet 12b is examples of the “second side surface” and the “crystal growth facet” in the present invention. The facets 12a are formed to extend in a direction ([11-20] direction) substantially perpendicular to a main surface of the n-type GaN substrate 11 so as to start from inner side surfaces 21a having (000-1) planes of grooves 21 previously formed on the main surface of the n-type GaN substrate 11 in a manufacturing process described later. The facets 12b have inclined planes starting from inner side surfaces 21b of the grooves 21, and form obtuse angles with respect to an upper surface (main surface) of the light-emitting device layer 12. The groove 21 and the inner side surface 21a are examples of the “recess portion” and the “first inner side surface of the recess portion” in the present invention, respectively. In FIG. 3, only some of the grooves 21 are denoted by reference characters of the inner side surfaces 21a and 21b in the drawing because of illustration.

An n-side electrode 16 is formed on a lower surface of the n-type GaN substrate 11. The recess portions 20 are formed with insulating films 22 of SiO₂ transparent for an emission wavelength and also formed with a translucent p-side electrode 17 to cover the insulating films 22 and the p-type cladding layer 15.

The manufacturing process of the light-emitting diode chip 30 according to the first embodiment will be now described with reference to FIGS. 3 to 6.

A plurality of the grooves 21 having a width W1 of about 5 μm in a [0001] direction (direction A) and a depth of about 2 μm and extending in a [1-100] direction (direction B) are formed on the main surface, having the a-plane ((11-20) plane), of the n-type GaN substrate 11 using an etching technique as shown in FIG. 4. In FIG. 4, areas with bold diagonal lines are etched regions of the grooves 21. The grooves 21 are formed in a striped manner in the direction A in a period of about 50 μm (=W1+L1 (L1=about 45 μm).

In the manufacturing process of the first embodiment, each groove 21 is formed with the inner side surface 21a having the (000-1) plane substantially perpendicular to the (11-20) plane of the n-type GaN substrate 11 and the inner side surface 21b having the (0001) plane substantially perpendicular to the (11-20) plane of the n-type GaN substrate 11. The inner side surface 21b is an example of the “second inner side surface of the recess portion” in the present invention.

The n-type cladding layer 13, the light-emitting layer 14 and the p-type cladding layer 15 are successively stacked on the n-type GaN substrate 11 having the grooves 21 by metalorganic chemical vapor deposition (MOCVD), thereby forming the light-emitting device layer 12.

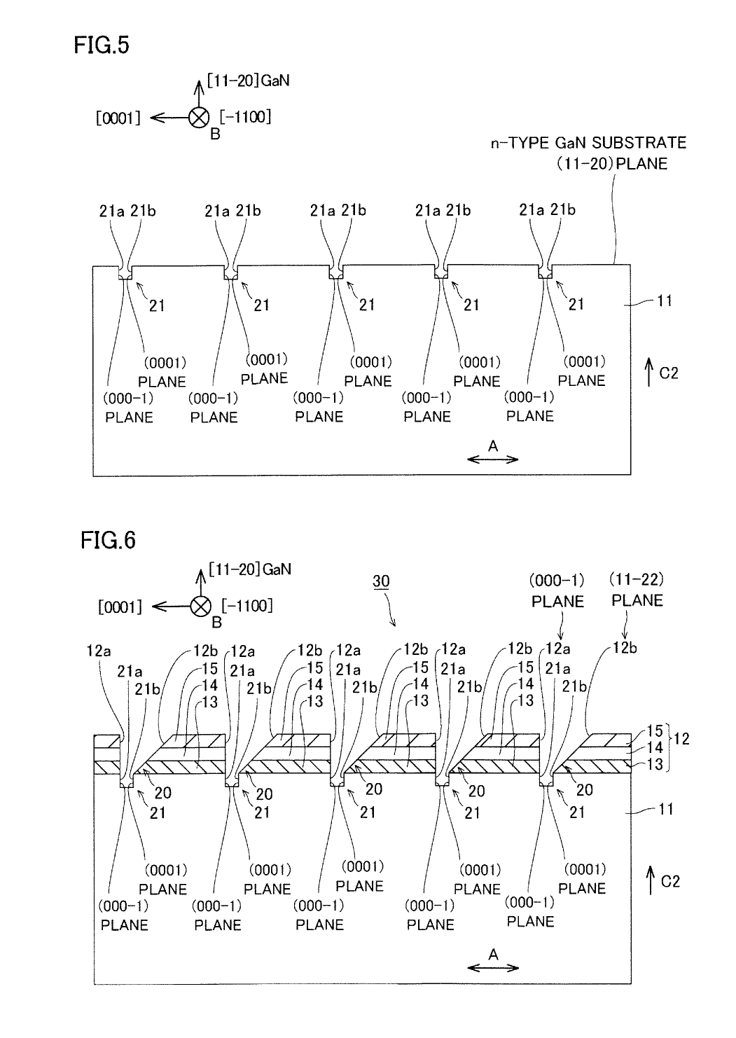

According to the first embodiment, when the light-emitting device layer 12 is grown on the n-type GaN substrate 11, the light-emitting device layer 12 is crystal-grown on the inner side surfaces 21a having the (000-1) planes of the grooves 21 extending in the [1-100] direction, while forming the (000-1) facets 12a extending in the [11-20] direction (along arrow C2) to start from the (000-1) planes of the grooves 21, as shown in FIG. 6. On the (0001) plane (inner side surface 21b) opposed to the (000-1) planes of the grooves 21, the light-emitting device layer 12 is crystal-grown while forming the (11-22) facets 12b extending in a direction inclined at a prescribed angle with respect to the [11-20] direction (along arrow C2). Thus, the facets 12b form the obtuse angles with respect to the upper surface (main surface) of the light-emitting device layer 12.

As shown in FIG. 3, the insulating films 22 are formed to fill up the recess portions 20 (regions above the grooves 21 including the grooves 21) held between the (000-1) facets 12a and the (11-22) facets 12b of the light-emitting device layer 12. Then, the p-side electrode 17 is formed on the upper surfaces of the insulating films 22 and the light-emitting device layer 12, and the n-side electrode 16 is formed on the lower surface of the n-type GaN substrate 11. Thus, the light-emitting diode chip 30 according to the first embodiment shown in FIG. 3 is formed.

According to the first embodiment, as hereinabove described, the light-emitting diode 30 comprises the light-emitting device layer 12 including the n-type GaN substrate 11 formed with the grooves 21 on the main surface, the (000-1) facets 12a formed to start from the inner side surfaces 21a of the grooves 21 on the main surface of the n-type GaN substrate 11 and the facets 12b formed to start from the inner side surfaces 21b of the grooves 21, whereby the light-emitting device layer 12 is formed with the facets 12a and 12b starting from the inner side surfaces 21a and 21b of the grooves 21 previously formed on the n-type GaN substrate 11. In other words, no etching is required in the manufacturing process dissimilarly to a case of forming the aforementioned facets 12a or 12b by etching the nitride-based semiconductor layer stacked on a flat substrate with no recess portion, and hence the manufacturing process of the light-emitting diode 30 can be inhibited from complication. The facets 12a and 12b of the light-emitting device layer 12 are not formed by dry etching or the like, and hence the light-emitting layer 14 and the like are difficult to be damaged in the manufacturing process. Thus, light extraction efficiency from the light-emitting layer 14 can be improved.

According to the first embodiment, the light-emitting diode 30 comprises the light-emitting device layer 12 including the n-type GaN substrate 11 formed with the grooves 21 on the main surface, the (000-1) facets 12a formed to start from the inner side surfaces 21a of the grooves 21 on the main surface of the n-type GaN substrate 11 and the facets 12b formed to start from the inner side surfaces 21b of the grooves 21, whereby when the light-emitting device layer 12 is crystal-grown on the n-type GaN substrate 11, growth rates of forming the facets 12a and 12b starting from the inner side surface 21a and 21b of the grooves 21 are slower than a growth rate of growing the upper surface (main surface of the light-emitting device layer 12) of the growth layer, and hence the upper surface (main surface) of the growth layer is grown while maintaining flatness. Thus, flatness of the surface (upper surface) of the light-emitting device layer 12 having the light-emitting layer 14 can be further improved as compared with surfaces of a growth layer of a light-emitting device layer with no facet having the aforementioned facets 12a and 12b.

According to the first embodiment, the inner side surfaces 21a of the grooves 21 have the (000-1) planes, whereby the (000-1) plane of the light-emitting device layer 12 is formed to start from the (000-1) planes of the inner side surfaces 21a of the grooves 21 when forming the light-emitting device layer 12 having the (000-1) facets 12a on the main surface of the n-type GaN substrate 11, and hence the (000-1) facets 12a can be easily formed on the n-type GaN substrate 11.

According to the first embodiment, the facets 12a and 12b of the light-emitting device layer 12 have facets formed in crystal growth, of the light-emitting device layer 12, whereby two types of the facets of the aforementioned facets 12a and 12b can be formed simultaneously with the crystal growth of the light-emitting device layer 12.

According to the first embodiment, the facets 12b have the (11-22) planes, whereby the surface (upper surface) of the growth layer can be reliably formed to have flatness in forming the (11-22) facets 12b on the n-type GaN substrate 11 as compared with a surface (main surface) of a growth layer of the light-emitting device layer 12 in forming side surfaces, plain orientations of which are greatly different from those of the (11-22) planes on the n-type GaN substrate 11. A growth rate of the facets 12b is slower than the growth rate of the main surface of the light-emitting device layer 12, and hence the facets 12b can be easily formed by crystal growth.

According to the first embodiment, the substrate is formed to be the n-type GaN substrate 11 made of a nitride-based semiconductor such as GaN, whereby the light-emitting device layer 12 having the (000-1) facets 12a and the (11-22) facets 12b can be easily formed by utilizing crystal growth of the light-emitting device layer 12 on the n-type GaN substrate 11 made of a nitride-based semiconductor.

According to the first embodiment, the facets 12b of the light-emitting device layer 12 form obtuse angles with respect to the main surface ((11-20) plane)) of the light-emitting device layer 12, whereby a plurality of the recess portions 20 (upper regions of the grooves 21, including the grooves 21 of the n-type GaN substrate 11) where the facets 12a and 12b of the light-emitting device layer 12 are opposed are formed to broaden from the n-type GaN substrate 11 toward the upper surface of the light-emitting device layer 12, and hence light from the light-emitting layer 14 can be easily extracted not only through the upper surface of the light-emitting device layer 12 but also through the facets 12b inclined with respect to the main surface of the n-type GaN substrate 11. Thus, luminous efficiency of the light-emitting diode chip 30 can be further improved.

### Second Embodiment

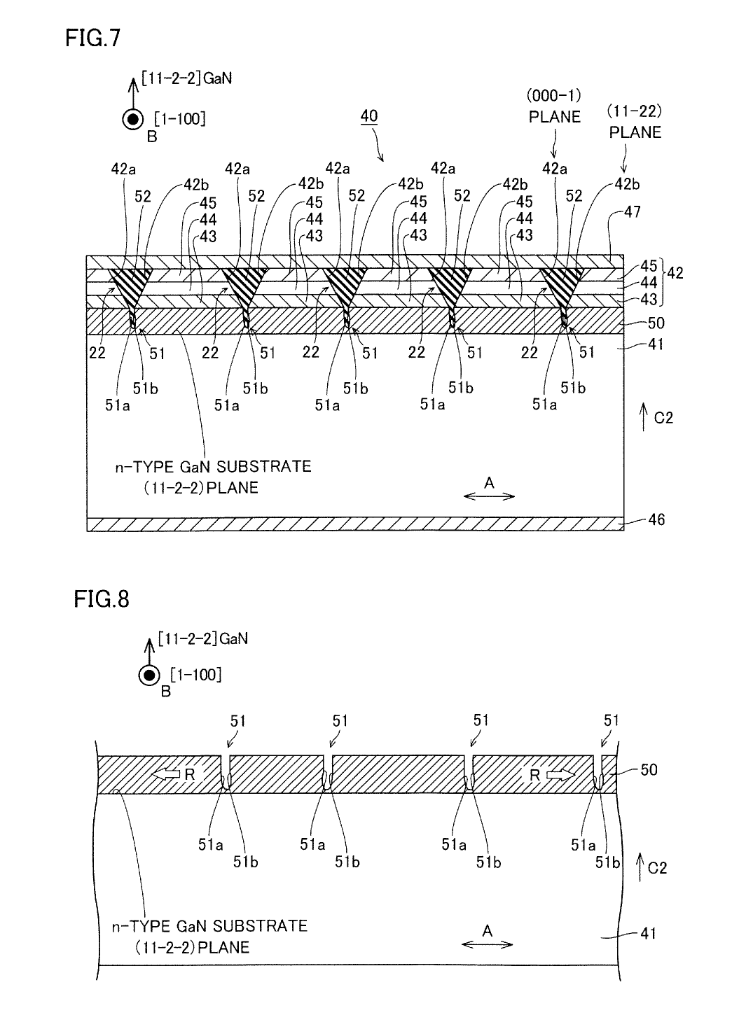

In a manufacturing process of a light-emitting diode chip 40 according to a second embodiment, a case where a light-emitting device layer 42 is formed after forming an underlayer 50 made of AlGaN on an n-type GaN substrate 41 dissimilarly to the aforementioned first embodiment will be described with reference to FIGS. 7 to 10. The n-type GaN substrate 41 is an example of the “base substrate” in the present invention.

The light-emitting diode chip 40 according to the second embodiment is constituted by a wurtzite structure nitride-based semiconductor having a (11-2-2) plane as a main surface. The shape of the light-emitting diode chip 40 is a square shape, a rectangular shape, a rhombus shape, a parallelogram shape or the like in plan view (as viewed from an upper side of the light-emitting diode chip 40).

In the manufacturing process of the light-emitting diode chip 40 according to the second embodiment, the underlayer 50 made of Al_{0.05}Ga_{0.95}N having a thickness of about 3 μm to about 4 μm is grown on the n-type GaN substrate 41 having a thickness of about 100 μm. When the underlayer 50 is crystal-grown, a lattice constant c₂ of the underlayer 50 is smaller than a lattice constant c₁ of the n-type GaN substrate 41 (c₂>c₂), and hence tensile stress R (see FIG. 8) is caused inside the underlayer 50, a thickness of which reaches a prescribed thickness, in response to the lattice constant c₁ of the n-type GaN substrate 41. Consequently, the cracks 51 as shown in FIG. 8 are formed in the underlayer 50 following local contraction of the underlayer 50 in the direction A. Difference between c-axial lattice constants of GaN and AlGaN is larger than difference between a-axial lattice constants of GaN and AlGaN, and hence the cracks 51 are likely to be formed in a [1-100] direction (direction B) parallel to a (000-1) plane of the underlayer 50 and a (11-2-2) plane of the main surface of the n-type GaN substrate 41. FIG. 8 schematically shows a state of voluntarily forming the cracks 51 on the underlayer 50.

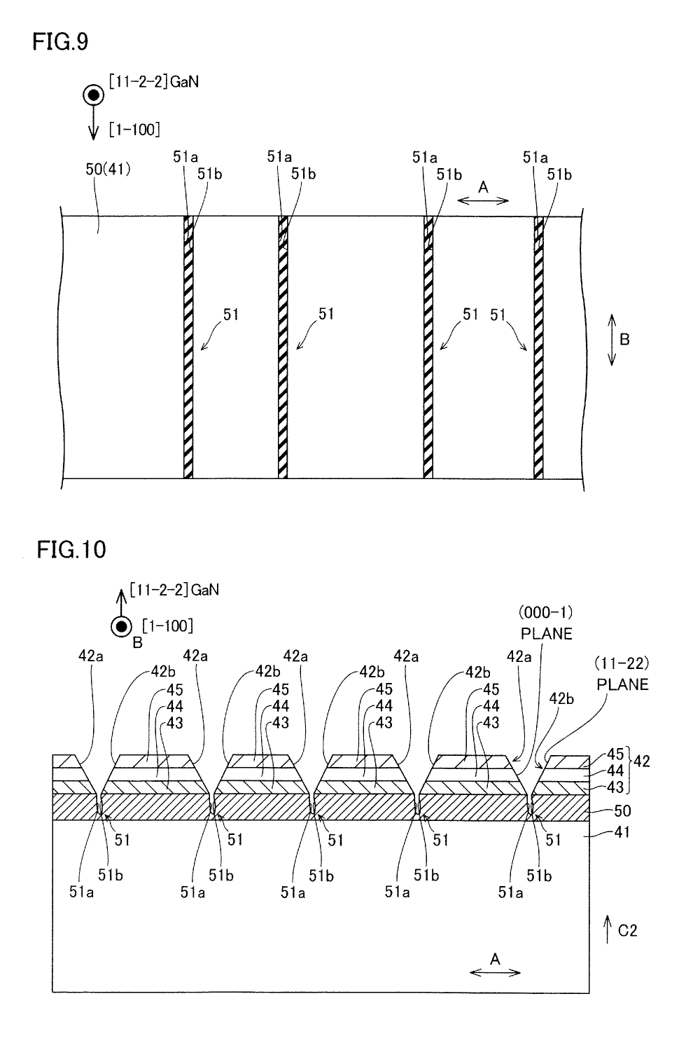

When the n-type GaN substrate 41 formed with the cracks 51 is viewed in a planar manner, the cracks 51 are formed in a striped manner along the [1-100] direction (direction B) substantially orthogonal to the direction A of the n-type GaN substrate 41, as shown in FIG. 9. The crack 51 is an example of the “recess portion” in the present invention.

As shown in FIG. 10, an n-type cladding layer 43 made of n-type GaN having a thickness of about 0.5 μm, a light-emitting layer 44 of MQW formed by stacking a well layer made of Ga_{0.7}In_{0.3}N having a thickness of about 2 nm and a barrier layer of Ga_{0.9}In_{0.1}N, and a p-type cladding layer 45 doubling as a p-type contact layer made of p-type GaN having a thickness of about 0.2 μm are successively stacked on the underlayer 50 through a manufacturing process similar to the aforementioned first embodiment, thereby forming the light-emitting device layer 42. The light-emitting device layer 42, the n-type cladding layer 43, the light-emitting layer 44 and the p-type cladding layer 45 are each an example of the “nitride-based semiconductor layer” in the present invention.

According to the second embodiment, when the light-emitting device layer 42 is grown on the n-type GaN substrate 41, the light-emitting device layer 12 is crystal-grown on inner side surfaces 51a of the cracks 51 extending in the [1-100] direction in a striped manner while forming (000-1) facets 42a extending in a direction inclined by a prescribed angle with respect to a [11-2-2] direction (along arrow C2) of the n-type GaN substrate 41. The light-emitting device layer 42 is crystal-grown on inner side surfaces 51b opposed to the inner side surfaces 51a of the cracks 51 while forming (11-22) facets 42b extending in a direction inclined by a prescribed angle with respect to the [11-2-2] direction (along arrow C2) of the n-type GaN substrate 41. The inner side surfaces 51a and 51b are examples of the “first inner side surface of the recess portion” and the “second inner side surface of the recess portion” in the present invention, respectively. The facet 42a is examples of the “first side surface” and the “crystal growth facet” in the present invention, and the facet 42b is examples of the “second side surface” and the “crystal growth facet” in the present invention. Thus, the facets 42a and 42b form respective obtuse angles with respect to the upper surface (main surface) of the light-emitting device layer 12.

As shown in FIG. 7, insulating films 22 of as SiO₂ or the like transparent for an emission wavelength are formed to fill up recess portions 52 (regions on the upper portions of the cracks 51) held between the (000-1) facets 42a and the (11-22) facets 42b of the light-emitting device layer 42. Then, a p-side electrode 47 is formed on upper surfaces of the insulating films 22 and the light-emitting device layer 42, and an n-side electrode 46 is formed on a lower surface of the n-type GaN substrate 41. Thus, the light-emitting diode chip 40 according to the second embodiment shown in FIG. 7 is formed.

According to the second embodiment, as hereinabove described, the n-type GaN substrate 41 formed with the cracks 51 on the underlayer 50 and the light-emitting device layer 42 including the (000-1) facets 42a formed to start from the inner side surfaces 51a of the cracks 51 on the main surface of the n-type GaN substrate 41 and the facets 42b formed to start from the inner side surfaces 51b of the cracks 51 are provided, whereby the facets 42a and 42b starting from the inner side surfaces 51a and 51b of the cracks 51 of the underlayer 50 previously formed on the n-type GaN substrate 41 are formed on the light-emitting device layer 42. In other words, no etching is required dissimilarly to a case of forming the aforementioned facets 42a or 42b by etching the nitride-based semiconductor layer stacked on a flat substrate with no recess portion in the manufacturing process, and hence the manufacturing process of the light-emitting diode 40 can be inhibited from complication. The facets 42a and 42b of the light-emitting device layer 42 are not formed by dry etching or the like, and hence the light-emitting layer 44 and the like are difficult to be damaged in the manufacturing process. Thus, light extraction efficiency from the light-emitting layer 44 can be improved.

According to the second embodiment, the n-type GaN substrate 41 formed with the cracks 51 on the underlayer 50 and the light-emitting device layer 42 including the (000-1) facets 42a formed to start from the inner side surfaces 51a of the cracks 51 on the main surface of the n-type GaN substrate 41 and the facets 42b formed to start from the inner side surfaces 51b of the cracks 51 are provided, whereby when the light-emitting device layer 42 is crystal-grown on the n-type GaN substrate 41, growth rates of forming the facets 42a and 42b starting from the inner side surfaces 51a and 51b of the cracks 51 are slower than a growth rate of growing the upper surface (main surface of the light-emitting device layer 42) of the growth layer, and hence the upper surface (main surface) of the growth layer is grown while maintaining flatness. Thus, flatness of the surface (upper surface) of the light-emitting device layer 42 having the light-emitting layer 44 can be further improved as compared with surfaces of a growth layer of a light-emitting device layer with no facet having the aforementioned crystal facets 42a and 42b.

According to the second embodiment, the underlayer 50 made of AlGaN is formed on the n-type GaN substrate 41, and a lattice constant c₁ of the n-type GaN substrate 41 and a lattice constant c₂ of the underlayer 50 have the relation of c₁>c₂, and the facets 42a and 42b of the light-emitting device layer 42 are formed to start from the inner side surfaces 51a and 51b of the cracks 51, respectively, whereby the lattice constant c₂ of the underlayer 50 is smaller than the lattice constant c₁ of the n-type GaN substrate 41 (c₁>c₂) when the underlayer 50 made of AlGaN is formed on the n-type GaN substrate 41, and hence tensile stress R is caused inside the underlayer 50 in response to the lattice constant c₁ of the n-type GaN substrate 41. Consequently, when the thickness of the underlayer 50 is at least a prescribed thickness, the underlayer 50 cannot withstand this tensile stress R and hence the cracks 51 are formed in the underlayer 50. Thus, the inner side surfaces 51a and 52b which are the basis for forming the (000-1) facets 42a and the (11-22) facets 42b of the light-emitting device layer 42 on the underlayer 50 in crystal growth can be easily formed in the underlayer 50.

According to the second embodiment, the (000-1) facets 42a and the (11-22) facets 42b of the light-emitting device layer 42 have the facets formed in crystal growth, of the light-emitting device layer 42, whereby two types of the flat facets of the aforementioned facets 42a and 42b can be formed simultaneously with the crystal growth of the light-emitting device layer 42.

According to the second embodiment, the facets 42b and 42b of the light-emitting device layer 42 form obtuse angles with respect to the main surface ((11-2-2) plane)) of the light-emitting device layer 42, whereby a plurality of the recess portions 52 (upper regions of the cracks 51, including the cracks 51 on the n-type GaN substrate 41) opposed to the facets 42a and 42b of the light-emitting device layer 42 are formed to broaden from the n-type GaN substrate 41 toward the upper surface of the light-emitting device layer 42, and hence light from the light-emitting layer 44 can be easily extracted not only through the upper surface of the light-emitting device layer 42 but also through the facets 42a and 42b inclined with respect to the main surface of n-type GaN substrate 41. Thus, luminous efficiency of the light-emitting diode chip 40 can be further improved. The remaining effects of the second embodiment are similar to those of the aforementioned first embodiment.

### Third Embodiment

In a manufacturing process of a light-emitting diode chip 60 according to a third embodiment, a case where cracks 71, positions of which are controlled by forming skipped shaped scribing cracks 70 on an underlayer 50 on an n-type GaN substrate 61, are formed dissimilarly to the aforementioned second embodiment will be described with reference to FIGS. 8 and 11 to 13. The n-type GaN substrate 61 is an example of the “base substrate” in the present invention, and the crack 71 is an example of the “recess portion” in the present invention.

The light-emitting diode chip 60 according to the third embodiment is constituted by a wurtzite structure nitride-based semiconductor having a (1-10-2) plane as a main surface. The shape of the light-emitting diode chip 60 is a square shape, a rectangular shape, a rhombus shape, a parallelogram shape or the like in plan view (as viewed from an upper side of the light-emitting diode chip 60).

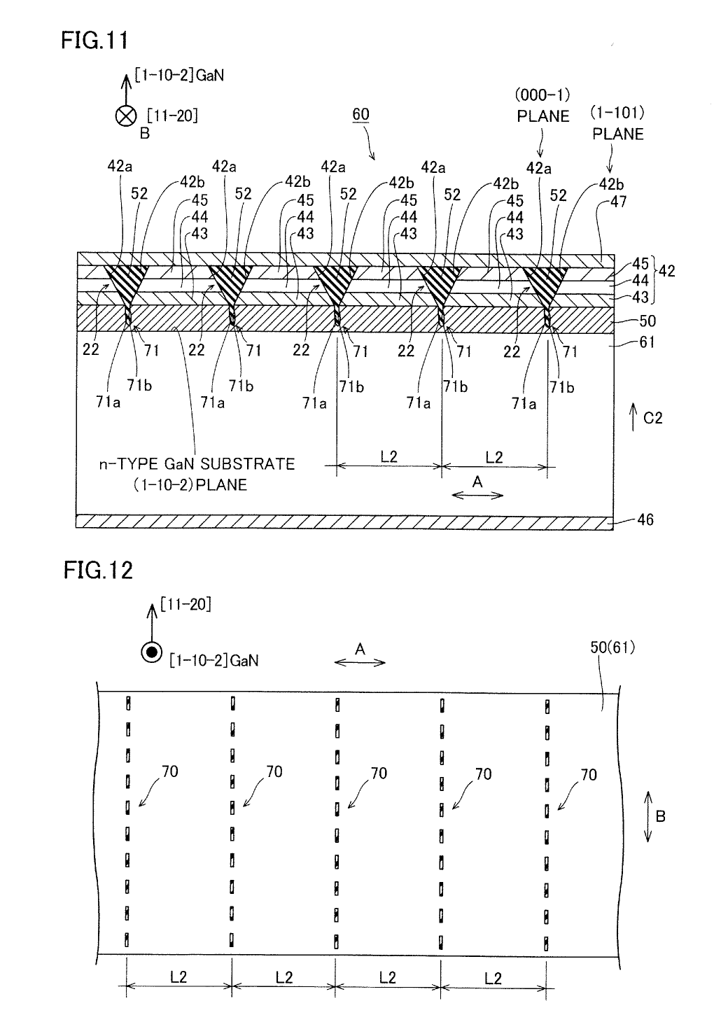

In the manufacturing process of the light-emitting diode chip 60 according to the third embodiment, the underlayer 50 made of AlGaN having a critical thickness smaller than the thickness (about 3 μm to about 4 μm) described in the aforementioned second embodiment is grown on an n-type GaN substrate 61 (see FIG. 11), similarly to the case shown in FIG. 8. At this time, tensile stress R (see FIG. 8) is caused inside the underlayer 50 due to action similar to the second embodiment. The critical thickness means a minimum thickness of the semiconductor layer in a case where no cracks resulting from difference between lattice constants is caused on the semiconductor layer when staking the semiconductor layer having a lattice constant different from the critical thickness.

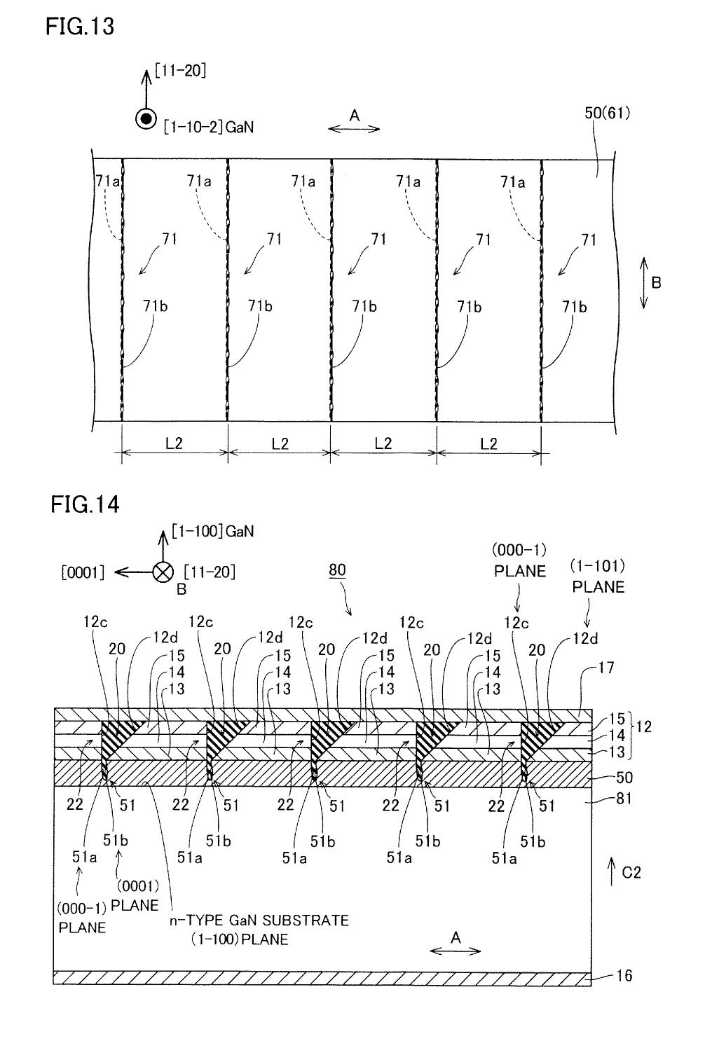

Thereafter, the skipped scribing cracks 70 are formed in the underlayer 50 in the [11-20] direction (direction B) orthogonal to the direction A at an interval of about 50 μm by a laser beam or a diamond point, as shown in FIG. 12. A plurality of the scribing cracks 70 are formed in the direction A at an interval L2. Thus, in the underlayer 50, formation of the cracks proceeds on regions of the underlayer 50 formed with no scribing crack 70 to starting from the skipped scribing cracks 70, as shown in FIG. 13. Consequently, substantially linear cracks 71 (see FIG. 13) dividing the underlayer 50 in the direction B are formed.

In this case, division of the scribing cracks 70 in a depth direction (direction perpendicular to the plane of FIG. 13) also proceeds. Thus, inner side surfaces 71a (shown by broken lines) reaching in the vicinity of an interface between the underlayer 50 and the n-type GaN substrate 61 are formed on the cracks 71. The inner side surface 71a is an example of the “first inner side surface of the recess portion” in the present invention.

An n-type cladding layer 43, a light-emitting layer 44 of MQW formed by stacking a well layer made of Ga_{0.7}In_{0.3}N having a thickness of about 2 nm and a barrier layer of Ga_{0.9}In_{0.1}N, and a p-type cladding layer 45 are successively stacked on the underlayer 50 through a manufacturing process similar to the aforementioned second embodiment, thereby forming the light-emitting device layer 42.

At this time, (000-1) facets 42c extending in a direction inclined by a prescribed angle with respect to a [1-10-2] direction (along arrow C2) of the n-type GaN substrate 61 and (1-101) facets 42d extending in a direction inclined by a prescribed angle with respect to a [1-10-2] direction (along arrow C2) of the n-type GaN substrate 61 are formed on the light-emitting device layer 42 on the n-type GaN substrate 61. The facet 42c is examples of the “first side surface” and the “crystal growth facet” in the present invention, and the facet 42d is examples of the “second side surface” and the “crystal growth facet” in the present invention.

The remaining manufacturing process of the third embodiment is similar to that of the aforementioned second embodiment. Thus, the light-emitting diode chip 60 according to the third embodiment shown in FIG. 11 is formed.

As hereinabove described, the manufacturing process of the third embodiment comprises steps of forming the underlayer 50 on the n-type GaN substrate 61 to have substantially critical thickness when forming the cracks 71 and thereafter forming a plurality of the skipped scribing cracks 70 (with an interval of about 50 μm) extending in the [11-20] direction (direction B) in the direction A at an interval L2 in the underlayer 50, whereby the cracks 71 with a regular interval are formed parallel to the direction B and along the direction A on the underlayer 50 to start from the skipped scribing cracks 70. In other words, the light-emitting diode chip 60 (see FIG. 11) having the same emission area can be more easily formed in the aforementioned second embodiment, as compared with a case of stacking the semiconductor layer by utilizing voluntarily formed cracks. The remaining effects of the third embodiment are similar to those of the aforementioned second embodiment.

### Fourth Embodiment

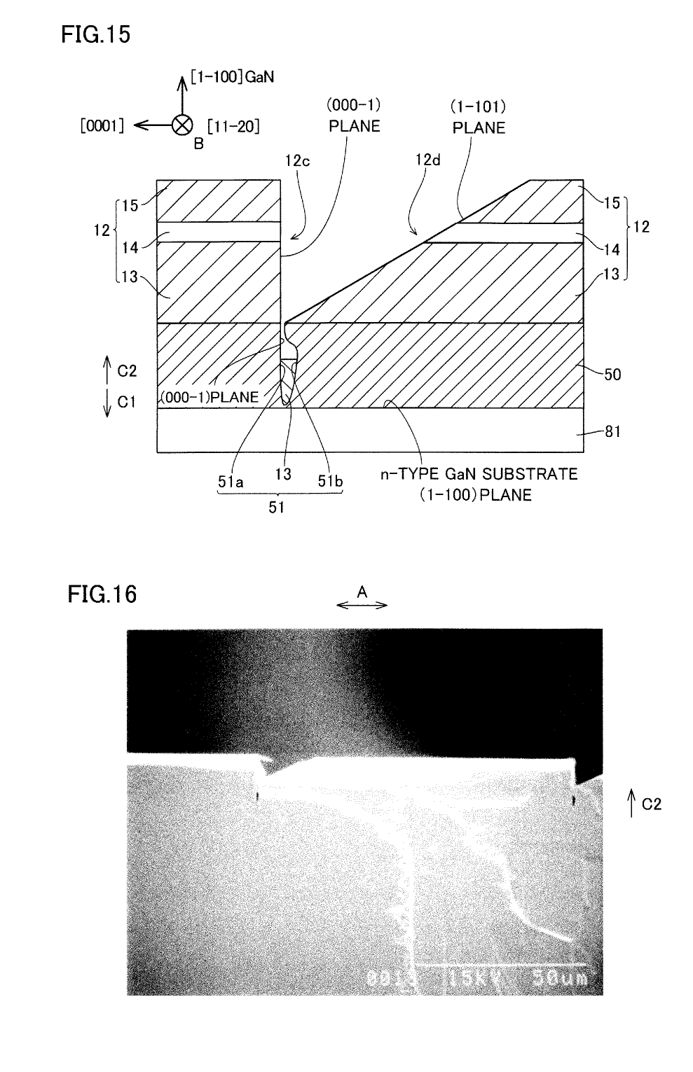

In a manufacturing process of a light-emitting diode chip 80 according to a fourth embodiment, a case where a light-emitting device layer 12 is formed after forming an underlayer 50 made of AlGaN on the n-type GaN substrate 81 having a main surface having an m-plane ((1-100) plane) dissimilarly to the aforementioned first embodiment will be described with reference to FIGS. 14 and 15. The n-type GaN substrate 81 is an example of the “base substrate” in the present invention.

The light-emitting diode chip 80 according to the fourth embodiment is constituted by a wurtzite structure nitride-based semiconductor having the m-plane as a main surface. The shape of the light-emitting diode chip 80 is a square shape, a rectangular shape, a rhombus shape, a parallelogram shape or the like in plan view (as viewed from an upper side of the light-emitting diode chip 80).

In the manufacturing process of the light-emitting diode chip 80 according to the fourth embodiment, the underlayer 50 made of Al_{0.05}Ga_{0.95}N having a thickness of about 3 μm to about 4 μm is grown on the n-type GaN substrate 81 having a thickness of about 100 μm, as shown in FIG. 15. In this case, cracks 51 resulting from difference between lattice constants of the n-type GaN substrate 81 and the underlayer 50 are formed in the underlayer 50 similarly to the aforementioned second embodiment.

An n-type cladding layer 13 made of n-type Al_{0.03}Ga_{0.97}N having a thickness of about 0.5 μm, a light-emitting layer 14 of MQW formed by stacking a well layer made of Ga_{0.7}In_{0.3}N having a thickness of about 2 nm and a barrier layer of Ga_{0.9}In_{0.1}N, and a p-type cladding layer 15 doubling as a p-type contact layer made of p-type GaN having a thickness of about 0.2 μm are successively stacked on the underlayer 50 through a manufacturing process similar to the aforementioned first embodiment, thereby forming the light-emitting device layer 12.

According to the fourth embodiment, as shown in FIG. 15, when the light-emitting device layer 12 is grown on the n-type GaN substrate 81, the light-emitting device layer 12 is crystal-grown on inner side surfaces 51a having the (000-1) planes of the cracks 51 extending in the [11-20] direction (direction B) while forming (000-1) facets 12c extending in a [1-100] direction (along arrow C2) to start from the (000-1) planes of the cracks 51. The light-emitting device layer 12 is crystal-grown on the (0001) plane (inner side surface 51b) opposed to the (000-1) planes of the cracks 51 while forming (1-101) facets 12d extending in a direction inclined by a prescribed angle with respect to the [1-100] direction (along arrow C2). Thus, the facets 12d form obtuse angles with respect to the upper surface (main surface) of the light-emitting device layer 12. The facet 12c is examples of the “first side surface” and the “crystal growth facet” in the present invention, and the facet 12d is examples of the “second side surface” and the “crystal growth facet” in the present invention.

Also in the fourth embodiment, insulating films 22 of SiO₂ or the like transparent for an emission wavelength are formed to fill up recess portions 20 (regions on the upper portions of the cracks 51, including the cracks 51) held between the (0001) facets 12c and the (1-101) facets 12b of the light-emitting device layer 12.

The remaining manufacturing process of the fourth embodiment is similar to that of the aforementioned first embodiment. Thus, the light-emitting diode chip 80 according to the fourth embodiment shown in FIG. 14 is formed. The remaining effects of the light-emitting diode chip 80 according to the fourth embodiment are similar to those of the aforementioned first and second embodiments.

### Example

A confirmatory experiment conducted for confirming the aforementioned effects of the aforementioned fourth embodiment will be described with reference to FIGS. 9, 16 and 17.

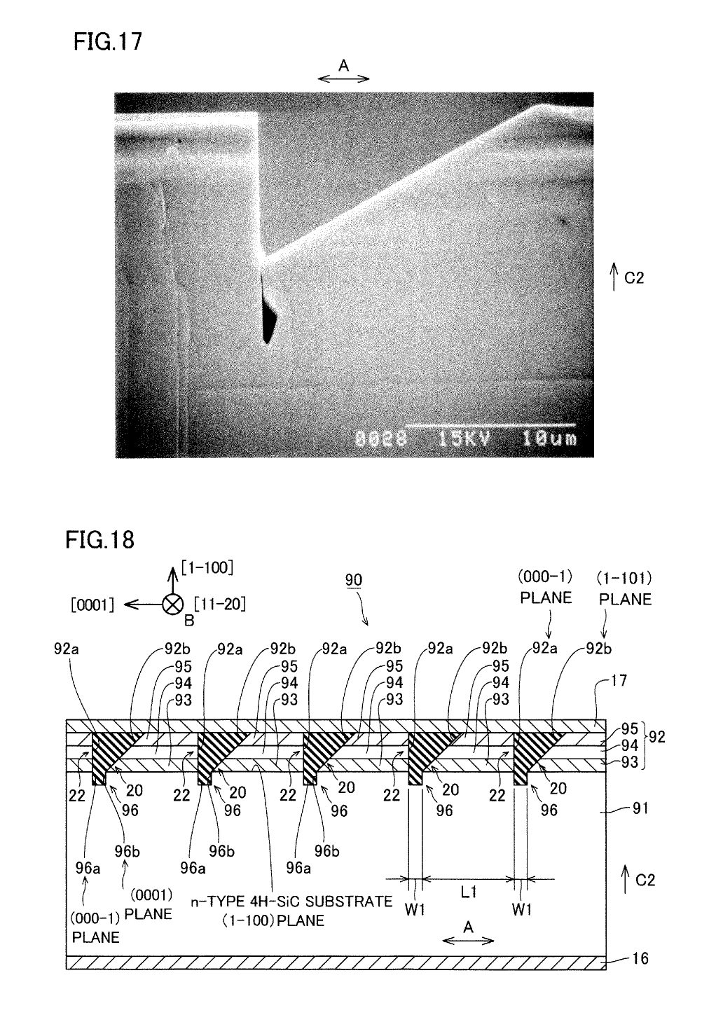

In this confirmatory experiment, an underlayer made of AlGaN having a thickness of 3 μm to 4 μm was first formed on an n-type GaN substrate having a main surface having an m-plane ((1-100) plane) by MOCVD through a manufacturing process similar to the manufacturing process of the aforementioned fourth embodiment. At this time, cracks shown in FIGS. 16 and 17 were formed in the underlayer resulting from difference between lattice constants of the n-type GaN substrate and the underlayer. At this time, it has been confirmed that the cracks formed (000-1) planes extending in a direction perpendicular to the main surface of the n-type GaN substrate, as shown in FIG. 17. Further, it has been confirmed that the cracks were formed in a striped manner along a [11-20] direction (direction B) orthogonal to a [0001] direction (direction A) of the n-type GaN substrate, as shown in FIG. 9.

A semiconductor layer of GaN was crystal-grown on the underlayer by MOCVD. Consequently, it has been confirmed that the semiconductor layer was crystal-grown on inner side surfaces, having the (000-1) planes, of the cracks in a [1-100] (along arrow C2) direction while forming the (000-1) plane of GaN extending in a vertical direction so as to start from this plain orientation, as shown in FIG. 17. It has been confirmed that the inclined facets, having the (1-101) planes, of GaN are formed on inner side surfaces on sides of the cracks opposite to the (000-1) planes as shown in FIG. 17. Further, it has been confirmed that each of these inclined surfaces is formed so as to form an obtuse angle with respect to the upper surface (main surface) of the semiconductor layer. Thus, it has been confirmed that the semiconductor layer can be formed on the underlayer while starting from the two inner side surfaces of each crack provided on the underlayer as starting points of crystal growth. Further, it has been confirmed that voids of the cracks reaching the n-type GaN substrate in forming the underlayer were partly filled up following lamination of the semiconductor layer.

In the present invention, it has been confirmed from results of the aforementioned confirmatory experiment that the facets (side surfaces perpendicular to the semiconductor layer and inclined surfaces of the semiconductor layer) having the (000-1) planes and the (1-101) planes can be formed on the semiconductor layer (light-emitting layer) without etching when forming the semiconductor layer by crystal growth. Further, it has been confirmed that not only flatness of the aforementioned (000-1) plane and (1-101) plane but also flatness of the upper surface (main surface) of the semiconductor layer can be improved from difference of growth rates of portions formed with the aforementioned (000-1) plane and (1-101) plane and a growth rate of the upper surface (main surface) of the semiconductor layer along arrow C2 (see FIG. 16) in a process of the crystal growth of the semiconductor layer.

### Fifth Embodiment

In a light-emitting diode chip 90 according to a fifth embodiment, a case where a light-emitting device layer 92 is formed on an n-type 4H—SiC substrate 91 having a main surface having an m-plane ((1-100) plane) dissimilarly to the aforementioned first embodiment will be described with reference to FIG. 18. The n-type 4H—SiC substrate 91 and the light-emitting device layer 92 are examples of the “substrate” and the “nitride-based semiconductor layer” in the present invention, respectively.

The light-emitting diode chip 90 according to the fifth embodiment is constituted by a wurtzite structure nitride-based semiconductor having the m-plane ((1-100) plane) as a main surface. The shape of the light-emitting diode chip 90 is a square shape, a rectangular shape, a rhombus shape, a parallelogram shape or the like in plan view (as viewed from an upper side of the light-emitting diode chip 90).

The light-emitting diode chip 90 is formed with a light-emitting device layer 92 on the n-type 4H—SiC substrate 91 having a thickness of about 100 μm, as shown in FIG. 18. The light-emitting device layer 92 is formed with an n-type cladding layer 93 made of Al_{0.03}Ga_{0.9}7N having a thickness of about 0.5 μm and a light-emitting layer 94 formed by stacking a well layer made of Ga_{0.7}In_{0.3}N having a thickness of about 2 nm and a barrier layer made of Ga_{0.9}In_{0.1}N. A p-type cladding layer 95 doubling as a p-type contact layer made of p-type GaN having a thickness of about 0.2 μm are formed on the light-emitting layer 94. The n-type cladding layer 93, the light-emitting layer 94 and the p-type cladding layer 95 are each an example of the “nitride-based semiconductor layer” in the present invention.

According to the fifth embodiment, recess portions 20 are formed from the n-type cladding layer 93 to the p-type cladding layer 95 by (000-1) facets 92a and (1-101) facets 92b of the light-emitting device layer 92. The facet 92a is examples of the “first side surface” and the “crystal growth facet” in the present invention, and the facet 92b is examples of the “second side surface” and the “crystal growth facet” in the present invention. The facets 92a are formed to extend in a direction ([1-100] direction) substantially perpendicular to a main surface of the n-type 4H—SiC substrate 91 so as to start from inner side surfaces 96a having (000-1) planes of grooves 96 previously formed on the main surface of the n-type 4H—SiC substrate 91 in a manufacturing process. The facets 92b have inclined planes starting from inner side surfaces 96b of the grooves 96, and form obtuse angles with respect to an upper surface (main surface) of the light-emitting device layer 92. The groove 96 and the inner side surfaces 96a and 96b are examples of the “recess portion” and the “first inner side surface of the recess portion” and the “second inner side surface of the recess portion” in the present invention, respectively. In FIG. 18, only some of the grooves 96 are denoted by reference characters of the inner side surfaces 96a and 96b in the drawing because of illustration.

An n-side electrode 16 is formed on a lower surface of the n-type 4H—SiC substrate 91. The recess portions 20 are formed with insulating films 22, a translucent p-side electrode 17 is formed to cover the insulating films 22 of SiO₂ transparent for an emission wavelength and the p-type cladding layer 15.

The manufacturing process of the light-emitting diode chip 90 according to the fifth embodiment is similar to that of the aforementioned first embodiment. The effects of the fifth embodiment are also similar to those of the aforementioned first embodiment.

### Sixth Embodiment

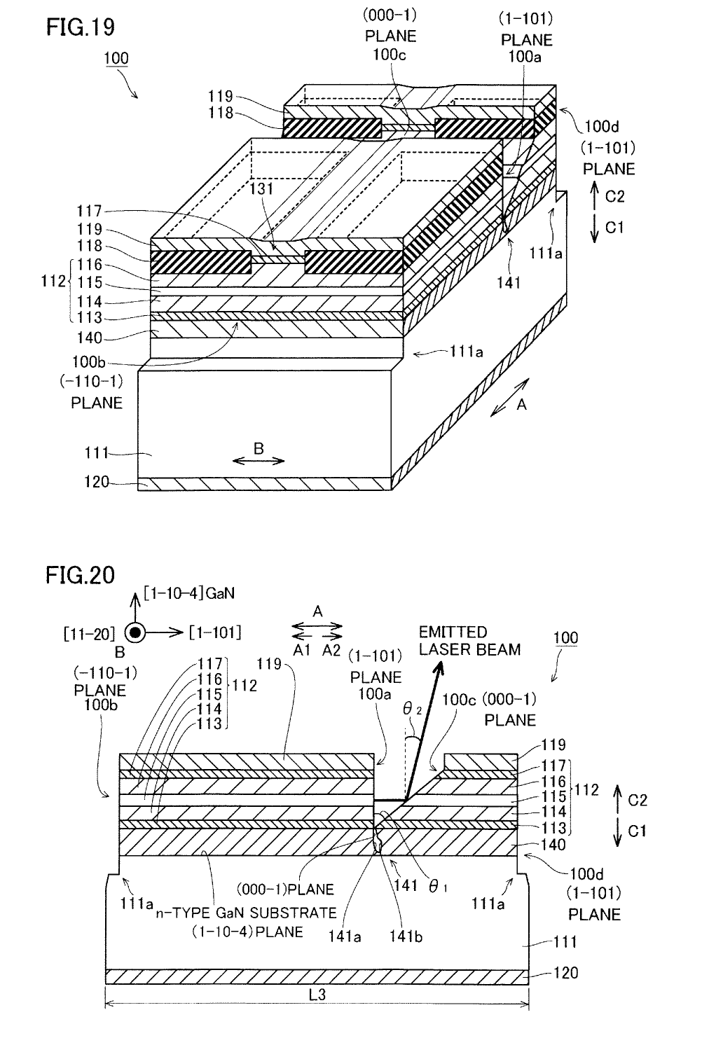

A structure of a surface emission type nitride-based semiconductor laser device 100 according to a sixth embodiment will be described with reference to FIGS. 19 to 21.

In the surface emission type nitride-based semiconductor laser device 100 according to the sixth embodiment, a semiconductor laser device layer 112 having a thickness of about 3.1 μm is formed on an n-type GaN substrate 111 having a thickness of about 100 μm and on a underlayer 140 made of AlGaN, having a thickness of about 3 μm to about 4 μm, as shown in FIGS. 19 and 20. The n-type GaN substrate 111 and the semiconductor laser device layer 112 are examples of the “substrate” and the “nitride-based semiconductor device layer” in the present invention, respectively. As shown in FIG. 20, the semiconductor laser device layer 112 is formed to have a length L3 between laser device ends (in a direction A) of about 1560 μm.

According to the sixth embodiment, the semiconductor laser device layer 112 is formed on a main surface, having a (1-10-4) plane, of the n-type GaN substrate 111 through the underlayer 140, as shown in FIG. 20.

The semiconductor laser device layer 112 is formed with a light-emitting surface 100a and a light-reflecting surface 100b substantially perpendicular to the main surface of the n-type GaN substrate 111 in a cavity direction (direction A), which is a [1-101] direction. The light-emitting surface 100a and the light-reflecting surface 100b are examples of the “first cavity facet” and the “second cavity facet” in the present invention, respectively. In the present invention, the light-emitting surface 100a and the light-reflecting surface 100b are distinguished by the large-small relation between intensity levels of laser beams emitted from cavity facets formed on the light-emitting side and the light-reflecting side, respectively. In other words, the side on which the emission intensity of the laser beam is relatively large is the light-emitting surface 100a, and the side on which the emission intensity of the laser beam is relatively small is the light-reflecting surface 100b.

According to the sixth embodiment, the underlayer 140 is formed with a crack 141 formed in crystal growth of the underlayer 140 and extending in a striped manner in a [11-20] direction of the n-type GaN substrate 111. As shown in FIG. 20, the light-emitting surface 100a of the semiconductor laser device layer 112 is constituted by a facet having a (1-101) plane crystal-grown to start from inner side surface 141a of the crack 141 of the underlayer 140 in forming the semiconductor laser device layer 112 described later. The light-reflecting surface 100b of the semiconductor laser device layer 112 has the (−110-1) plane which is a facet perpendicular to the [−110-1] direction (along arrow A1 in FIG. 20). The crack 141 is an example of the “recess portion” in the present invention, and the inner side surface 141a is an example of the “inner side surface of the recess portion” in the present invention.

While the crack 141 employed as the recess portion is formed in the underlayer 140 by utilizing difference between lattice constants of the n-type GaN substrate 111 and the underlayer 140 when crystal-growing the underlayer 140 made of AlGaN in the sixth embodiment, the recess portion (dent in a groove shape) may be formed by mechanical scribing, laser scribing, dicing, etching and the like from a surface of the underlayer 140 after crystal-growing the underlayer 140. When forming the recess portion by the aforementioned method, the underlayer 140 may be made of GaN having a lattice constant similar to that of the n-type GaN substrate 111 which is the substrate (base substrate). Further, a recess portion (a groove 250 in a twelfth embodiment) may be directly formed on a surface of the n-type GaN substrate 111 by mechanical scribing, laser scribing, dicing, etching and the like.

According to the sixth embodiment, the semiconductor laser device layer 112 is formed with a reflection surface 100c extending in a direction inclined at an angle θ₁ (=about 65°) with respect to the light-emitting surface 100a on a region opposed to the light-emitting surface 100a in the [1-101] direction (along arrow A2), as shown in FIG. 20. The reflection surface 100c has a (000-1) facet crystal-grown while starting from an upper end of an inner side surface 141b of the crack 141 of the underlayer 140 in forming the semiconductor laser device layer 112 described later. Thus, the surface emission type nitride-based semiconductor laser device 100 is so formed that a laser beam emitted from the light-emitting surface 100a of a light-emitting layer 115 described later along arrow A2 can be emitted outside by changing an emission direction to a direction inclined at an angle θ₂ (=about 40°) with respect to the light-emitting surface 100a by the reflection surface 100c, as shown in FIG. 20. The inner side surface 141b is an example of the “inner side surface of the recess portion” in the present invention. As shown in FIG. 20, a facet 100d having the (1-101) plane of the semiconductor laser device layer 112 is formed at an end of the surface emission type nitride-based semiconductor laser device 100 along arrow A2.

The semiconductor laser device layer 112 includes a buffer layer 113, an n-type cladding layer 114, the light-emitting layer 115, a p-type cladding layer 116 and a p-type contact layer 117, as shown in FIGS. 19 and 20. More specifically, the buffer layer 113 made of undoped Al_{0.01}Ga_{0.99}N having a thickness of about 1.0 μm and the n-type cladding layer 114 made of Ge-doped Al_{0.07}Ga_{0.93}N having a thickness of about 1.9 μm are formed on an upper surface of the underlayer 140 formed on the n-type GaN substrate 111, as shown in FIG. 20.

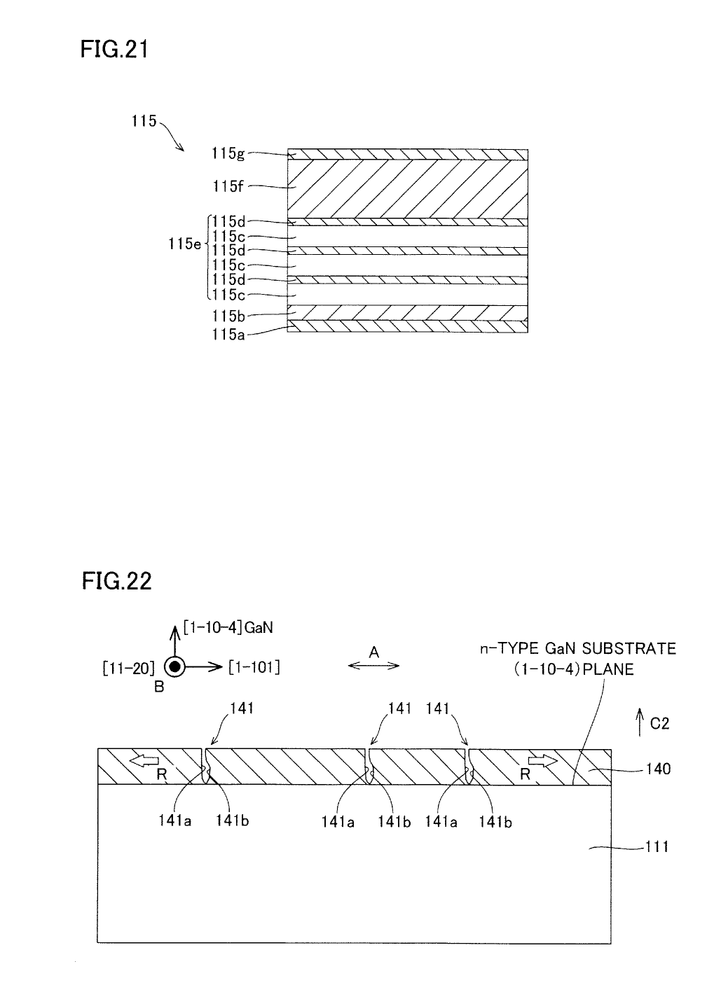

The light-emitting layer 115 is formed on the n-type cladding layer 114. As shown in FIG. 21, the light-emitting layer 115 is constituted by a n-type carrier blocking layer 115a made of Al_{0.2}Ga_{0.8}N having a thickness of about 20 nm, an n-type optical guide layer 115b made of undoped In_{0.02}Ga_{0.98}N having a thickness of about 20 nm, an MQW active layer 115e, a p-type optical guide layer 115f made of undoped In_{0.01}Ga_{0.99}N having a thickness of about 0.8 μm and a carrier blocking layer 115g made of Al_{0.25}Ga_{0.75}N having a thickness of about 20 nm successively from a side closer to the n-type cladding layer 114 (see FIG. 20). In the MQW active layer 115e, three quantum well layers 115c made of undoped In_{0.15}Ga_{0.85}N having a thickness of about 2.5 nm and three quantum barrier layers 115d made of undoped In_{0.02}Ga_{0.98}N having a thickness of about 20 nm are alternately stacked. The n-type cladding layer 114 has a larger band gap than the MQW active layer 115e. An optical guide layer having an intermediate band gap between those of the n-type carrier blocking layer 115a and the MQW active layer 115e may be formed between the n-type carrier blocking layer 115a and the MQW active layer 115e. The MQW active layer 115e may alternatively have a single-layer structure or an SQW structure.

As shown in FIGS. 19 and 20, the p-type cladding layer 116 made of Mg doped Al_{0.07}Ga_{0.93}N having a planar portion and a projecting portion formed to protrude upward (along arrow C2) from a substantially central portion of the planar portion and having a thickness of about 1 μm is formed on the light-emitting layer 115. The p-type cladding layer 116 has a larger band gap than the MQW active layer 115e. The p-type contact layer 117 made of undoped In_{0.07}Ga_{0.93}N having a thickness of about 3 nm is formed on the projecting portion of the p-type cladding layer 116. A ridge 131 formed as an optical waveguide of the surface emission type nitride-based semiconductor laser device 100 and extending along a cavity direction (in the direction A in FIG. 19) in a striped (slender) manner is constituted by the projecting portion of the p-type cladding layer 116 and the p-type contact layer 117. The buffer layer 113, the n-type cladding layer 114, the light-emitting layer 115, the p-type cladding layer 116 and the p-type contact layer 117 are each an example of the “nitride-based semiconductor device layer” in the present invention.

As shown in FIG. 19, a current blocking layer 118 made of SiO₂ having a thickness of about 200 nm is formed to cover an upper surface of the planar portion other than the projecting portion of the p-type cladding layer 116 of the semiconductor laser device layer 112 and both side surfaces of the ridge 131.

A p-side electrode 119 constituted by a Pt layer having a thickness of about 5 nm, a Pd layer having a thickness of about 100 nm and an Au layer having a thickness of about 150 nm successively from a side closer to the upper surface of the p-type contact layer 117 is formed on the upper surfaces of the current blocking layer 118 and the p-type contact layer 117.

As shown in FIGS. 19 and 20, an n-side electrode 120 formed by an Al layer having a thickness of about 10 nm, a Pt layer having a thickness of about 20 nm and an Au layer having a thickness of about 300 nm is formed on a back surface of the n-type GaN substrate 111 successively from a side closer to the n-type GaN substrate 111. This n-side electrode 120 is formed on the overall back surface of the n-type GaN substrate 111 to extend to both side portions of the surface emission type nitride-based semiconductor laser device 100 along arrow A, as shown in FIG. 20.

A manufacturing process of the surface emission type nitride-based semiconductor laser device 100 according to the sixth embodiment will be now described with reference to FIGS. 15 and 19 to 25.

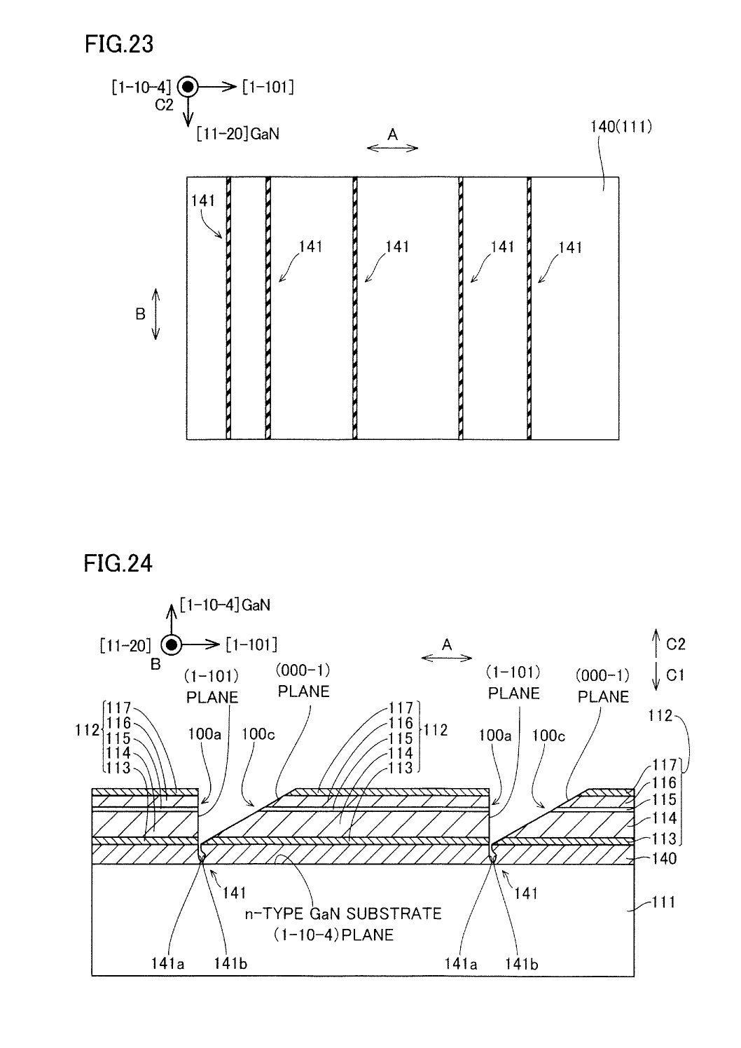

As shown in FIG. 22, the underlayer 140 made of AlGaN is grown on the n-type GaN substrate 111. When the underlayer 140 is crystal-grown, a lattice constant c₂ of the underlayer 140 is smaller than a lattice constant c₁ of the n-type GaN substrate 111, and hence tensile stress R is caused inside the underlayer 140 in response to the lattice constant c₁ of the n-type GaN substrate 111. Consequently, the cracks 141 as shown in FIGS. 22 and 23 are formed in the underlayer 140 following local contraction of the underlayer 140 in the direction A. At this time, the cracks 141 are easily formed in a striped manner along the [11-20] direction (direction B) parallel to a (0001) plane and the (1-10-4) plane of the main surface of the n-type GaN substrate 111.

According to the sixth embodiment, when forming the cracks 141 on the underlayer 140, the inner side surfaces 141a reaching in the vicinity of an interface between the underlayer 140 and the n-type GaN substrate 111 are formed on the cracks 141. These inner side surfaces 141a are formed substantially perpendicular to the main surface, having the (1-10-4) plane, of the n-type GaN substrate 111. The cracks 141 are formed by utilizing the tensile stress R (see FIG. 22) caused inside the underlayer 140, and hence the cracks 141 can be easily coincide with the [11-20] direction dissimilarly to a case where the recess portions are formed by external processing techniques (mechanical scribing, laser scribing, dicing, etching, etc. for example). Consequently, the cracks 141 can be formed extremely flatly, and hence the semiconductor laser device layer 112 having flat facets ((1-101) planes) can be easily grown.

According to the sixth embodiment, the cracks 141 reaching in the vicinity of the main surface of the n-type GaN substrate 111 are formed inside the underlayer 140, and hence lattice strains of the underlayer 140 different in lattice constant from the n-type GaN substrate 111 can be opened. Therefore, the crystal quality of the underlayer 140 is excellent, and the semiconductor laser device layer 112 formed on the underlayer 140 can be brought into a high quality crystalline state. Consequently, electric characteristics of the semiconductor laser device layer 112 formed through steps described later are improved, and light absorption in the semiconductor laser device layer 112 can be suppressed. Further, internal loss of the light-emitting layer 115 is reduced, and hence luminous efficiency of the light-emitting layer 115 can be improved. While the cracks 141 reaching in the vicinity of the main surface of the n-type GaN substrate 111 are formed inside the underlayer 140 in the sixth embodiment, grooves having a depth corresponding to a thickness of the underlayer 140 may be formed in a thickness direction (along arrow C2 in FIG. 22) of the underlayer 140. Also according to this structure, internal strains of the underlayer 140 can be opened by the grooves having the depth corresponding to the thickness of the underlayer 140, and hence effects similar to those in a case of forming the cracks 141 can be attained.

As shown in FIG. 24, the semiconductor laser device layer 112 is formed by successively growing the buffer layer 113, the n-type cladding layer 114, the light-emitting layer 115 (see FIG. 21 in details), the p-type cladding layer 116 and the p-type contact layer 117 on the underlayer 140 formed with the cracks 141 by MOCVD.

In forming the aforementioned semiconductor laser device layer 112, carrier gas of H₂ containing trimethylgallium (TMGa) and trimethylaluminum (TMAl) employed as Ga and Al sources is supplied into a reactor in a state where a substrate temperature is kept at a growth temperature of about 1000° C., and the buffer layer 113 is grown on the n-type GaN substrate 111. Then, carrier gas of H₂ containing TMGa, TMAl and GeH₄ (monogerman) employed as a Ge impurity source for obtaining an n-type conductivity is supplied into the reactor, and the n-type cladding layer 114 is grown on the buffer layer 113. Thereafter, H₂ gas containing TMGa and TMAl is supplied into the reactor, and the n-type carrier blocking layer 115a is grown on the n-type cladding layer 114.

Triethyl gallium (TEGa) and trimethyl indium (TMIn) employed as Ga and In sources are supplied in a nitrogen gas atmosphere obtained by supplying NH₃ gas into the reactor in a state where the substrate temperature reduced to a growth temperature of about 850° C. is kept, and the n-type optical guide layer 115b, the MQW active layer 115e and the p-type optical guide layer 115f are grown. Then, TMGa and TMAl are supplied into the reactor, and the carrier blocking layer 115g is grown. The light-emitting layer 115 (see FIG. 21) is formed in the aforementioned manner.

Then, Mg(C₅H₅)₂ (cyclopentadienyl magnesium) employed as a Mg source serving as a p-type impurity, and TMGa and TMAl are supplied into an atmosphere of hydrogen gas and nitrogen gas obtained by supplying NH₃ gas into the reactor in a state where the substrate temperature increased to a growth temperature of about 1000° C. is kept, and the p-type cladding layer 116 is grown on the light-emitting layer 115. Thereafter, TEGa and TMIn are supplied in a nitrogen gas atmosphere obtained by supplying NH₃ gas into the reactor in a state where the substrate temperature reduced to a growth temperature of about 850° C. again is kept, and the p-type contact layer 117 is grown. The semiconductor laser device layer 112 is formed on the underlayer 140 in the aforementioned manner.

According to the sixth embodiment, when the semiconductor laser device layer 112 is grown similarly to the case shown in FIG. 15, the semiconductor laser device layer 112 is crystal-grown while forming a facet ((1-101) plane) extending in the [1-10-4] direction (along arrow C2) to start from the inner side surfaces 141a of the cracks 141 employing the upper ends of the inner side surfaces 141a of the cracks 141 extending in a striped manner in the direction B (see FIG. 23) as staring points. Thus, the light-emitting surfaces 100a having the (1-101) planes are formed on the semiconductor laser device layer 112. Simultaneously, the semiconductor laser device layer 112 is formed with the (000-1) facets extending in a direction inclined at the angle θ₁ (=about 65°) with respect to the main surface of the n-type GaN substrate 111 employing upper ends of inner side surfaces 141b of the cracks 141 as starting points. Thus, the light-emitting device layer 112 is formed with the reflection surface 100c having the (000-1) plane and forming the obtuse angle with respect to the upper surface (main surface) of the light-emitting device layer 112. A growth rate of growing the surface (upper surface) of the semiconductor laser device layer 112 along arrow C2 (see FIG. 24) is faster than growth rates of portions formed with the aforementioned (1-101) plane and (000-1) plane in a process of the crystal growth of the semiconductor laser device layer 112, and hence flatness of the main surface (upper surface) of the semiconductor laser device layer 112 can be also improved.

Then, p-type annealing treatment is performed in a nitrogen gas atmosphere under a temperature condition of about 800° C.

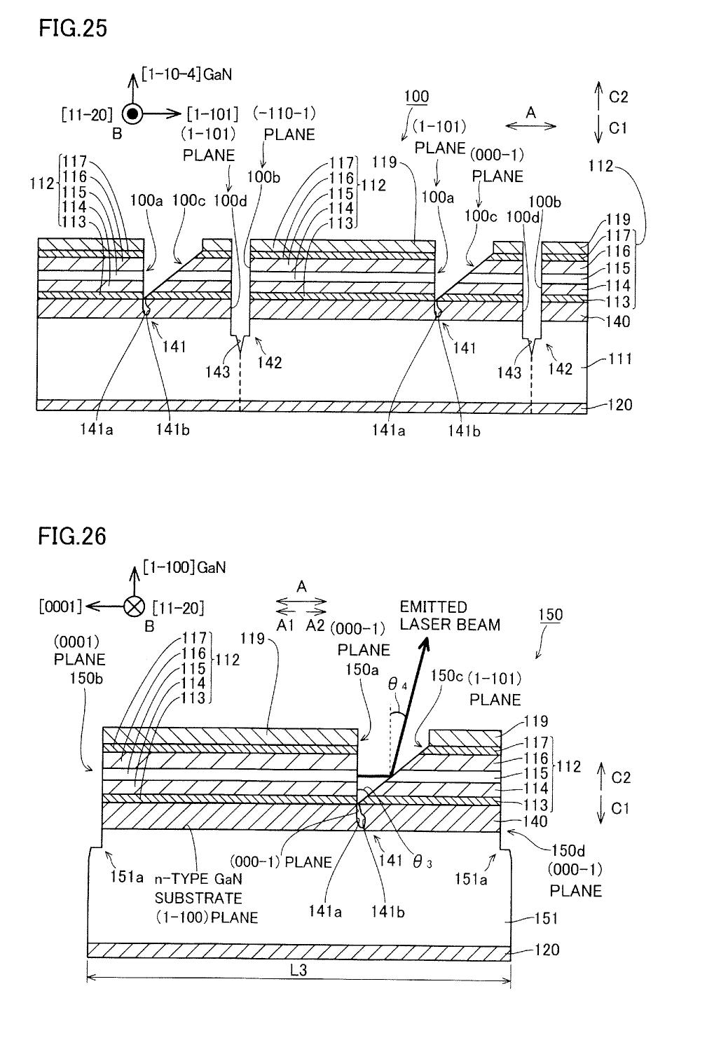

As shown in FIG. 19, resist patterns are formed on the upper surface of the p-type contact layer 117 by photolithography and the resist patterns are thereafter employed as masks for dry etching, thereby forming the ridge 131. Thereafter, the current blocking layer 118 is formed to cover the upper surface of the planar portion other than the projecting portion of the p-type cladding layer 116 and both the side surfaces of the ridge 131. As shown in FIGS. 19 and 25, the p-side electrodes 119 are formed on the current blocking layer 118 and the p-type contact layer 117 formed with no current blocking layer 118 by vacuum evaporation. FIG. 25 shows a sectional structure taken along the cavity direction (direction A) of the semiconductor laser device located on the position formed with the p-type contact layer 117 (in the vicinity of the ridge 131).

As shown in FIG. 25, a back surface of the n-type GaN substrate 111 is so polished that a thickness of the n-type GaN substrate 111 reaches a thickness of about 100 μm, and an n-side electrode 120 is thereafter formed on the back surface of the n-type GaN substrate 111 by vacuum evaporation to be in contact with the n-type GaN substrate 111.

According to the sixth embodiment, as shown in FIG. 25, positions to be formed with prescribed cavity facets are dry-etched in a direction (along arrow C1) reaching the n-type GaN substrate 111 from the surface (upper surface) of the semiconductor laser device layer 112, whereby grooves 142 in which first side surfaces of the semiconductor laser device layer 112 have the flat substantially (−110-1) planes are formed. Thus, the substantially (−110-1) planes, which are first side surfaces of the grooves 142, are easily formed as the light-reflecting surfaces 100b of the surface emission type nitride-based semiconductor laser device 100. The substantially (1-101) planes, which are second side surfaces of the grooves 142, are formed as the facets 100d of the surface emission type nitride-based semiconductor laser device 100. The grooves 142 are formed to extend in the [11-20] direction (direction B) substantially parallel to a direction in which the cracks 141 extend in plan view.

As shown in FIG. 25, linear scribing grooves 143 are formed parallel to the grooves 142 of the n-type GaN substrate 111 in the grooves 142 by laser scribing or mechanical scribing. In this state, a wafer is separated on a position of each of the scribing grooves 143 by applying a load while fulcruming the back surface of the n-type GaN substrate 111 so that a surface (upper side) of the wafer opens, as shown in FIG. 25. The grooves 142 of the n-type GaN substrate 111 become step portions 111a formed on lower portions of the light-reflecting surface 100b and the facet 100d after device division, as shown in FIG. 20.

The device is divided along the cavity direction (direction A) into chips, thereby forming the surface emission type nitride-based semiconductor laser device 100 according to the sixth embodiment shown in FIGS. 19 and 20.

According to the sixth embodiment, as hereinabove described, the surface emission type nitride-based semiconductor laser device 100 comprises the reflection surfaces 100c formed at regions opposed to the light-emitting surfaces 100a formed at an end of the semiconductor laser device layer 112 and having the (000-1) planes extending to be inclined at the angle θ₁ (=about 65°) with respect to the main surface ((1-10-4) plane) of the n-type GaN substrate 111, whereby the reflection surfaces 100c having the (000-1) planes have flatness so that the laser beam emitted from the light-emitting surfaces 100a can be emitted outside (above the surface emission type nitride-based semiconductor laser device 100) by uniformly changing the emission direction without scattering by the reflection surfaces 100c. Therefore, reduction in luminous efficiency of the surface emission type nitride-based semiconductor laser device 100 can be suppressed.

According to the sixth embodiment, the reflection surface 100c inclined with respect to the light-emitting surface 100a is formed in simultaneously the crystal growth for forming the semiconductor laser device layer 111 so that the manufacturing process of the semiconductor laser device can be inhibited from complication dissimilarly to a case of growing a flat semiconductor device layer on the n-type GaN substrate 111 and thereafter forming the reflection surface inclined at the angle θ₁ (=about 65°) with respect to the light-emitting surface 100a by ion beam etching or the like.

According to the sixth embodiment, the n-type GaN substrate 111 has the cracks 141 formed on the main surface of the n-type GaN substrate 111, and the reflection surfaces 100c of the semiconductor laser device layer 112 have facets of the semiconductor laser device layer 112 formed to start from the inner side surfaces 141b of the cracks 141, whereby when the semiconductor laser device layer 112 is crystal-grown on the n-type GaN substrate 111, a growth rate of forming the reflection surfaces 100c having the facets starting from the inner side surfaces 141b of the cracks 141 is slower than the growth rate of growing the upper surface (main surface of the semiconductor laser device layer 112) of the growth layer, and hence the upper surface (main surface) of the growth layer is grown while maintaining flatness. Thus, flatness of the surface of the semiconductor layer having the light-emitting layer can be further improved as compared with surfaces of a growth layer of the semiconductor laser device layer 112 in a case of not previously forming the cracks 141 on the n-type GaN substrate 111.

Further, a growth rate of the (1-101) plane is slower than the growth rate of the main surface (upper surface) of the semiconductor laser device layer 112 so that the light-emitting surface 100a can be easily formed by crystal growth.

According to the sixth embodiment, the surface emission type nitride-based semiconductor laser device 100 comprises the light-emitting surfaces 100b which are formed at an end of the semiconductor laser device layer 112 having the light-emitting layer opposite to the light-emitting surfaces 100a and which are extending in a direction substantially perpendicular to the maim surface of the n-type GaN substrate 111, whereby the semiconductor laser device layer 112 having the light-emitting surface 100a and the light-emitting surface 100b opposite to the light-emitting surface 100a as a pair of the cavity facets can be formed.

According to the sixth embodiment, the substrate is formed to be the n-type GaN substrate 111 made of a nitride-based semiconductor such as GaN, whereby the semiconductor laser device layer 112 having both the light-emitting surface 100a having the (1-101) plane and the reflection surface 100c having the (000-1) plane can be easily formed on the n-type GaN substrate 111 made of a nitride-based semiconductor by utilizing crystal growth of the semiconductor laser device layer 112 on the n-type GaN substrate 111 made of a nitride-based semiconductor.

According to the sixth embodiment, the light-reflecting surface 100b is formed by etching, whereby the cavity facets can be easily formed at the end of the semiconductor laser device layer 112 formed on a substrate with poor cleavage such as a GaN substrate. The light-reflecting surface 100b having the (−110-1) plane extending in a direction ([1-10-4] direction) substantially perpendicular to the main surface of the n-type GaN substrate 111 can be easily formed by controlling an etching condition.

### Seventh Embodiment

In a manufacturing process of a surface emission type nitride-based semiconductor laser device 150 according to a seventh embodiment, a case where a semiconductor laser device layer 112 is formed after forming an underlayer 140 on an n-type GaN substrate 151 having a main surface having an m-plane ((1-100) plane) dissimilarly to the aforementioned sixth embodiment will be described with reference to FIGS. 23, 26 and 27. The n-type GaN substrate 151 is an example of the “substrate” in the present invention.

According to the seventh embodiment, the semiconductor laser device layer 112 having a structure similar to that of the sixth embodiment is formed on the n-type GaN substrate 151 having the main surface having the m-plane, as shown in FIG. 26.

According to the seventh embodiment, the semiconductor laser device layer 112 is formed with a light-emitting surface 150a and a light-reflecting surface 150b substantially perpendicular to the main surface of the n-type GaN substrate 151. The light-emitting surface 150a and the light-reflecting surface 150b are examples of the “first cavity facet” and the “second cavity facet” in the present invention, respectively. The light-emitting surface 150a has a (000-1) plane crystal-grown to start from an inner side surface 141a of a crack 141 of an underlayer 140. The light-reflecting surface 150b has a (0001) plane perpendicular to a [0001] direction (along arrow A1 in FIG. 26).

According to the seventh embodiment, the semiconductor laser device layer 112 is formed with a reflection surface 150c extending in a direction inclined at an angle θ₃ (=about 62°) with respect to the light-emitting surface 150a on a region opposed to the light-emitting surface 150a in the [000-1] direction (along arrow A2), as shown in FIG. 26. The reflection surface 150c has a (1-101) facet crystal-grown in forming the semiconductor laser device layer 112. Thus, the surface emission type nitride-based semiconductor laser device 150 is so formed that an emission direction of a laser beam emitted from the light-emitting surface 150a of a light-emitting layer 115 along arrow A2 can be changed to a direction inclined at an angle θ₄ (=about 34°) with respect to the light-emitting surface 150a by the reflection surface 150c, as shown in FIG. 26. A facet 150d having the (000-1) plane of the semiconductor laser device layer 112 is formed at an end of the surface emission type nitride-based semiconductor laser device 150 along arrow A2, as shown in FIG. 26.

A device structure of the semiconductor laser device layer 112 of the surface emission type nitride-based semiconductor laser device 150 according to the seventh embodiment is similar to that of the aforementioned sixth embodiment.

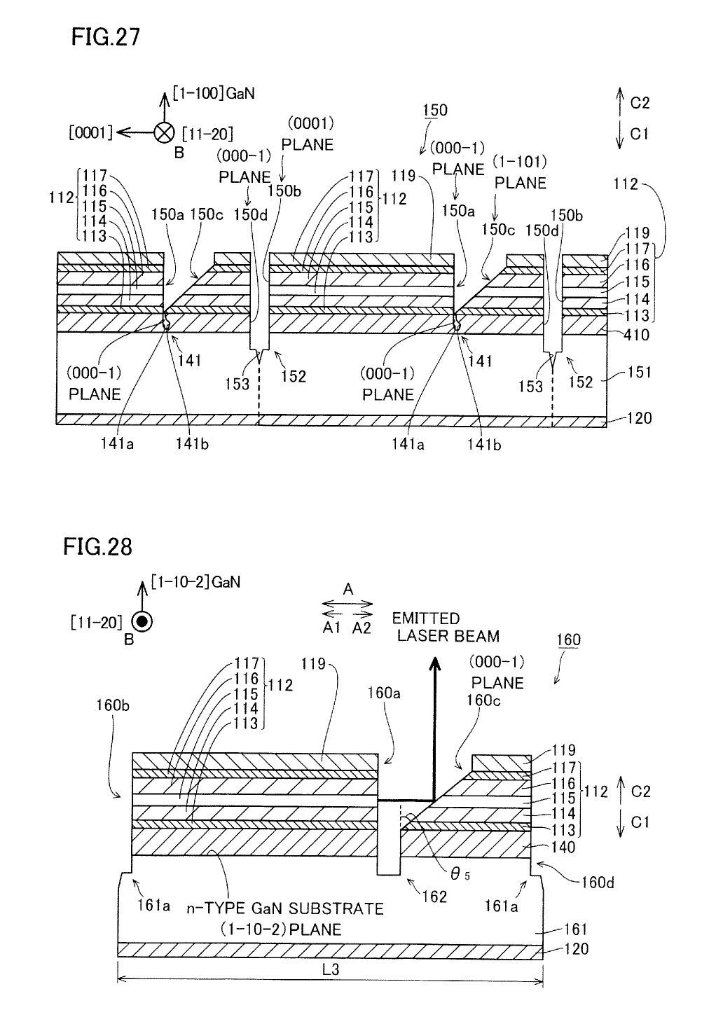

Next, in the manufacturing process of the surface emission type nitride-based semiconductor laser device 150 according to the seventh embodiment, the semiconductor laser device layer 112 is formed on the underlayer 140 through a manufacturing process similar to the aforementioned sixth embodiment, as shown in FIG. 27.

According to the seventh embodiment, as shown in FIG. 27, when the semiconductor laser device layer 112 is grown on the underlayer 140, the semiconductor laser device layer 112 is crystal-grown while forming the (000-1) planes extending in a [1-100] direction (along arrow C2) to start from the inner side surfaces 141a of the cracks 141 employing upper ends of the inner side surfaces 141a of the cracks 141 extending in a striped manner in a direction B (see FIG. 23) as staring points. Thus, the semiconductor laser device layer 112 is formed with the light-emitting surfaces 150a having the (000-1) planes. The (1-101) facets inclined at the angle θ₃ (=about 62°) with respect to the main surface of the n-type GaN substrate 151 employing the upper ends of inner side surfaces 141b of the cracks 141 as starting points are formed simultaneously on the semiconductor laser device layer 112. Thus, the semiconductor laser device layer 112 is formed with the reflection surfaces 150c having the (1-101) planes while forming acute angles with respect to an upper surface (main surface) of the semiconductor laser device layer 112. A growth rate of growing the surface (upper surface) of the semiconductor laser device layer 112 along arrow C2 (see FIG. 27) is faster than growth rates of portions formed with the aforementioned (000-1) plane and (1-101) plane in a process of the crystal growth of the semiconductor laser device layer 112, and hence not only flatness of the aforementioned (000-1) plane and (1-101) plane but also flatness of the surface (upper surface) of the semiconductor laser device layer 112 can be improved.

According to the seventh embodiment, positions to be formed with prescribed cavity facets are dry-etched in a direction (along arrow C1) reaching the n-type GaN substrate 151 from the surface (upper surface) of the semiconductor laser device layer 112, whereby grooves 152 in which first side surfaces of the semiconductor laser device layer 112 have the flat substantially (0001) planes are formed. Thus, first side surfaces of the grooves 152 are easily formed as the light-reflecting surfaces 150b of the surface emission type nitride-based semiconductor laser device 150. The substantially (0001) planes, which are second side surfaces of the grooves 142, are formed as the facets 150d of the surface emission type nitride-based semiconductor laser device 150. The grooves 152 are formed to extend in a [11-20] direction (direction B) substantially parallel to a direction in which the cracks 141 extend in plan view.

As shown in FIG. 27, scribing grooves 153 are formed parallel (in a direction perpendicular to the plane of FIG. 27) to the grooves 152 of the n-type GaN substrate 151 in the grooves 152 by laser scribing or mechanical scribing. In this state, a wafer is separated on a position of each of the scribing grooves 153 as shown in FIG. 27. The grooves 152 of the n-type GaN substrate 151 become step portions 151a formed on lower portions of the light-reflecting surface 150b and the facet 150d after device division, as shown in FIG. 26.

The device is divided along a cavity direction (direction A) into chips, thereby forming the surface emission type nitride-based semiconductor laser device 150 according to the seventh embodiment shown in FIG. 26.

According to the seventh embodiment, as hereinabove described, the surface emission type nitride-based semiconductor laser device 150 comprises the light-emitting surfaces 150a formed at the end of the semiconductor laser device layer 112 and the reflection surfaces 150c having the (1-101) planes extending to be inclined at the angle θ₃ (=about 62°) with respect to the m-plane ((1-100) plane) of the n-type GaN substrate 151, whereby the reflection surfaces 100c having the (1-101) planes have flatness so that the laser beam emitted from the light-emitting surfaces 150a can be emitted outside (above the surface emission type nitride-based semiconductor laser device 150) by uniformly changing the emission direction without scattering by the reflection surfaces 100c. Therefore, reduction in luminous efficiency of the surface emission type nitride-based semiconductor laser device 150 can be suppressed.

According to the seventh embodiment, the inner side surfaces 141a of the cracks 141 include the (000-1) planes, whereby the (000-1) planes of the semiconductor laser device layer 112 are formed to start the (000-1) planes of the inner side surfaces 141a of the cracks 141 when forming the semiconductor laser device layer 112 having the light-emitting surfaces 150a having the (000-1) planes on the main surface of the n-type GaN substrate 151, so that the light-emitting surfaces 15a can be easily formed on the n-type GaN substrate 151.

According to the seventh embodiment, the light-emitting surfaces 150a opposed to the reflection surfaces 150c having the (1-101) planes of the semiconductor laser device layer 112 have the (000-1) planes, whereby a surface (upper surface) of a growth layer in a case of forming the light-emitting surfaces 150a having the (000-1) planes on the n-type GaN substrate 151 can be reliably formed to have flatness as compared with a case of forming the light-emitting surfaces 150a which are not the (000-1) planes on the n-type GaN substrate 151. A growth rate of the (000-1) planes is slower than a growth rate of the main surface (upper surface) of the semiconductor laser device layer 112, and hence the light-emitting surfaces 150a can be easily formed by crystal growth.

According to the seventh embodiment, the semiconductor laser device layer 112 is formed on the n-type GaN substrate 151 having a main surface of a nonpolar face ((1-100) plane), whereby a piezoelectric field caused in the semiconductor device layer (light-emitting layer 115) or an internal electric field such as intrinsic polarization can be reduced. Thus, generation of heat of the semiconductor laser device layer 112 (light-emitting layer 115) including the vicinities of the cavity facets (light-emitting surfaces 150a) is further suppressed so that the surface emission type nitride-based semiconductor laser device 150 having further improved luminous efficiency can be formed. The remaining effects of the seventh embodiment are similar to those of the aforementioned sixth embodiment.

### Eighth Embodiment

In a surface emission type nitride-based semiconductor laser device 160 according to an eighth embodiment, a case where an underlayer 140 is formed on an n-type GaN substrate 161 by employing the n-type GaN substrate 161 having a main surface having a substantially (1-10-2) plane and a semiconductor laser device layer 112 is thereafter formed dissimilarly to the aforementioned sixth embodiment will be described with reference to FIG. 28. The n-type GaN substrate 161 is an example of the “substrate” in the present invention.

According to the eighth embodiment, the semiconductor laser device layer 112 is formed on the maim surface, having the substantially (1-10-2) plane, of the n-type GaN substrate 161 through the underlayer 140. The semiconductor laser device layer 112 is formed with a light-emitting surface 160a and a light-reflecting surface 160b substantially perpendicular to the main surface of the n-type GaN substrate 161 in a cavity direction (direction A). The light-emitting surface 160a and the light-reflecting surface 160b are examples of the “first cavity facet” and the “second cavity facet” in the present invention, respectively.

According to the eighth embodiment, a reflection surface 160c extending in a direction inclined at a prescribed angle θ₅ (=about 47°) with respect to the light-emitting surface 160a is formed at a region opposed to the light-emitting surface 160a of the semiconductor laser device layer 112. The reflection surface 160c has a (000-1) facet crystal-grown in forming the semiconductor laser device layer 112. Thus, the surface emission type nitride-based semiconductor laser device 160 is so formed that an emission direction of a laser beam emitted from the light-emitting surface 160a of a light-emitting layer 115 along arrow A2 can be changed to a direction ([1-10-2] direction (along C2 arrow)) substantially the same as the light-emitting surface 160a by the reflection surface 160c, as shown in FIG. 28. As shown in FIG. 28, a facet 160d is formed at an end of the surface emission type nitride-based semiconductor laser device 160 along arrow A2.

The remaining device structure of the surface emission type nitride-based semiconductor laser device 160 according to the eighth embodiment is similar to that of the aforementioned sixth embodiment.

A manufacturing process of the surface emission type nitride-based semiconductor laser device 160 according to the eighth embodiment will be now described with reference to FIGS. 28 to 30.

According to the eighth embodiment, the underlayer 140 is grown on the n-type GaN substrate 161 through a manufacturing process similar to that of the aforementioned sixth embodiment. Cracks 141 are formed due to difference between lattice constants of the n-type GaN substrate 161 and the underlayer 140. At this time, difference between c-axial lattice constants of GaN and AlGaN is larger than difference between a-axial lattice constants of GaN and AlGaN, and hence the cracks 141 are formed to extend in a striped manner along a [11-20] direction (direction B) parallel to a (0001) plane and the (1-10-2) plane of the main surface of the n-type GaN substrate 161.

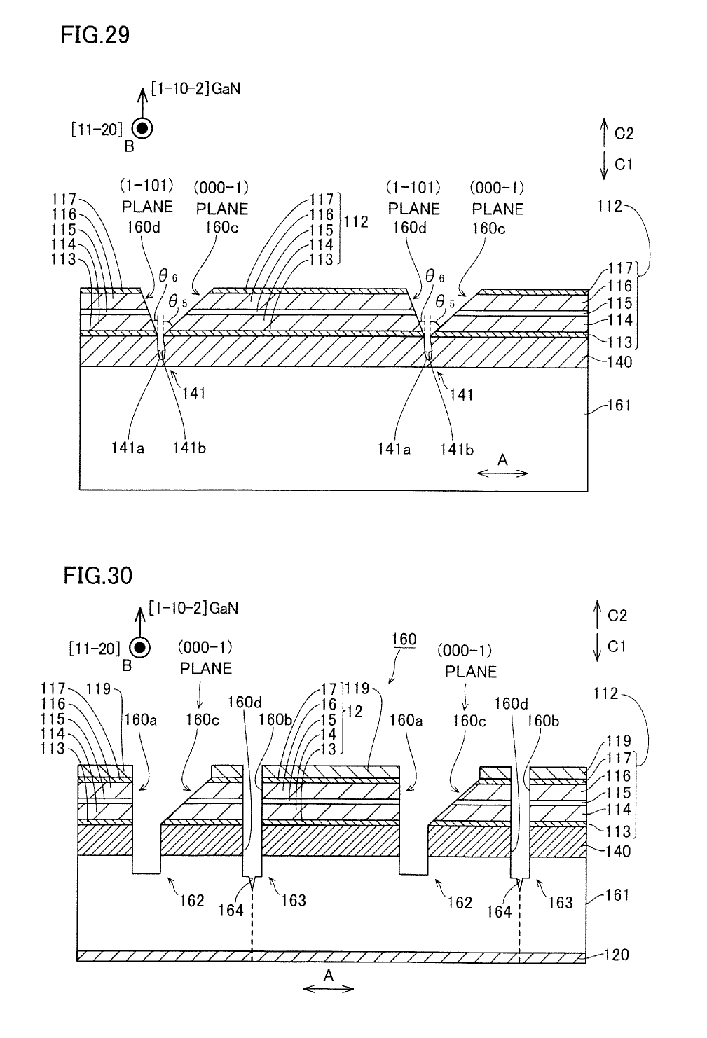

Thereafter, the semiconductor laser device layer 112 is formed on the underlayer 140 through the manufacturing process similar to that of the aforementioned sixth embodiment, as shown in FIG. 29.

According to the eighth embodiment, when the semiconductor laser device layer 112 is grown on the underlayer 140, the semiconductor laser device layer 112 is crystal-grown on inner side surfaces 141b of the cracks 141 extending in the striped manner in the [11-20] direction, while forming the reflection surfaces 160c having the (000-1) planes extending in the direction inclined at the angle θ₅ (=about 47°) with respect to the [1-10-2] direction (along arrow C2), as shown in FIG. 29.

According to the eighth embodiment, the semiconductor laser device layer 112 is crystal-grown on sides of an inner side surfaces 141a opposed to the inner side surfaces 141b of the cracks 141, while forming (1-101) facets 160d extending in a direction inclined at an angle θ₆ (=about 15°) with respect to the [1-10-2] direction (along arrow C2). Therefore, each of the reflection surfaces 160c and the facets 160d form obtuse angles with respect to an upper surface of the semiconductor laser device layer 112.

As shown in FIG. 30, a current blocking layer 118 and a p-side electrode 119 are formed on the semiconductor laser device layer 112 through the manufacturing process similar to the aforementioned sixth embodiment. A back surface of the n-type GaN substrate 161 is polished, and an n-side electrode 120 is thereafter formed on the back surface of the n-type GaN substrate 161 by vacuum evaporation, as shown in FIG. 30.

According to the eighth embodiment, as shown in FIG. 30, the facets 160d (see FIG. 29) are dry-etched in a direction (along arrow C1) reaching the n-type GaN substrate 161 from the surface (upper surface) of the semiconductor laser device layer 112, whereby grooves 162 are formed. Thus, portions of the facets 160d (see FIG. 29) of the semiconductor laser device layer 112 are removed while the light-emitting surfaces 160a, which are facets substantially perpendicular to the main surface on the n-type GaN substrate 161, are formed. The cracks 141 (see FIG. 29) of the underlayer 140 are also removed while forming the grooves 162, as shown in FIG. 30.

According to the eighth embodiment, as shown in FIG. 30, positions to be formed with prescribed cavity facets are dry-etched in the direction (along arrow C1) reaching the n-type GaN substrate 161 from the surface (upper surface) of the semiconductor laser device layer 112, whereby grooves 163 are formed. Thus, first side surfaces of the grooves 163 are easily formed as the light-reflecting surfaces 160b of the surface emission type nitride-based semiconductor laser device 160. Second side surfaces of the grooves 163 are formed as facets 160d of the surface emission type nitride-based semiconductor laser device 160. The grooves 163 are formed to extend in the [11-20] direction (direction B) substantially parallel to a direction in which the grooves 162 extend in plan view.

As shown in FIG. 30, scribing grooves 164 are formed parallel (in a direction perpendicular to the plane of FIG. 30) to the grooves 163 of the n-type GaN substrate 161 in the grooves 163. In this state, a wafer is separated on a position of each of the scribing grooves 164 as shown in FIG. 30. The groove 163 of the n-type GaN substrate 161 becomes a step portion 161a formed on a lower portion of the light-reflecting surface 160b after device division, as shown in FIG. 28.

The device is divided along the cavity direction (direction A) into chips, thereby forming the surface emission type nitride-based semiconductor laser device 160 according to the eighth embodiment shown in FIG. 28.

According to the eighth embodiment, as hereinabove described, the surface emission type nitride-based semiconductor laser device 160 comprises the light-emitting surfaces 160a formed at the end of the semiconductor laser device layer 112 and the reflection surfaces 160c having the (000-1) planes extending to be inclined at the angle θ₅ (=about 47°) with respect to the substantially (1-10-2) plane of the n-type GaN substrate 161, whereby the reflection surfaces 160c having the (000-1) planes have flatness so that the laser beam emitted from the light-emitting surfaces 160a can be emitted by uniformly changing the emission direction without scattering by the reflection surfaces 160c, similarly to the aforementioned sixth embodiment. Therefore, reduction in luminous efficiency of the surface emission type nitride-based semiconductor laser device 160 can be suppressed. The remaining effects of the eighth embodiment are similar to those of the aforementioned first and seventh embodiments.

(Modification of Eighth Embodiment)

In a surface emission type nitride-based semiconductor laser device 170 according to a modification of the eighth embodiment, a case where a semiconductor laser device layer 112 is etched to employ a (1-101) facet 160d of two facets in forming the semiconductor laser device layer 112 as a reflection surface 170c of a laser beam in a manufacturing process dissimilarly to the aforementioned eight embodiment is described will be described with reference to FIGS. 29, 31 and 32.

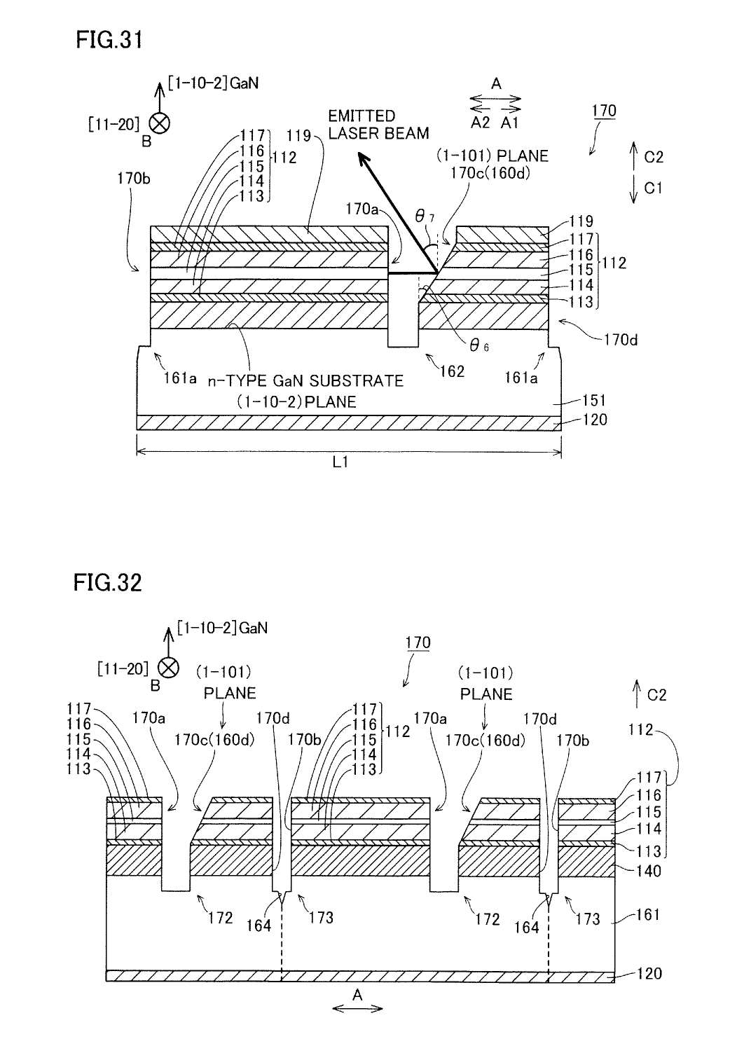

According to the modification of the eighth embodiment, the reflection surface 170c inclined at an angle θ₆ (=about 15°) with respect to a light-emitting surface 170a is formed at a region opposed to the light-emitting surface 170a of the semiconductor laser device layer 112, as shown in FIG. 31. The reflection surface 170c has a (1-101) facet. Thus, the surface emission type nitride-based semiconductor laser device 170 is so formed that an emission direction of a laser beam emitted from the light-emitting surface 170a of a light-emitting layer 115 along arrow A1 can be changed to a direction inclined at an angle θ₇ (=about 60°) with respect to the light-emitting surface 170a by the reflection surface 170c, as shown in FIG. 31. As shown in FIG. 31, a light-reflecting surface 170b and a facet 170d are formed at respective both ends of the surface emission type nitride-based semiconductor laser device 170. The light-emitting surface 170a and the light-reflecting surface 170b are examples of the “first cavity facet” and the “second cavity facet” in the present invention, respectively. The remaining device structure of the surface emission type nitride-based semiconductor laser device 170 according to the modification of the eighth embodiment is similar to that of the aforementioned eighth embodiment.

In the manufacturing process according to the modification of the eighth embodiment, as shown in FIG. 32, the reflection surfaces 160c (see FIG. 29) having the (000-1) planes according to the aforementioned eighth embodiment are dry-etched in a direction (along arrow C1) reaching an n-type GaN substrate 161 from a surface (upper surface) of the semiconductor laser device layer 112, whereby grooves 172 are formed. Thus, portions of the reflection surfaces 160c (see FIG. 29) are removed while the light-emitting surfaces 170a, which are facets substantially perpendicular to a main surface on the n-type GaN substrate 161, are easily formed. Cracks 141 (see FIG. 29) of an underlayer 140 are also removed while forming the grooves 172, as shown in FIG. 32.

According to the modification of the eighth embodiment, as shown in FIG. 32, positions to be formed with prescribed cavity facets are dry-etched in the direction (along arrow C1) reaching the n-type GaN substrate 161 from the surface (upper surface) of the semiconductor laser device layer 112, whereby grooves 173 are formed. Thus, first side surfaces of the grooves 173 are formed as the light-reflecting surfaces 170b of the surface emission type nitride-based semiconductor laser device 170. Second side surfaces of the grooves 173 are formed as facets 170d of the surface emission type nitride-based semiconductor laser device 170. The remaining manufacturing process of the surface emission type nitride-based semiconductor laser device 170 according to the modification of the eighth embodiment is similar to that of the aforementioned eighth embodiment. The effects of the modification of the eighth embodiment are also similar to those of the aforementioned eighth embodiment.

### Ninth Embodiment

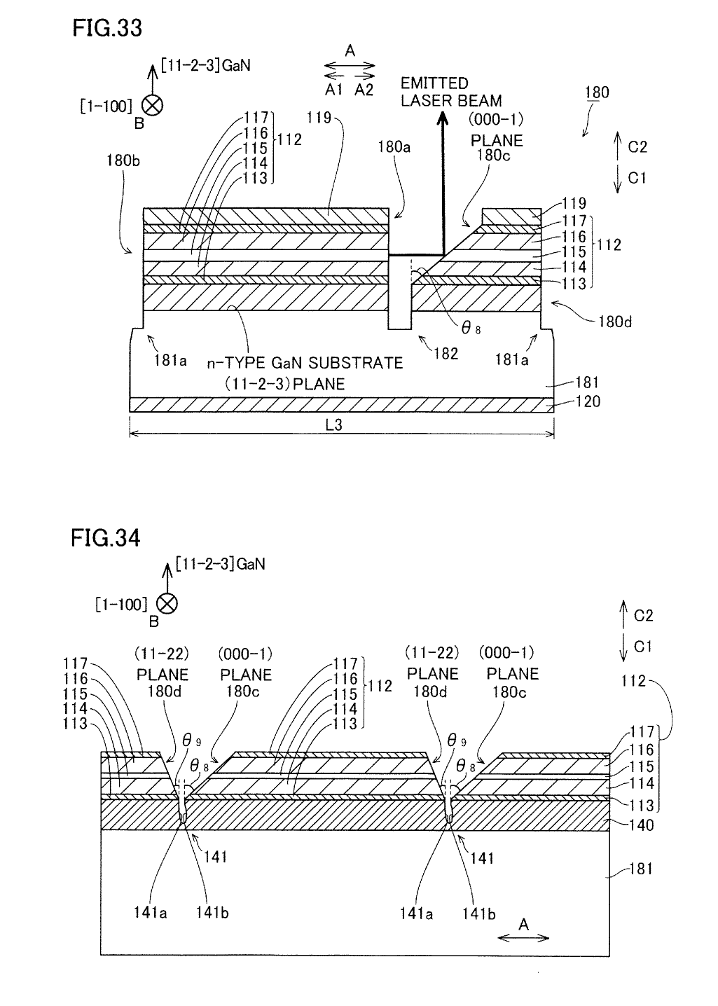

In a surface emission type nitride-based semiconductor laser device 180 according to a ninth embodiment, a case where a semiconductor laser device layer 112 is formed on a main surface of an n-type GaN substrate 181 by employing the n-type GaN substrate 181 having the main surface having a substantially (11-2-3) plane dissimilarly to the aforementioned eighth embodiment will be described with reference to FIGS. 33 to 35.

According to the ninth embodiment, as shown in FIG. 33, a reflection surface 180c inclined at an angle θ₈ (=about 43°) with respect to a light-emitting surface 180a is formed at a region opposed to the light-emitting surface 180a of the semiconductor laser device layer 112. The reflection surface 180c has a (000-1) facet. Thus, the surface emission type nitride-based semiconductor laser device 180 is so formed that an emission direction of a laser beam emitted from the light-emitting surface 180a of a light-emitting layer 115 along arrow A2 can be changed to a direction ([11-2-3] direction (along C2 arrow)) substantially the same as the light-emitting surface 180a by the reflection surface 180c, as shown in FIG. 33. As shown in FIG. 33, a light-reflecting surface 180b and a facet 180d are formed at respective both ends of the surface emission type nitride-based semiconductor laser device 180. The light-emitting surface 180a and the light-reflecting surface 180b are examples of the “first cavity facet” and the “second cavity facet” in the present invention, respectively. The remaining device structure of the surface emission type nitride-based semiconductor laser device 180 according to the ninth embodiment is similar to that of the aforementioned eighth embodiment.

In the manufacturing process according to the ninth embodiment, when the semiconductor laser device layer 112 is grown on an underlayer 140, the semiconductor laser device layer 112 is crystal-grown on inner side surfaces 141b of cracks 141 extending in a striped manner in a [11-20] direction, while forming the reflection surfaces 180c having the (000-1) planes extending in a direction inclined at the angle θ₈ (=about 43°) with respect to the [11-2-3] direction (along arrow C2). The semiconductor laser device layer 112 is crystal-grown on sides of inner side surfaces 141a of the cracks 141, while forming the (11-22) facets 180d extending in a direction inclined at an angle θ₉ (=about 16°) with respect to the [11-2-3] direction (along arrow C2). Therefore, each of the reflection surfaces 180c and the facets 180d form obtuse angles with respect to an upper surface (main surface) of the semiconductor laser device layer 112.

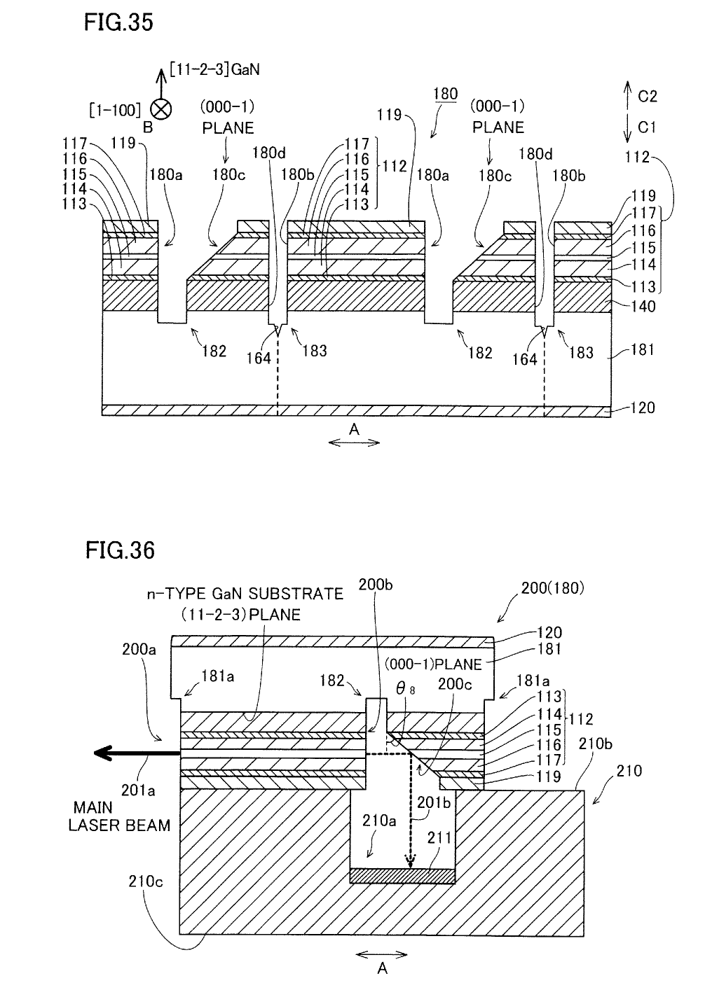

Thereafter, as shown in FIG. 35, the facets 180d are dry-etched in a direction (along arrow C1) reaching the n-type GaN substrate 181 from the surface (upper surface) of the semiconductor laser device layer 112, whereby grooves 182 are formed. Thus, portions of the facets 180d (see FIG. 34) of the semiconductor laser device layer 112 are removed while the light-emitting surfaces 180a, which are facets substantially perpendicular to the main surface on the n-type GaN substrate 181, are easily formed. The cracks 141 (see FIG. 34) of the underlayer 140 are also removed while forming the grooves 182, as shown in FIG. 35.

According to the ninth embodiment, grooves 183 are formed through the manufacturing process similar to that of the aforementioned eighth embodiment. Thus, first side surfaces of the grooves 183 are formed as the light-reflecting surfaces 180b of the surface emission type nitride-based semiconductor laser device 180. Second side surfaces of the grooves 183 are formed as the facets 180d of the surface emission type nitride-based semiconductor laser device 180.

The remaining manufacturing process of the surface emission type nitride-based semiconductor laser device 180 according to the ninth embodiment is similar to that of the aforementioned eighth embodiment. The effects of the ninth embodiment are also similar to those of the aforementioned eighth embodiment.

### Tenth Embodiment

A structure in which a surface emission type nitride-based semiconductor laser device 100 according to a tenth embodiment and a monitor photodiode (PD)-equipped submount 210 are combined will be described with reference to FIG. 36.

According to the tenth embodiment, the surface emission type nitride-based semiconductor laser device 200 having a structure similar to the surface emission type nitride-based semiconductor laser device 180 shown in the aforementioned ninth embodiment is fixed to the monitor PD-equipped submount 210 made of Si, as shown in FIG. 36. A recess portion 210a is formed on a substantially central portion of the monitor PD-equipped submount 210, and a PD 211 is incorporated into an inner bottom portion of the recess portion 210a. The PD 211 is an example of the “optical sensor” in the present invention.

According to the tenth embodiment, a main surface 210b of the monitor PD-equipped submount 210 is formed substantially parallel to a back surface 210c. The surface emission type nitride-based semiconductor laser device 200 are fixed onto the main surface 210b to extend over the recess portion 210a, which is opened to the main surface 210b side of the monitor PD-equipped submount 210, in a direction A.

According to the tenth embodiment, the surface emission type nitride-based semiconductor laser device 200 is a facet light-emitting laser device, and the emission intensity of a laser beam 201a (solid line) emitted from a facet 200a (light-emitting surface) is larger than the emission intensity of a laser beam 201b (broken line) emitted from a facet 200b (light-reflecting surface) of laser beams emitted from a light-emitting layer 115, as shown in FIG. 36. The facet 200a and the facet 200b are examples of the “second cavity facet” and the “first cavity facet” in the present invention, respectively.

Therefore, the monitor PD-equipped submount 210 is so formed that the laser beam 201b emitted from the facet 200b of the surface emission type nitride-based semiconductor laser device 200 to a reflection surface 200c is incident on the PD 211 provided on the monitor PD-equipped submount 210 by the reflection surface 200c having a (000-1) plane, as shown in FIG. 36. At this time, the reflection surface 200c is inclined at an angle θ₈ (=about 43°) with respect to a main surface of an n-type GaN substrate 181, and hence the laser beam 201b is incident substantially perpendicular to the PD 211.

According to the tenth embodiment, as hereinabove described, an emission direction of the laser beam 201b emitted from the facet 200b, having the (000-1) plane, of the light-emitting layer 115 of the surface emission type nitride-based semiconductor laser device 200 is changed to a direction intersecting with the emission direction from the light-emitting layer 115 by the reflection surface 200c having the (000-1) plane which is a facet in crystal growth of the semiconductor laser device layer 112, and the laser beam 201b is incident substantially perpendicular to the PD 211 of the monitor PD-equipped submount 210 by combining the surface emission type nitride-based semiconductor laser device 200 and the monitor PD-equipped submount 210. Thus, the laser beam 201b (sample light monitoring a laser beam intensity of a facet emission laser device) where light scattering is suppressed by the reflection surface 200c having excellent flatness due to a facet formed in crystal growth as a crystal growth surface can be guided to the PD 211, and hence the laser beam intensity can be more precisely measured. The remaining effects of the tenth embodiment are similar to those of the aforementioned ninth embodiment.

### Eleventh Embodiment

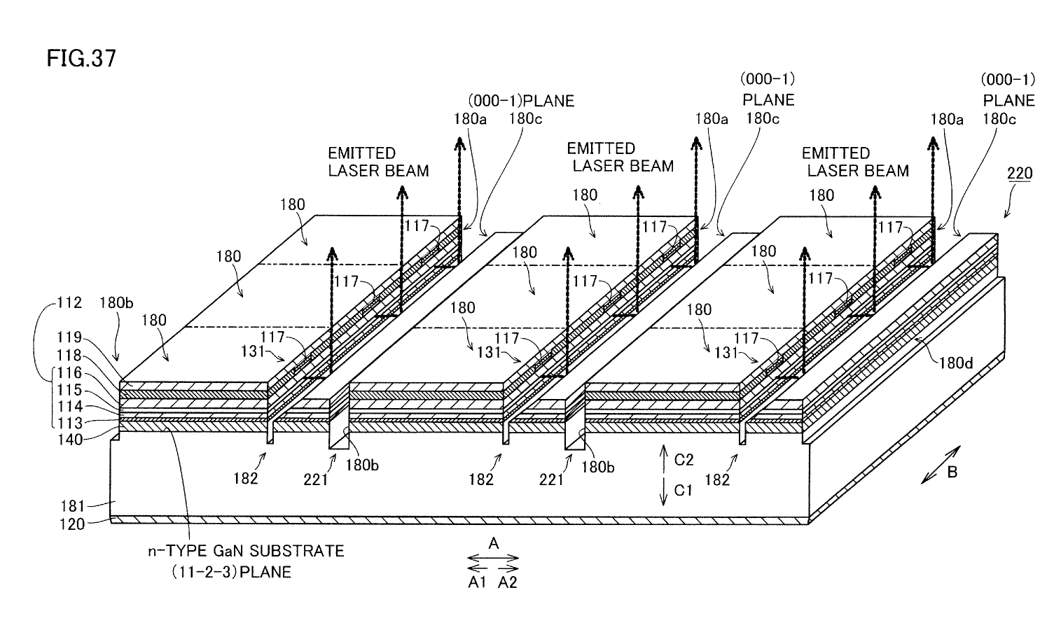

A structure of a surface-emitting laser array 220 according to an eleventh embodiment will be described with reference to FIGS. 33 and 37.

The surface-emitting laser array 220 according to the eleventh embodiment is formed by vertically arranging the three surface emission type nitride-based semiconductor laser devices 180 (see FIG. 33) according to the aforementioned ninth embodiment and laterally arranging the three surface emission type nitride-based semiconductor laser devices 180 (see FIG. 33) according to the aforementioned ninth embodiment (9 in total) on a wafer for allowing two-dimensional array, as shown in FIG. 37.

According to the eleventh embodiment, a semiconductor laser device layer 112 is formed on an n-type GaN substrate 181 through a manufacturing process similar to that of the aforementioned ninth embodiment, and thereafter isolation grooves 221 for isolating the semiconductor laser device layers 112 of the surface emission type nitride-based semiconductor laser devices 180, which are adjacent to each other in a cavity direction (direction A), in the direction A are formed by etching, as shown in FIG. 37. Light-reflecting surfaces 180b of the cavity facets of the respective surface emission type nitride-based semiconductor laser devices 180 are formed on the semiconductor laser device layer 112 by forming the isolation grooves 221.

According to the eleventh embodiment, nine laser beams emitted from light-emitting surfaces 180a of the respective surface emission type nitride-based semiconductor laser devices 180 of the surface-emitting laser array 220 can be emitted upward by changing emission directions to directions ([11-2-3] direction (along arrow C2)) substantially the same with respect to the light-emitting surfaces 180a by reflection surfaces 180c having (000-1) planes, as shown in FIG. 37. As shown in FIG. 37, a facet 180d of the semiconductor laser device layer 112 is formed at an end along arrow A2 of the semiconductor laser device layer 112 by dry etching in the manufacturing process. In FIG. 37, illustrations of parts (p-type contact layer 117 and current blocking layer 118) of the semiconductor laser device layer 112 formed on the reflection surfaces 180c and a p-side electrode 119 are omitted in order to clearly show reflection of laser beams by the reflection surfaces 180c.

According to the eleventh embodiment, as hereinabove described, the nine laser beams emitted from the light-emitting surfaces 180a of the respective surface emission type nitride-based semiconductor laser device 180 are emitted so as to change the emission directions to the direction substantially perpendicular to a main surface of the n-type GaN substrate 181 by reflecting the beams on the reflection surfaces 180c having the (000-1) planes which are facets in crystal growth of the semiconductor laser device layer 112, whereby the surface-emitting laser array 220 is employed as a light source of a surface-emitting laser. Thus, a plurality of laser beams (nine) where light scattering is suppressed by a plurality of the reflection surfaces 180c (nine portions) having excellent flatness due to a facet formed in crystal growth are emitted, and hence the surface-emitting laser improving luminous efficiency can be formed.

### Twelfth Embodiment

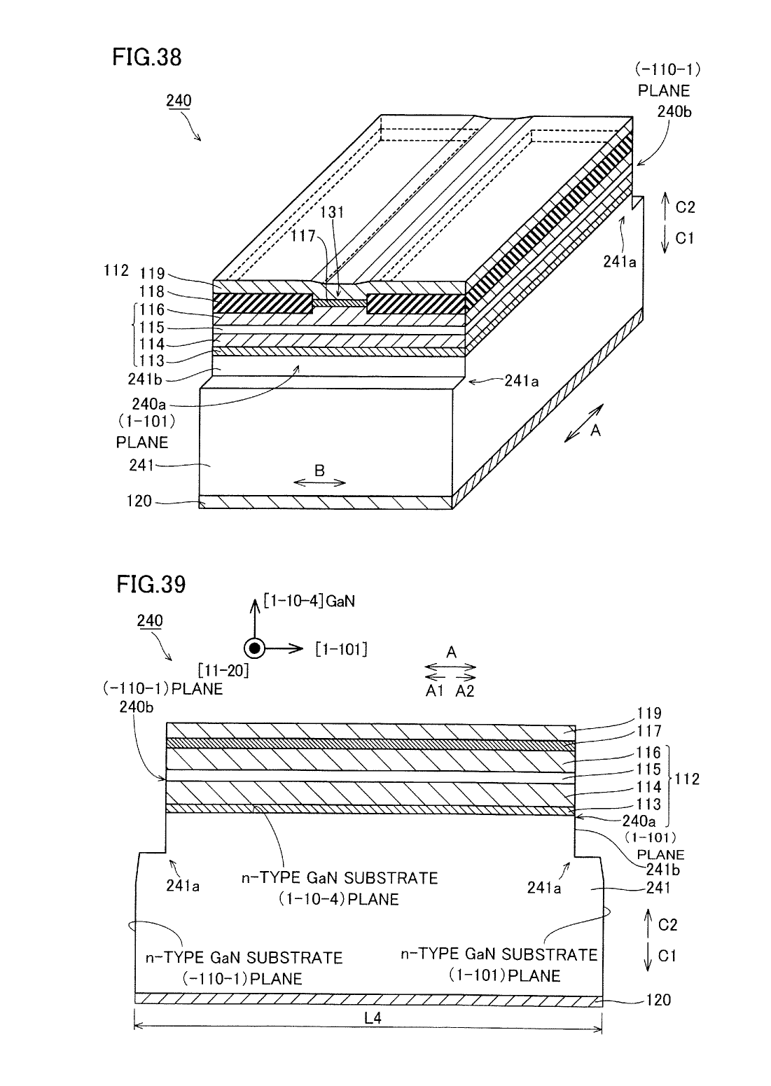

In a nitride-based semiconductor laser device 240 according to a twelfth embodiment, a case where recess portions (grooves 250 described later) extending in a [11-20] direction (direction perpendicular to the plane of FIG. 39) are formed on an n-type GaN substrate 241 having a main surface having a substantially (1-10-4) plane and a semiconductor laser device layer 112 is thereafter formed dissimilarly to the aforementioned sixth embodiment will be described with reference to FIGS. 38 and 39. The n-type GaN substrate 241 and the groove 250 are examples of the “substrate” and the “recess portion” in the present invention, respectively.

In the nitride-based semiconductor laser device 240 according to the twelfth embodiment, step portions 241a are formed at ends in a cavity direction (direction A), as shown in FIG. 38. The semiconductor laser device layer 112 having a thickness of about 3.1 μm is formed on an n-type GaN substrate 241 having a thickness of about 100 μm. The semiconductor laser device layer 112 has a length L4 between laser device ends (in a direction A) of about 1560 μm and a light-emitting surface 240a and a light-reflecting surface 240b substantially perpendicular to the main surface of the n-type GaN substrate 241 are formed at respective both ends of the nitride-based semiconductor laser device 240, as shown in FIG. 39. The light-emitting surface 240a and the light-reflecting surface 240b are examples of the “first cavity facet” and the “second cavity facet” in the present invention, respectively.

According to the twelfth embodiment, the semiconductor laser device layer 112 is formed on the main surface, having the substantially (1-10-4) plane, of the n-type GaN substrate 241. The step portion 241a formed on a lower portion of the light-emitting surface 240a, of the n-type GaN substrate 241 has a facet 241b having a (1-101) plane substantially perpendicular to the main surface of the n-type GaN substrate 241. As shown in FIG. 38, the light-emitting surface 240a of the semiconductor laser device layer 112 has the substantially (1-101) plane formed when being crystal-grown to start from the facet 241b of the n-type GaN substrate 241. The light-reflecting surface 240b of the semiconductor laser device layer 112 has a (−110-1) plane which is a facet perpendicular to a [−110-1] direction (along arrow A1 in FIG. 39).

The device structure of the semiconductor laser device layer 112 of the nitride-based semiconductor laser device 240 according to the twelfth embodiment is similar to that of the aforementioned sixth embodiment.

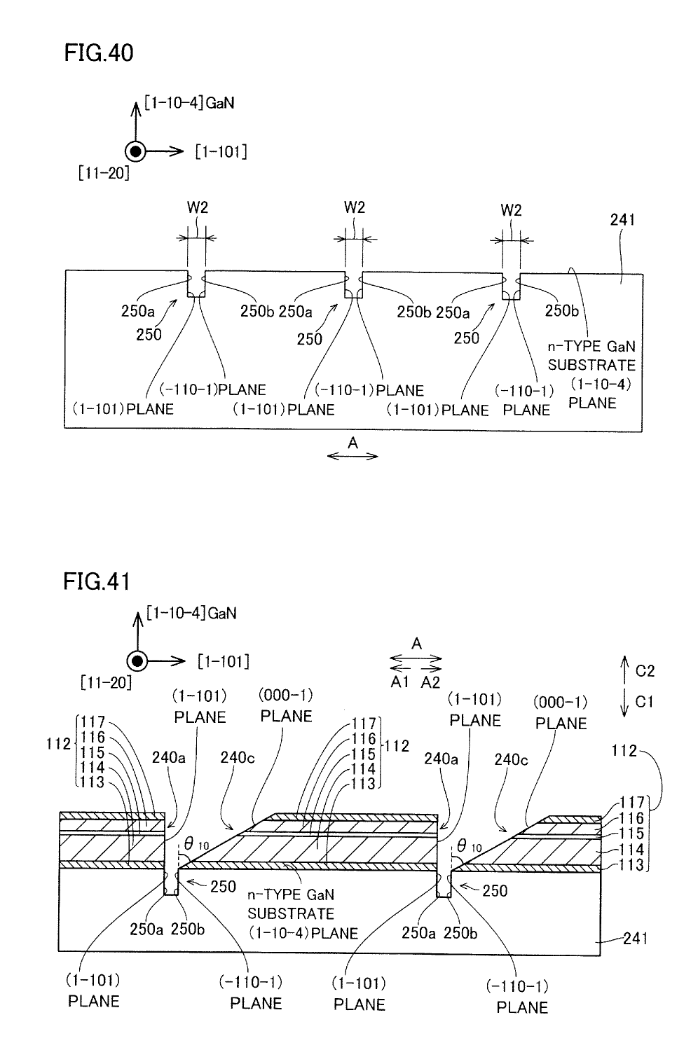

The manufacturing process of the nitride-based semiconductor laser device 240 according to the twelfth embodiment will be now described with reference to FIGS. 38 to 42.

The grooves 250 having a width W2 of about 40 μm in a [1-101] direction (direction A) and a depth of about 2 μm and extending in the [11-20] direction (direction B) are formed on the main surface, having the substantially (1-10-4) plane, of the n-type GaN substrate 241 by etching. The grooves 250 are formed in the direction A in a period of about 1560 μm (=L4). The semiconductor laser device layer 112 is crystal-grown on the n-type GaN substrate 241 by MOCVD.

According to the twelfth embodiment, as shown in FIG. 41, the semiconductor laser device layer 112 is crystal-grown on inner side surfaces 250a having the (1-101) planes of the grooves 250, while forming the (1-101) planes extending in the [1-10-4] direction (along arrow C2) to start the (1-101) planes of the grooves 250. Thus, the (1-101) planes of the semiconductor laser device layer 112 are formed as the light-emitting surfaces 240a of the nitride-based semiconductor laser device 240.

According to the twelfth embodiment, the semiconductor laser device layer 112 is crystal-grown on the (−110-1) planes (inner side surfaces 250b) opposed to the (1-101) planes of the grooves 250, while forming (000-1) facets 240c extending in a direction inclined at an angle θ₁₀ (=about 65°) with respect to the [1-10-4] direction (along arrow C2). Therefore, the facets 240c form obtuse angles with respect to an upper surface (main surface) of the semiconductor laser device layer 112. Each of the inner side surfaces 250a and 250b is an example of the “inner side surface of the recess portion” in the present invention.

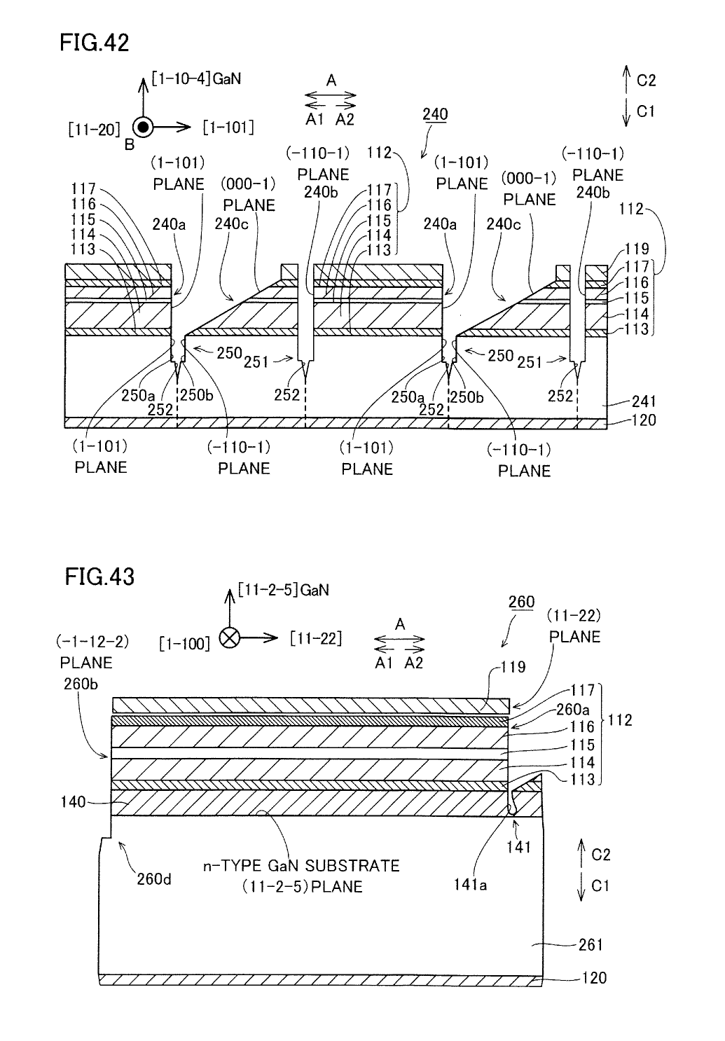

Thereafter, a current blocking layer 118 (see FIG. 38) a p-side electrode 119 are formed on the semiconductor laser device layer 112 through the manufacturing process similar to that of the aforementioned sixth embodiment, as shown in FIG. 42. A back surface of the n-type GaN substrate 241 is polished, and an n-side electrode 120 is thereafter formed on the back surface of the n-type GaN substrate 241 by vacuum evaporation, as shown in FIG. 42.

In the manufacturing process according to the twelfth embodiment, as shown in FIG. 42, positions to be formed with prescribed cavity facets are dry-etched in a direction (along arrow C1) reaching the n-type GaN substrate 241 from the surface (upper surface) of the semiconductor laser device layer 112, whereby grooves 251 in which first side surfaces of the semiconductor laser device layer 112 have the flat substantially (−110-1) planes are formed. Thus, the substantially (−110-1) planes, which are first side surfaces of the grooves 251, are easily formed as the light-reflecting surfaces 240b of the nitride-based semiconductor laser device 240. The grooves 251 are formed to extend in the [11-20] direction (direction B in FIG. 42) substantially parallel to a direction in which the grooves 250 extend in plan view.

As shown in FIG. 42, a scribing groove 252 is formed parallel to the groove 250 in each of the grooves 250 and 251. In this state, a wafer is separated on a position of the scribing groove 252, as shown in FIG. 42. The groove 250 of the n-type GaN substrate 241 becomes a step portion 241a formed on a lower portion of the light-emitting surface 240a after device division, as shown in FIG. 38.

The device is divided along the cavity direction (direction A in FIG. 39) into chips, thereby forming the nitride-based semiconductor laser device 240 according to the twelfth embodiment shown in FIG. 38.

According to the twelfth embodiment, as hereinabove described, the nitride-based semiconductor laser device 240 comprises the light-emitting surface 240a having the substantially (1-101) plane substantially perpendicular to the main surface of the n-type GaN substrate 241, whereby the light-emitting surface 240a having the (1-101) plane can be formed to start the inner side surface 250a having the (1-101) plane of the groove 250 formed in the n-type GaN substrate 241 while crystal growing the semiconductor laser device layer 112 in the manufacturing process. Thus, the light-emitting surface 240a can be formed without employing etching process also in a case where the (1-101) plane with no cleavage is the cavity facet. The light-emitting surface 240a having the (1-101) plane is formed by crystal growth, whereby flatness of a surface (main surface) of a growth layer can be improved as compared with surfaces of a growth layer of a nitride-based semiconductor device layer in a case of not forming the (1-101) facet. The remaining effects of the twelfth embodiment are similar to those of the aforementioned sixth embodiment.

### Thirteenth Embodiment

In a nitride-based semiconductor laser device 260 according to a thirteenth embodiment, a case where an underlayer 140 and a semiconductor laser device layer 112 are formed on an n-type GaN substrate 261 having a main surface having a substantially (11-2-5) plane dissimilarly to the aforementioned sixth embodiment will be described with reference to FIG. 43. The n-type GaN substrate 261 is an example of the “substrate” in the present invention.

According to the thirteenth embodiment, the semiconductor laser device layer 112 is formed on the maim surface, having a substantially (1-10-2) plane, of the n-type GaN substrate 261 through the underlayer 140. A light-emitting surface 260a of the semiconductor laser device layer 112 has a (11-22) facet formed when being crystal-grown to start an inner side surface 141a of a crack 141 of the underlayer 140. A light-reflecting surface 260b of the semiconductor laser device layer 112 has a (−1-12-2) plane which is a facet perpendicular to a [11-22] direction (along arrow A2 in FIG. 43). The light-emitting surface 260a and the light-reflecting surface 260b are examples of the “first cavity facet” and the “second cavity facet” in the present invention, respectively. A step portion 260d is formed on a lower portion of the light-reflecting surface 260b.

A device structure of the semiconductor laser device layer 112 of the nitride-based semiconductor laser device 260 according to the thirteenth embodiment is similar to that of the aforementioned sixth embodiment.

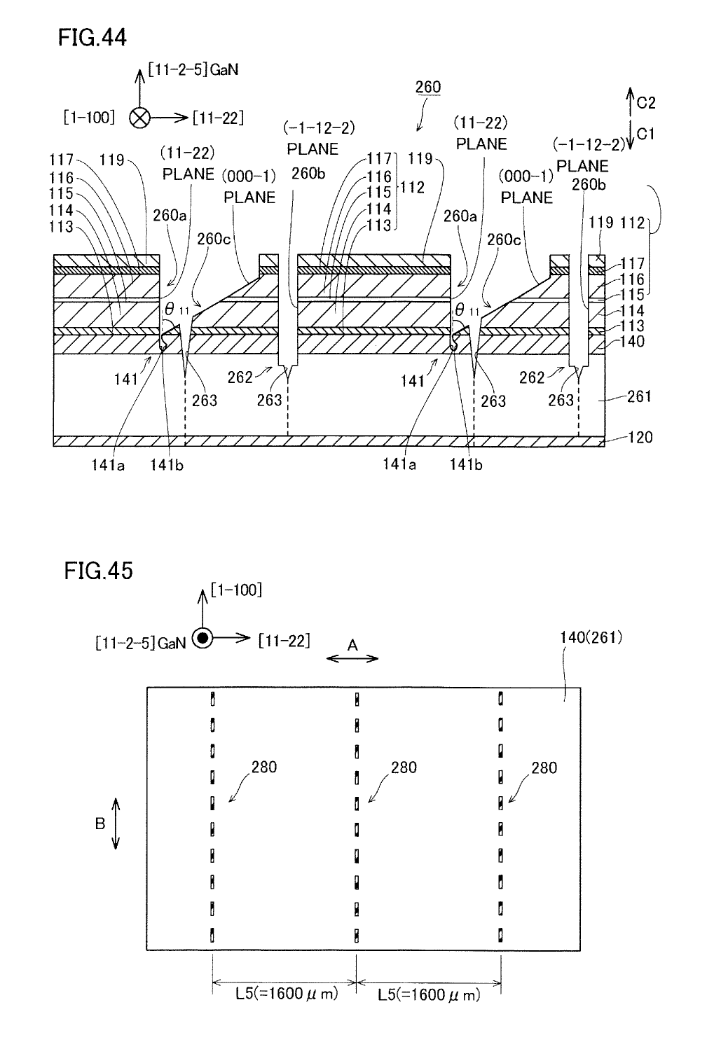

A manufacturing process of the nitride-based semiconductor laser device 260 according to the thirteenth embodiment will be now described with reference to FIGS. 43 and 44.

According to the thirteenth embodiment, the underlayer 140 is grown on the n-type GaN substrate 261 through the manufacturing process similar to that of the aforementioned sixth embodiment. The cracks 141 are formed due to difference between lattice constants of the n-type GaN substrate 261 and the underlayer 140. Further, the cracks 141 are formed in a striped manner along a [1-100] direction (direction perpendicular to the plane of FIG. 44).

Thereafter, the semiconductor laser device layer 112 is formed on the underlayer 140 through the manufacturing process similar to that of the sixth embodiment, as shown in FIG. 44.

According to the thirteenth embodiment, as shown in FIG. 44, when the semiconductor laser device layer 112 is grown on the underlayer 140, the semiconductor laser device layer 112 is crystal-grown on the inner side surfaces 141a of the cracks 141 extending in the striped manner in the [1-100] direction, while forming the (11-22) planes extending in a [11-2-5] direction (along arrow C2). Thus, the (11-22) planes of the semiconductor laser device layer 112 are formed as the light-emitting surfaces 260a of the nitride-based semiconductor laser device 260.

According to the thirteenth embodiment, the semiconductor laser device layer 112 is crystal-grown on inner side surfaces 141b of the cracks 141, while forming (000-1) facets 260c extending in a direction inclined at an angle θ₁₁ (=about 57°) with respect to the [11-2-5] direction (along arrow C2).

A current blocking layer 118 (see FIG. 3) and a p-side electrode 119 are formed on the semiconductor laser device layer 112, as shown in FIG. 44. A back surface of the n-type GaN substrate 261 is polished, and an n-side electrode 120 is thereafter formed on the back surface of the n-type GaN substrate 261 by vacuum evaporation, as shown in FIG. 44.

According to the thirteenth embodiment, as shown in FIG. 44, positions to be formed with prescribed cavity facets are dry-etched in a direction (along arrow C1) reaching the n-type GaN substrate 261 from a surface (upper surface) of the semiconductor laser device layer 112, whereby grooves 162 in which first side surfaces of the semiconductor laser device layer 112 have the flat substantially (−1-12-2) planes are formed. Thus, the substantially (−1-12-2) planes, which are first side surfaces of the grooves 162, are easily formed as the light-reflecting surfaces 260b of the nitride-based semiconductor laser device 260. The grooves 162 are formed to extend in the [1-100] direction (direction B) substantially parallel to a direction in which the cracks 141 extend in plan view.

As shown in FIG. 44, a scribing groove 263 is formed parallel to the groove 162 in each of the cracks 141 and the grooves 162 by laser scribing or mechanical scribing. In this state, a wafer is separated on a position of the scribing groove 263, as shown in FIG. 44. The groove 162 of the n-type GaN substrate 261 becomes a step portion 260d formed on a lower portion of the light-reflecting surface 260b after device division, as shown in FIG. 43.

The device is divided along a cavity direction (direction A in FIG. 43) into chips, thereby forming the nitride-based semiconductor laser device 260 according to the thirteenth embodiment shown in FIG. 43.

According to the thirteenth embodiment, as hereinabove described, the nitride-based semiconductor laser device 260 comprises the light-emitting surface 260a having the substantially (11-22) plane substantially perpendicular to the main surface of the n-type GaN substrate 261, whereby the light-emitting surface 260a having the (11-22) plane can be formed to start the inner side surface 141a of the crack 141 formed in the n-type GaN substrate 261 while crystal growing the semiconductor laser device layer 112 in the manufacturing process. Thus, the light-emitting surface 260a can be formed without employing etching process also in a case where the (11-22) plane with no cleavage is the cavity facet. The light-emitting surface 260a having the (11-22) plane is formed by crystal growth, whereby flatness of the surface (main surface) of the growth layer can be improved. The remaining effects of the thirteenth embodiment are similar to those of the aforementioned twelfth embodiment.

(Modification of Thirteenth Embodiment)

In a manufacturing process according to a modification of the thirteenth embodiment, a case where cracks 281, positions of which are controlled by forming skipped shaped scribing cracks 280 on an underlayer 140 on an n-type GaN substrate 261, are formed dissimilarly to the aforementioned thirteenth embodiment will be described with reference to FIGS. 22 and 43 to 46. The crack 281 is an example of the “recess portion” in the present invention.

According to the modification of the thirteenth embodiment, as shown in FIG. 45, the underlayer 140 having a critical thickness smaller than the thickness (about 3 μm to about 4 μm) described in the aforementioned thirteenth embodiment is grown on the n-type GaN substrate 261 (see FIG. 44). At this time, tensile stress R (see FIG. 22) is caused inside the underlayer 140 due to action similar to the aforementioned thirteenth embodiment.

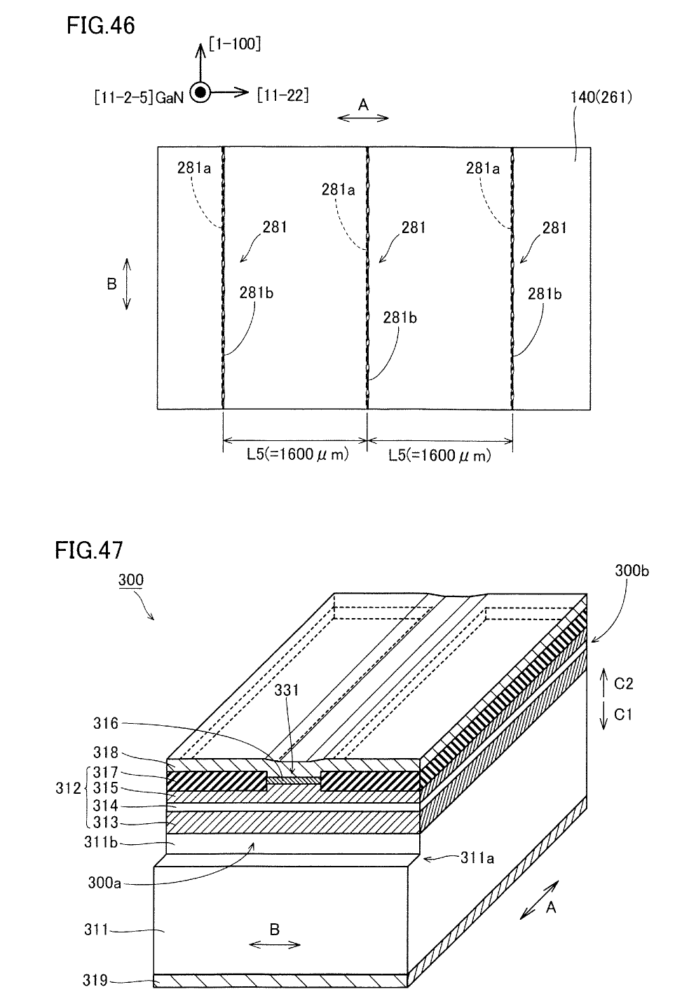

Thereafter, the skipped scribing cracks 280 (with an interval of about 40 μm) extending in a direction B are formed in the underlayer 140 in a direction A at an interval L5 (=about 1600 μm) by a laser beam or a diamond point, as shown in FIG. 45. Thus, in the underlayer 140, formation of the cracks proceeds on regions of the underlayer 140 formed with no scribing crack 280 to starting from the skipped scribing cracks 280, as shown in FIG. 46. Consequently, substantially linear cracks 281 dividing the underlayer 140 in the direction B are formed.

In this case, division of the scribing cracks 280 in a depth direction (direction perpendicular to the plane of FIG. 45) also proceeds. Thus, inner side surfaces 281a (shown by broken lines in FIG. 46) reaching in the vicinity of an interface between the underlayer 140 and the n-type GaN substrate 261 are formed on the cracks 281. The inner side surfaces 281a are formed substantially perpendicular to a main surface, having a (11-2-5) plane, of the n-type GaN substrate 261. The inner side surface 281a is an example of the “inner side surface of the recess portion” in the present invention.

A semiconductor laser device layer 112 is crystal-grown on inner side surfaces 281b (see FIG. 46) opposed to the inner side surfaces 281a of the cracks 281, while forming (000-1) facets 260c (see FIG. 44) extending in a direction inclined at a prescribed angle (about 57°) with respect to a [11-2-5] direction, similarly to the aforementioned thirteenth embodiment. The inner side surface 281b is an example of the “inner side surface of the recess portion” in the present invention. The remaining device structure and manufacturing process of the nitride-based semiconductor laser device 260 (see FIG. 44) according to the modification of the thirteenth embodiment are similar to those of the aforementioned thirteenth embodiment.

In the manufacturing process according to the modification of the thirteenth embodiment, as hereinabove described, the underlayer 140 is formed on the n-type GaN substrate 261 to have a substantially critical thickness when forming the cracks 281, and thereafter the skipped scribing cracks 280 (with an interval of about 40 μm) extending in the direction B are formed in the direction A at a regular interval in the underlayer 140, whereby the cracks 281 are formed parallel to the direction B and at the regular interval in a cavity direction on the underlayer 140 to start from the skipped scribing cracks 280. Thus, the nitride-based semiconductor laser device 260 (see FIG. 29) having the same cavity length can be more easily formed. The remaining effects of the modification of the thirteenth embodiment are similar to those of the aforementioned thirteenth embodiment.

### Fourteenth Embodiment

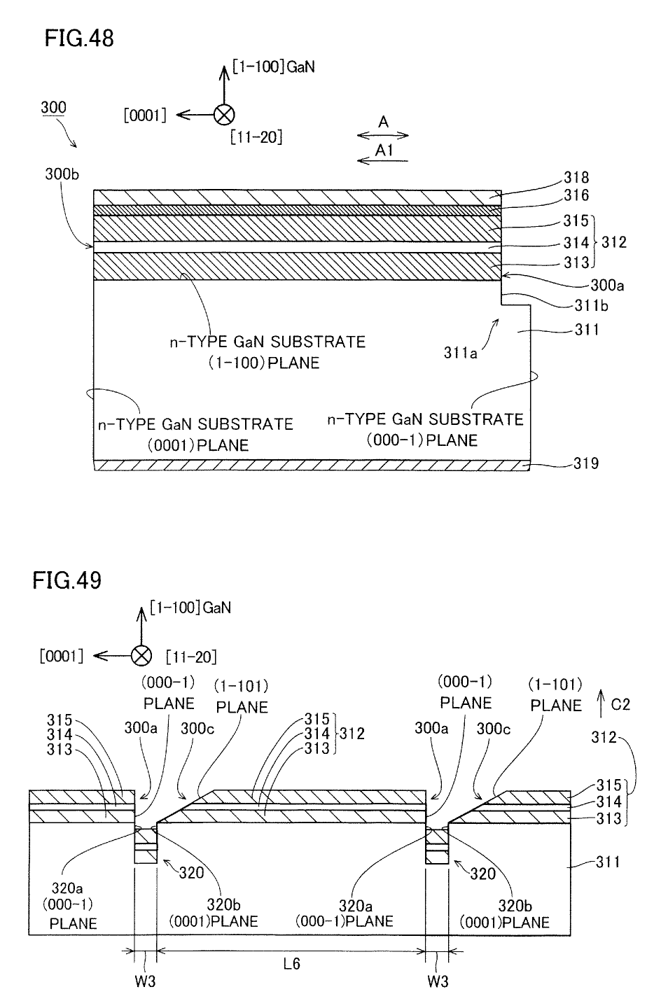

A structure of a nitride-based semiconductor laser device 300 formed by a forming method according to a fourteenth embodiment will be described with reference to FIGS. 47 and 48.

In the nitride-based semiconductor laser device 300 formed by the forming method according to the fourteenth embodiment, a step portion 311a is formed at a first end in a cavity direction (direction A) (end of a light-emitting surface 300a), as shown in FIG. 47. A semiconductor laser device layer 312 having a thickness of about 3.1 μm is formed on an n-type GaN substrate 311 having a thickness of about 100 μm. The semiconductor laser device layer 312 has a cavity length of about 1500 μm and formed with the light-emitting surface 300a and a light-reflecting surface 300b substantially perpendicular to a main surface of the n-type GaN substrate 311 on the both ends in the cavity direction (direction A) which is a [0001] direction, as shown in FIG. 48. The n-type GaN substrate 311 and the semiconductor laser device layer 312 are examples of the “substrate” and the “nitride-based semiconductor layer” in the present invention, respectively, and the light-emitting surface 300a is examples of the “first side surface” and the “crystal growth facet” in the present invention.

According to the fourteenth embodiment, the semiconductor laser device layer 312 is formed on the main surface having a (1-100) plane of the n-type GaN substrate 311. The step portion 311a of the n-type GaN substrate 311 has a facet 311b having a (000-1) plane substantially perpendicular to the main surface of the n-type GaN substrate 311. As shown in FIG. 48, the light-emitting surface 300a of the semiconductor laser device layer 312 has a (000-1) facet formed when being crystal-grown to start from the facet 311b of the n-type GaN substrate 311. The light-reflecting surface 300b of the semiconductor laser device layer 312 has a (0001) plane which is a facet perpendicular to the [0001] direction (along arrow A1 in FIG. 48).

The semiconductor laser device layer 312 includes an n-type cladding layer 313 made of AlGaN having a thickness of about 3 μm and an active layer 314 formed by alternately stacking three quantum well layers made of InGaN having a thickness of about 75 nm and three barrier layers made of GaN successively from a side closer to a upper surface of the n-type GaN substrate 311, as shown in FIG. 47. A p-type cladding layer 315 made of AlGaN having a planar portion having a thickness of about 0.05 μm and a projecting portion formed to protrude upward (along arrow C2) from a substantially central portion of the planar portion and having a thickness of about 1 μm is formed on the active layer 314, as shown in FIG. 47. A p-type contact layer 316 made of undoped In_{0.07}Ga_{0.93}N having a thickness of about 3 nm is formed on the projecting portion of the p-type cladding layer 315. A ridge 331 of the nitride-based semiconductor laser device 300 is constituted by the projecting portion of the p-type cladding layer 315 and the p-type contact layer 316. The n-type cladding layer 313, the active layer 314, the quantum well layer, the barrier layer, the p-type cladding layer 315 and the p-type contact layer 316 are each an example of the “nitride-based semiconductor layer” in the present invention.

As shown in FIG. 47, a current blocking layer 317 made of SiO₂ having a thickness of about 0.1 μm is formed to cover an upper surface of the planar portion other than the projecting portion of the p-type cladding layer 315 of the semiconductor laser device layer 312 and both side surfaces of the ridge 331.

A p-side electrode 318 formed by a Pt layer having a thickness of about 5 nm, a Pd layer having a thickness of about 100 nm and an Au layer having a thickness of about 150 nm is formed on a region (vicinity of a central portion in the direction B in FIG. 47) formed with no current blocking layer 317 on the upper surface of the p-type cladding layer 315. The p-side electrode 318 is formed to cover an upper surface of the current blocking layer 317. A contact layer preferably having a smaller band gap than the p-type cladding layer 315 may be formed between the p-type cladding layer 315 and the p-side electrode 318.

As shown in FIG. 47, an n-side electrode 319 formed by an Al layer having a thickness of about 10 nm, a Pt layer having a thickness of about 20 nm and an Au layer having a thickness of about 300 nm is formed on a back surface of the n-type GaN substrate 311 successively from a side closer to the n-type GaN substrate 311.

A manufacturing process of the nitride-based semiconductor laser device 300 according to the fourteenth embodiment will be now described with reference to FIGS. 47 to 50.

As shown in FIG. 49, grooves 320 having a width W3 of about 10 μm in a [0001] direction and a depth of about 2 μm and extending in a [11-20] direction are formed on the main surface, having the (1-100) plane, of the n-type GaN substrate 311 by etching. The grooves 320 are formed in the [0001] direction in a period of about 1600 μm (=W3+L6).

According to the fourteenth embodiment, the grooves 320 are formed with inner side surfaces 320a having the (000-1) planes substantially perpendicular to the (1-100) plane of the n-type GaN substrate 311 and inner side surfaces 320b having (0001) planes substantially perpendicular to the (1-100) plane of the n-type GaN substrate 311, as shown in FIG. 49. The groove 320, the inner side surface 320a and the inner side surface 320b are examples of the “recess portion”, the “first inner side surface of the recess portion” and the “second inner side surface of the recess portion” in the present invention, respectively.

The n-type cladding layer 313, the active layer 314, the p-type cladding layer 315 and the p-type contact layer 316 (see FIG. 47) are successively stacked on the n-type GaN substrate 311 having the grooves 320, thereby forming the semiconductor laser device layer 312. FIG. 49 shows a sectional structure taken along the cavity direction of portions, not formed with the p-type contact layer 316 (see FIG. 47) of the semiconductor laser device layer 312.

According to the fourteenth embodiment, when the semiconductor laser device layer 312 is grown on the n-type GaN substrate 311, the semiconductor laser device layer 312 is crystal-grown on the inner side surfaces 320a having the (000-1) planes of the grooves 320 extending in the [11-20] direction, while forming the (000-1) planes extending in a [1-100] direction (along arrow C2) to start from the (000-1) planes of the grooves 320 inner side surfaces 85a, as shown in FIG. 49. Thus, the (000-1) plane of the semiconductor laser device layer 312 is formed as the light-emitting surface 300a in the nitride-based semiconductor laser device 300.

According to the fourteenth embodiment, the semiconductor laser device layer 312 is crystal-grown on the (0001) planes (inner side surfaces 320b) opposed to the (000-1) planes of the grooves 320, while forming (1-101) facets 300c extending in a direction inclined at a prescribed angle with respect to the [1-100] direction.

The facet 300c is examples of the “second side surface” and the “crystal growth facet” in the present invention. Thus, the facets 300c form obtuse angles with respect to an upper surface (main surface) of the semiconductor laser device layer 312.

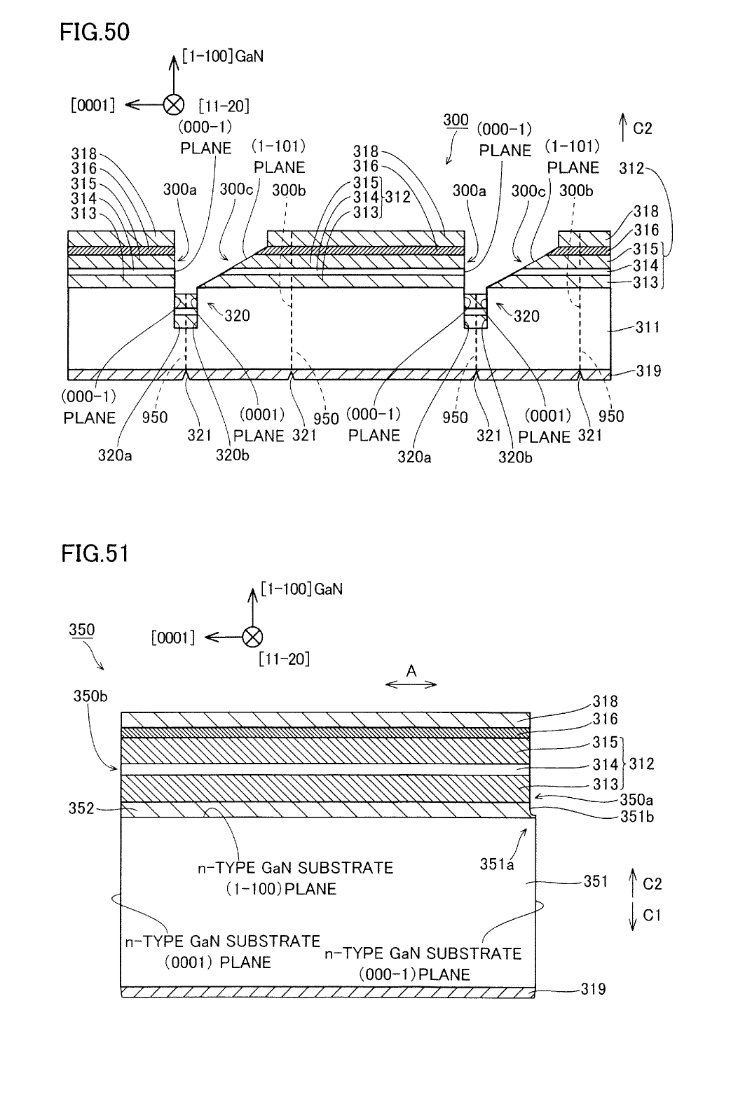

Then, p-type annealing treatment is performed in a nitrogen gas atmosphere under a temperature condition of about 800° C. As shown in FIG. 47, the ridge 331 is formed on an upper surface of the p-type contact layer 316, and thereafter the current blocking layer 317 is formed to cover the upper surface of the planar portion other than the projecting portion of the p-type cladding layer 315 and both the side surfaces of the ridge 331. As shown in FIGS. 47 and 50, the p-side electrode 318 is formed on the current blocking layer 317 and the p-type contact layer 316 not formed with the current blocking layer 317. FIG. 50 shows a sectional structure taken along the cavity direction of the semiconductor laser device located on the position formed with the p-type contact layer 316.

As shown in FIG. 50, a back surface of the n-type GaN substrate 311 is so polished that a thickness of the n-type GaN substrate 311 reaches a thickness of about 100 μm, and the n-side electrode 319 is thereafter formed on the back surface of the n-type GaN substrate 311.

As shown in FIG. 50, linear scribing grooves 321 are so formed on positions corresponding to the (000-1) semiconductor facets on a back surface of the n-side electrode 319 and positions to be formed with prescribed (0001) planes as to extend parallel to the grooves 320 of the n-type GaN substrate 311 (in the direction B in FIG. 47) by laser scribing or mechanical scribing. In this state, the wafer is cleaved on the position of each scribing groove 321 by applying a load while fulcruming the back surface of the n-type GaN substrate 311 so that a surface of the wafer opens, as shown in FIG. 50. Thus, the (0001) plane of the semiconductor laser device layer 312 is formed as the light-reflecting surface 300b in the nitride-based semiconductor laser device 300. The n-type GaN substrate 311 on a region corresponding to each groove 321 is divided along a cleavage line 950 connecting the groove 320 and the corresponding scribing groove 321. The groove 320 of the n-type GaN substrate 311 becomes the step portion 311a formed on a lower portion of the light-emitting surface 300a after device division, as shown in FIG. 48.

The device is divided along the cavity direction (direction A in FIG. 47) into chips, thereby forming the nitride-based semiconductor laser device 300 by the method of forming the nitride-based semiconductor layer according to the fourteenth embodiment shown in FIG. 47.

As hereinabove described, the manufacturing process of the nitride-based semiconductor laser device 300 according to the fourteenth embodiment comprises steps of forming the grooves 320 on the main surface ((1-100) plane) of the n-type GaN substrate 311 and forming the semiconductor laser device layer 312 having the light-emitting surfaces 300a having the (000-1) planes by employing the inner side surfaces 320a of the grooves 320 as stating points, whereby when the semiconductor laser device layer 312 is crystal-grown on the n-type GaN substrate 311, a growth rate of forming the (000-1) planes starting from the inner side surfaces 320a of the grooves 320 is slower than a growth rate of growing the upper surface (main surface of the semiconductor laser device layer 312) of the growth layer, and hence the upper surface (main surface) of the growth layer is grown while maintaining flatness.

A surface energy of a plane having a slow growth rate such as the (000-1) plane is conceivably small, and a surface energy of a plane having a fast growth rate such as the (1-100) plane is conceivably large. The smaller a surface energy of a surface during crystal growth is, the more the surface is stable, and hence a plane having a smaller surface energy than the (1-100) plane, other than the (1-100) plane is easy to come out when performing crystal growth by employing only the (1-100) plane as a growth surface. Consequently, flatness of the growth surface (main surface) is easy to be destroyed. According to the fourteenth embodiment, on the other hand, the (1-100) plane is grown while forming the (000-1) plane having a small surface energy, and hence a surface energy of the growth surface can be reduced as compared with a case of performing crystal growth by employing only the (1-100) plane as a growth surface. Thus, flatness of the growth surface is conceivably improved. From the aforementioned consideration, flatness of the surface of the semiconductor laser device layer 312 having the active layer 314 can be further improved as compared with surfaces of a growth layer of the semiconductor laser device layer 312 with no (000-1) facet.

Further, the manufacturing process comprises the step of forming the semiconductor laser device layer 312 having the light-emitting surfaces 300a having the (000-1) planes by employing the inner side surfaces 320a of the grooves 320 as starting points, whereby not only the upper surface of the growth layer but also the light-emitting surfaces 300a can be formed as flat facets having the (000-1) planes. Therefore, the semiconductor laser device layer 312 (active layer 314) having cavity facets having the (000-1) planes can be formed with no cleavage step by applying the method of forming a nitride-base semiconductor layer of this invention to a method of forming a semiconductor laser device.

In the manufacturing process of the nitride-based semiconductor laser device 300 according to the fourteenth embodiment, the step of forming the semiconductor laser device layer 312 includes the step of forming the semiconductor laser device layer 312 having the facets 300c on regions opposed to the light-emitting surfaces 300a including the (000-1) planes by employing the inner side surfaces 320b of the grooves 320 as starting points, whereby when the semiconductor laser device layer 312 is crystal-grown on the n-type GaN substrate 311, a growth rate of forming the facets 300c starting from the inner side surfaces 320b of the grooves 320 is slower than the growth rate of growing the upper surface (main surface of the semiconductor laser device layer 312) of the growth layer, and hence the upper surface (main surface) of the growth layer is grown while maintaining flatness. Thus, flatness of the surface of the semiconductor laser device layer 312 having the active layer 314 can be further improved as compared with surfaces of a growth layer of the semiconductor laser device layer 312 with neither the light-emitting surfaces 300a nor the facets 300c.

In the manufacturing process of the nitride-based semiconductor laser device 300 according to the fourteenth embodiment, the inner side surfaces 320a of the grooves 320 include the (000-1) planes, whereby when the semiconductor laser device layer 312 having the light-emitting surfaces 300a having the (000-1) planes is formed on the main surface of the substrate, the (000-1) planes of the semiconductor laser device layer 312 are formed to start the (000-1) planes of the inner side surfaces 320a of the grooves 320, and hence the light-emitting surfaces 300a having the (000-1) planes can be easily formed on the n-type GaN substrate 311.

In the manufacturing process of the nitride-based semiconductor laser device 300 according to the fourteenth embodiment, the light-emitting surfaces 300a and the facets 300c of the semiconductor laser device layer 312 have facets formed in crystal growth, of the semiconductor laser device layer 312, whereby two types of the facets of the light-emitting surfaces 300a and the facets 300c can be formed simultaneously with the crystal growth of the semiconductor laser device layer 312.

In the manufacturing process of the nitride-based semiconductor laser device 300 according to the fourteenth embodiment, the facets 300c have the (1-101) planes, whereby the main surface (upper surface) of the growth layer can be reliably formed to have flatness in forming the (1-101) facets 300c on the n-type GaN substrate 311 as compared with an upper surface (main surface) of a growth layer of the semiconductor laser device layer 312 in forming side surfaces (facets) of the growth layer plain orientations of which are greatly different from those of the (1-101) planes on the n-type GaN substrate 311. The (1-101) plane is a plane equivalent to a (10-11) plane which is an example of a {A+B, A, −2A−B, 2A+B} plane. The reason why the growth surface can be formed to have flatness as described above is because flatness of the (1-100) plane becoming the main surface is conceivably improved since the surface energy of the growth surface can be reduced by growing the {A+B, A, −2A−B, 2A+B} plane having a slower growth rate than the (1-100) plane as the side surface while growing the (1-100) plane as the main surface. The growth rate of the (1-101) facets 300c is slower than the growth rate of the main surface of the semiconductor laser device layer 312, and hence the facets 300c can be easily formed by crystal growth.

In the manufacturing process of the nitride-based semiconductor laser device 300 according to the fourteenth embodiment, the substrate is formed to be the n-type GaN substrate 311 made of a nitride-based semiconductor such as GaN, whereby the semiconductor laser device layer 312 having the light-emitting surfaces 300a having the (000-1) planes and the (1-101) facets 300c can be easily formed by utilizing crystal growth of the semiconductor laser device layer 312 on the n-type GaN substrate 311 made of a nitride-based semiconductor.

In the manufacturing process of the nitride-based semiconductor laser device 300 according to the fourteenth embodiment, the light-emitting surfaces 300a of the semiconductor laser device layer 312 are formed to be substantially perpendicular to the main surface ((1-100) plane) of the n-type GaN substrate 311, whereby the semiconductor laser device layer 312 (active layer 314) having the cavity facets having the light-emitting surfaces 300a can be easily formed without a cleavage step.

In the manufacturing process of the nitride-based semiconductor laser device 300 according to the fourteenth embodiment, the semiconductor laser device layer 312 is formed on the n-type GaN substrate 311 having the main surface having a nonpolar face ((1-100) plane), whereby a piezoelectric field caused in the semiconductor device layer (active layer 314) or an internal electric field such as intrinsic polarization can be further reduced. Thus, the nitride-based semiconductor laser device 300 where luminous efficiency of a laser beam is improved can be formed.

### Fifteenth Embodiment

In a manufacturing process of a nitride-based semiconductor laser device 350 according to a fifteenth embodiment, a case where a semiconductor laser device layer 312 is formed after forming an underlayer 352 on an n-type GaN substrate 351 dissimilarly to the aforementioned fourteenth embodiment will be described with reference to FIGS. 51 to 53. The n-type GaN substrate 351 is an example of the “base substrate” in the present invention.

In the nitride-based semiconductor laser device 350 formed by a forming method according to the fifteenth embodiment, a step portion 351a is formed at a first end in a cavity direction (direction A) (end on a light-emitting surface 350a), as shown in FIG. 51. The semiconductor laser device layer 312 having a structure similar to that of the fourteenth embodiment is formed on the n-type GaN substrate 351 having a main surface having a (1-100) plane. The semiconductor laser device layer 312 has a cavity length of about 1500 μm and formed with the light-emitting surface 350a and a light-reflecting surface 350b substantially perpendicular to the main surface of the n-type GaN substrate 351 on the both ends in the cavity direction (direction A) which is a [0001] direction. The light-emitting surface 350a is examples of the “first side surface” and the “crystal growth facet” in the present invention.

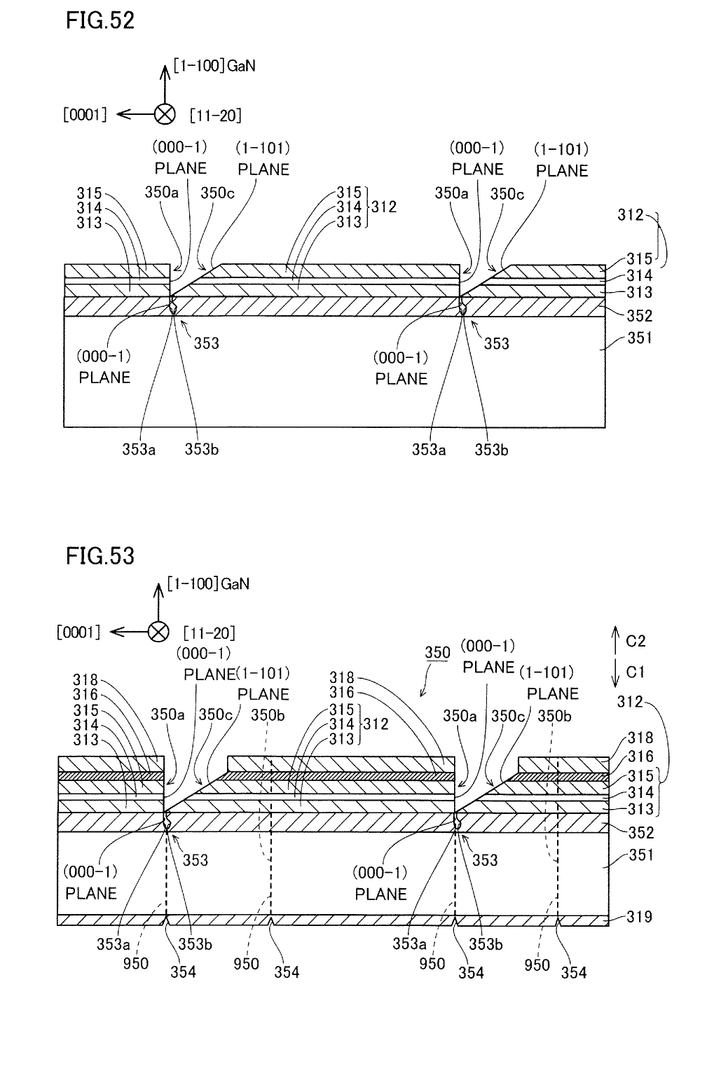

According to the fifteenth embodiment, the underlayer 352 is formed between the n-type GaN substrate 351 and the semiconductor laser device layer 312 as shown in FIG. 51, dissimilarly to the manufacturing process of the nitride-based semiconductor laser device 300 according to the aforementioned fourteenth embodiment. More specifically, the underlayer 352 made of AlGaN having a thickness of about 3 μm to 4 μm is grown on the n-type GaN substrate 351, as shown in FIG. 52. At this time, cracks 353 are formed in the underlayer 352 due to difference between lattice constants in the [0001] direction, of the n-type GaN substrate 351 and the underlayer 352.

When the n-type GaN substrate 351 formed with the cracks 353 is viewed in a planar manner, the cracks 353 are formed in a striped manner along a [11-20] direction substantially orthogonal to the [0001] direction of the n-type GaN substrate 353. The crack 353 is an example of the “recess portion” in the present invention.

According to the fifteenth embodiment, when the cracks 353 are formed in the underlayer 352, inner side surfaces 353a including (000-1) planes of an AlGaN layer and reaching in the vicinity of the (1-100) plane of an upper surface of the n-type GaN substrate 351 are formed on the cracks 353. The inner side surfaces 353a are formed substantially perpendicular to the main surface, having the (1-100) plane, of the n-type GaN substrate 351. The inner side surface 353a is an example of the “first inner side surface of the recess portion” in the present invention.

As shown in FIG. 52, an n-type cladding layer 313, an active layer 314, a p-type cladding layer 315 and a p-type contact layer 316 (see FIG. 51) are successively stacked on the underlayer 352 through a manufacturing process similar to that of the fourteenth embodiment, thereby forming the semiconductor laser device layer 312. FIG. 52 shows a sectional structure taken along the cavity direction (direction A) of portions, not formed with the p-type contact layer 316 (see FIG. 51) of the semiconductor laser device layer 312.

According to the fifteenth embodiment, when the semiconductor laser device layer 312 is grown on the underlayer 352, the semiconductor laser device layer 312 is crystal-grown on the inner side surfaces 353a including the (000-1) planes of the cracks 353 extending in a striped manner in the direction B, while forming the (000-1) planes extending in a [1-100] direction (along arrow C2) to start from the (000-1) planes of the cracks 353, as shown in FIG. 52. Thus, the (000-1) plane of the semiconductor laser device layer 312 is formed as the light-emitting surface 350a of each pair of the cavity facets in the nitride-based semiconductor laser device 350.

According to the fifteenth embodiment, the semiconductor laser device layer 312 is crystal-grown on inner side surfaces 353b opposed to the inner side surfaces 353a of the cracks 353 while forming (1-101) facets 350c extending in a direction inclined at a prescribed angle with respect to the [1-100] direction (along arrow C2). The facet 350c is examples of the “second side surface” and the “crystal growth facet” in the present invention, and the inner side surface 353b is an example of the “second inner side surface of the recess portion” in the present invention. Thus, the facets 350c form obtuse angles with respect to an upper surface (main surface) of the semiconductor laser device layer 312.

A current blocking layer 317, a p-side electrode 318 and an n-side electrode 319 are successively formed through a manufacturing process similar to that of the fourteenth embodiment. As shown in FIG. 53, linear scribing grooves 354 are so formed on positions corresponding to (000-1) semiconductor facets on a back surface of the n-side electrode 319 and positions to be formed with prescribed (0001) planes to extend parallel to the cracks 353 of the n-type GaN substrate 351 by laser scribing or mechanical scribing. In this state, the wafer is cleaved on the position of each scribing groove 354 by applying a load while fulcruming the back surface of the n-type GaN substrate 351 so that a surface (upper surface) of the wafer opens. Thus, the (0001) planes of the semiconductor laser device layer 312 are formed as the light-reflecting surfaces 350b of the nitride-based semiconductor laser device 350. The n-type GaN substrate 351 on a region corresponding to each crack 353 is divided along a cleavage line 950 connecting the crack 353 and the corresponding scribing groove 354. The cracks 353 of the n-type GaN substrate 351 become the step portions 351a formed on lower portions of the light-emitting surfaces 350a after device division, as shown in FIG. 51.

The device is divided along the cavity direction (direction A in FIG. 51) into chips, thereby forming the nitride-based semiconductor laser device 350 by the method of forming the nitride-based semiconductor layer according to the fifteenth embodiment shown in FIG. 51.

In the manufacturing process of the nitride-based semiconductor laser device 350 according to the fifteenth embodiment, as hereinabove described, the underlayer 352 made of AlGaN is formed on the n-type GaN substrate 351, and a lattice constant c₁ of the n-type GaN substrate 351 and a lattice constant c₂ of the underlayer 352 have the relation of c₁>c₂, whereby when the underlayer 352 is formed on the n-type GaN substrate 351, the lattice constant c₂ in the [0001] direction, of the underlayer 352 is smaller than the lattice constant c₁ in the [0001] direction, of the n-type GaN substrate 351 (c₁>c₂), and hence tensile stress is caused inside the underlayer 352 in response to the lattice constant c₁ of the n-type GaN substrate 351. Consequently, when the thickness of the underlayer 352 is at least a prescribed thickness, the underlayer 352 cannot withstand this tensile stress and hence the cracks 353 are formed along the (000-1) planes on the underlayer 352. Thus, the inner side surfaces (inner side surfaces 353a of the cracks 353) having the (000-1) planes which are the basis for forming the light-emitting surfaces 350a ((000-1) planes) of the semiconductor laser device layer 312 on the underlayer 352 in crystal growth can be easily formed in the underlayer 352.

In the manufacturing process of the nitride-based semiconductor laser device 350 according to the fifteenth embodiment, the step of forming the (000-1) planes substantially perpendicular to the main surface having the (1-100) plane of the n-type GaN substrate 351 includes the step of forming the cracks 353 (inner side surfaces 353a including the (000-1) planes) following difference between lattice constants on the underlayer 352, whereby the semiconductor laser device layer 312 having the light-emitting surfaces 350a having the (000-1) planes can be easily formed to start from the inner side surfaces 353a by utilizing the inner side surfaces 353a ((000-1) planes) of the cracks 353 formed in the underlayer 352 when forming the semiconductor laser device layer 312 on the main surface of the n-type GaN substrate 351.

In the manufacturing process of the nitride-based semiconductor laser device 350 according to the fifteenth embodiment, the step of forming the (000-1) planes substantially perpendicular to the main surface of the n-type GaN substrate 351 includes the step of forming the inner side surfaces 353a including the (000-1) planes formed substantially parallel to the (0001) plane substantially perpendicular to the main surface of the n-type GaN substrate 351 on the underlayer 352, whereby the semiconductor laser device layer 312 having the light-emitting surfaces 350a of the (000-1) planes can be easily formed to start from the inner side surfaces 353a having the (000-1) planes formed in the underlayer 352 due to difference between lattice constants when forming the semiconductor laser device layer 312 on the n-type GaN substrate 351. The remaining effects of the fifteenth embodiment are similar to those of the aforementioned fourteenth embodiment.

### Sixteenth Embodiment

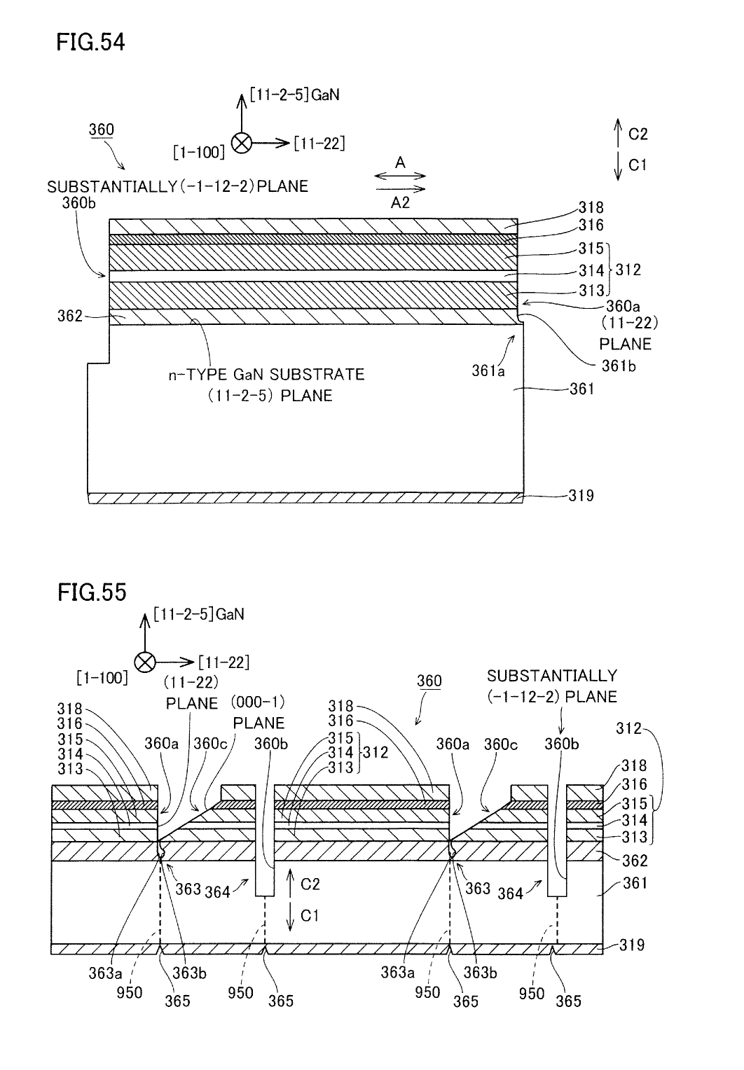

In a nitride-based semiconductor laser device 360 formed by a method of forming a nitride-based semiconductor layer according to a sixteenth embodiment, a case where a semiconductor laser device layer 312 is formed after forming an underlayer 362 on an n-type GaN substrate 361 by employing the n-type GaN substrate 361 having a main surface having a substantially (11-2-5) plane dissimilarly to the aforementioned fifteenth embodiment will be described with reference to FIG. 54. The n-type GaN substrate 361 is an example of the “base substrate” in the present invention.

According to the sixteenth embodiment, the semiconductor laser device layer 312 is formed through the underlayer 362 on the main surface having the substantially (11-2-5) plane of the n-type GaN substrate 361. A step portion 161a of the n-type GaN substrate 361 has a facet 361b having a (11-22) plane substantially perpendicular to the main surface of the n-type GaN substrate 361. As shown in FIG. 54, a light-emitting surface 360a of the semiconductor layer device layer 312 has the (11-22) facet formed when being crystal-grown to start the facet 361b of the n-type GaN substrate 361. A light-reflecting surface 360b of the semiconductor laser device layer 312 has a (−1-12-2) plane which is a facet perpendicular to a [11-22] direction (along arrow A2 in FIG. 54). The light-emitting surface 360a is examples of the “first side surface” and the “crystal growth facet” in the present invention.

The remaining structure of the nitride-based semiconductor laser device 360 formed by the forming method according to the sixteenth embodiment is similar to that of the aforementioned fifteenth embodiment.

A manufacturing process of the nitride-based semiconductor laser device 360 according to the sixteenth embodiment will be now described with reference to FIGS. 54 and 55.

According to the sixteenth embodiment, the underlayer 362 made of AlGaN and having a thickness of about 3 μm to about 4 μm is grown on the n-type GaN substrate 361 through the manufacturing process similar to that of the aforementioned fifteenth embodiment. A lattice constant c₂ of the underlayer 362 is smaller than a lattice constant c₁ of the n-type GaN substrate 361 (c₁>c₂), and hence cracks 363 as shown in FIG. 55 are formed in the underlayer 352 with crystal growth. At this time, difference between c-axial lattice constants of GaN and AlGaN is larger than difference between a-axial lattice constants of GaN and AlGaN, and hence the cracks 363 are formed in a striped manner along a [1-100] direction parallel to a (0001) plane and the (11-2-5) plane of the main surface of the n-type GaN substrate 361.

Thereafter, as shown in FIG. 36, a n-type cladding layer 313, an active layer 314, a p-type cladding layer 315 and a p-type contact layer 316 (see FIG. 54) are successively stacked on the underlayer 362 through the manufacturing process similar to that of the aforementioned fifteenth embodiment, thereby forming the semiconductor laser device layer 312.

According to the sixteenth embodiment, as shown in FIG. 55, when the semiconductor laser device layer 312 is grown on the underlayer 362, the semiconductor laser device layer 312 is crystal-grown on inner side surfaces 363a of the cracks 363 extending in the striped manner in the [1-100] direction, while forming the (11-22) planes extending in a [11-2-5] direction (along arrow C2). Thus, the (11-22) planes of the semiconductor laser device layer 312 are formed as the light-emitting surfaces 360a in the nitride-based semiconductor laser device 360.

According to the sixteenth embodiment, the semiconductor laser device layer 312 is crystal-grown on inner side surfaces 363b opposed to the inner side surfaces 363a of the cracks 363, while forming (000-1) facets 360c extending in a direction inclined at a prescribed angle with respect to the [11-2-5] direction (along arrow C2). The facet 360c is examples of the “second side surface” and the “crystal growth facet” in the present invention, and the crack 363 is an example of the “recess portion” in the present invention. The inner side surfaces 363a and 363b are examples of the “first inner side surface of the recess portion” and the “second inner side surface of the recess portion” in the present invention, respectively. Thus, the facets 360c form obtuse angles with respect to an upper surface (main surface) of the semiconductor laser device layer 312.

As shown in FIG. 55, a current blocking layer 317 and a p-side electrode 318 are formed on the semiconductor laser device layer 312 through the manufacturing process similar to that of the aforementioned fifteenth embodiment. As shown in FIG. 55, a back surface of the n-type GaN substrate 361 is so polished that a thickness of the n-type GaN substrate 361 reaches a thickness of about 100 μm, and an n-side electrode 319 is thereafter formed on the back surface of the n-type GaN substrate 361 by vacuum evaporation to be in contact with the n-type GaN substrate 361.

According to the sixteenth embodiment, as shown in FIG. 55, positions to be formed with prescribed cavity facets are dry-etched in a direction (along arrow C1) reaching the n-type GaN substrate 361 from the surface (upper surface) of the semiconductor laser device layer 312, whereby grooves 364 in which first side surfaces of the semiconductor laser device layer 312 have the flat substantially (−1-12-2) planes are formed. Thus, the substantially (−1-12-2) planes, which are first side surfaces of the grooves 364, are formed as the light-reflecting surfaces 360b in the nitride-based semiconductor laser device 360.

As shown in FIG. 55, linear scribing grooves 365 are so formed on positions corresponding to the (11-22) semiconductor facets on a back surface of the n-side electrode 319 and positions corresponding to the (−1-12-2) semiconductor facets on the back surface of the n-side electrode 319 as to extend parallel (in a direction perpendicular to the plane of FIG. 55) to the grooves 364 of the n-type GaN substrate 361 by laser scribing or mechanical scribing. In this state, the wafer is separated on the position of each scribing groove 365 by applying a load while fulcruming the back surface of the n-type GaN substrate 361 so that a surface (upper surface) of the wafer opens, as shown in FIG. 55. The n-type GaN substrate 361 on a region corresponding to each crack 363 is divided along a cleavage line 950 connecting the crack 363 and the corresponding scribing groove 365. The crack 363 of the n-type GaN substrate 361 becomes the step portion 161a formed on a lower portion of the light-emitting surface 360a after device division, as shown in FIG. 54.

The device is divided along the cavity direction (direction A in FIG. 54) into chips, thereby forming the nitride-based semiconductor laser device 360 according to the sixteenth embodiment shown in FIGS. 19 and 20.

In the manufacturing process of the nitride-based semiconductor laser device 360 according to the sixteenth embodiment, as hereinabove described, the step of forming the semiconductor laser device layer 312 includes the step of the forming the semiconductor laser device layer 312 having the facets 360c on a region opposed to the light-emitting surface 360a having the (11-22) planes by employing the inner side surfaces 363b of the cracks 363 as starting points, whereby when the semiconductor laser device layer 312 is crystal-grown on the n-type GaN substrate 361, a growth rate of forming the facets 360c starting from the inner side surfaces 363b of the cracks 363 is slower than a growth rate of growing the upper surface (main surface of the semiconductor laser device layer 312) of the growth layer, and hence the upper surface (main surface) of the growth layer is grown while maintaining flatness. Thus, flatness of the surface of the semiconductor laser device layer 312 having the active layer 314 can be further improved as compared with surfaces of a growth layer of the semiconductor laser device layer 312 with neither the light-emitting surfaces 360a nor the facets 360c.

In the manufacturing process of the nitride-based semiconductor laser device 360 according to the sixteenth embodiment, the facets 360c have the (000-1) planes, whereby the main surface (upper surface) of the growth layer can be reliably formed to have flatness in forming the (000-1) facets 360c on the n-type GaN substrate 361 as compared with an upper surface (main surface) of a growth layer of the semiconductor laser device layer 312 in forming side surfaces (facets), plain orientations of which are greatly different from those of the (000-1) planes on the n-type GaN substrate 361. A growth rate of the facets 360c is slower than the growth rate of the main surface of the semiconductor laser device layer 312, and hence the facets 360c can be easily formed by crystal growth.

In the manufacturing process of the nitride-based semiconductor laser device 360 according to the sixteenth embodiment, the light-emitting surfaces 360a of the semiconductor laser device layer 312 are formed to be substantially perpendicular to the (11-2-5) plane of the n-type GaN substrate 361, whereby the semiconductor laser device layer 312 (active layer 314) having the cavity facets having the light-emitting surfaces 360a can be easily formed without a cleavage step.

The remaining effects of the manufacturing process of the nitride-based semiconductor laser device 360 according to the sixteenth embodiment are similar to those of the aforementioned fifteenth embodiment.

### Seventeenth Embodiment

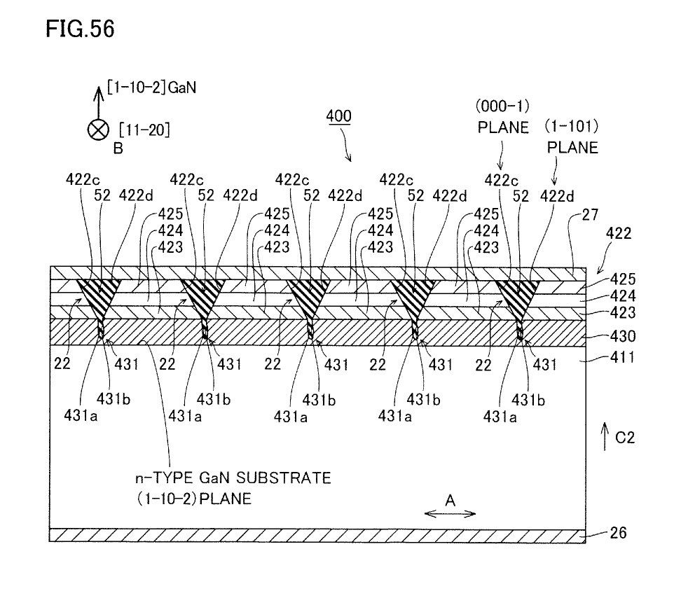

FIG. 56 is a sectional view showing a structure of a light-emitting diode chip formed by a forming method according to a seventeenth embodiment of the present invention. In a light-emitting diode chip 400 formed by the forming method according to the seventeenth embodiment, a case where a light-emitting device layer 422 is formed after forming cracks 431 extending in a striped manner in a [11-20] direction (direction perpendicular to the plane of FIG. 56) of an n-type GaN substrate 411 on an underlayer 430 on a main surface by employing the n-type GaN substrate 411 having the main surface having a (1-10-2) plane will be described with reference to FIG. 56. The n-type GaN substrate 411 is an example of the “base substrate” in the present invention.

In a manufacturing process of the light-emitting diode chip 400 formed by the forming method according to the seventeenth embodiment, the cracks 431 extending in the striped manner along the [11-20] direction (direction perpendicular to the plane of FIG. 56) parallel to a (0001) plane of the underlayer 430 and the (1-10-2) plane of the main surface of the n-type GaN substrate 411 are formed in the underlayer 430 made of Al_{0.05}Ga_{0.95}N due to action similar to the aforementioned second embodiment.

Thereafter, an n-type cladding layer 423, a light-emitting layer 424 consisting of an MQW formed by stacking a well layer of Ga_{0.7}In_{0.3}N having a thickness of about 2 nm and a barrier layer made of Ga_{0.9}In_{0.1}N and a p-type cladding layer 425 are successively stacked on the underlayer 430, thereby forming the light-emitting device layer 422.

At this time, when the light-emitting device layer 422 is grown on the n-type GaN substrate 411, the light-emitting device layer 422 is crystal-grown on inner side surfaces 431a of the cracks 431 extending in the striped manner in the [11-20] direction, while forming (000-1) facets 422c extending in a direction inclined at a prescribed angle with respect to the [1-10-2] direction (along arrow C2) of the n-type GaN substrate 411. Further, the light-emitting device layer 422 is crystal-grown on inner side surfaces 431b opposed to the inner side surfaces 431a of the cracks 431, while forming (1-101) facets 422d extending in a direction inclined at a prescribed angle with respect to the [1-10-2] direction (along arrow C2) of the n-type GaN substrate 411. The facet 422c is examples of the “first side surface” and the “crystal growth facet” in the present invention, and the facet 422d is examples of the “second side surface” and the “crystal growth facet” in the present invention.

The remaining manufacturing process of the seventeenth embodiment is similar to that of the aforementioned second embodiment. Thus, the light-emitting diode chip 400 employing the forming method according to the seventeenth embodiment shown in FIG. 56 is formed. The effects of the manufacturing process of the light-emitting diode chip 400 according to the seventeenth embodiment are similar to those of the aforementioned sixth embodiment.

Although the present invention has been described and illustrated in detail, it is clearly understood that the same is by way of illustration and example only and is not to be taken by way of limitation, the spirit and scope of the present invention being limited only by the terms of the appended claims.

For example, while the example of forming the light-emitting device layer (light-emitting device layer 12, etc.) by the nitride-based semiconductor layer made of AlGaN, InGaN or the like has been shown in the light-emitting diode chip according to each of the aforementioned first to fifth and seventeenth embodiments, the present invention is not restricted to this but the light-emitting device layer may be formed by a wurtzite nitride-based semiconductor layer of AlN, InN, BN, TlN or an alloyed semiconductor of these.

While the example of forming the semiconductor laser device layer by the nitride-based semiconductor device layer made of AlGaN, InGaN or the like has been shown in the semiconductor laser device according to each of the aforementioned sixth to sixteenth embodiments, the present invention is not restricted to this but the semiconductor device layer may be formed by a wurtzite nitride-based semiconductor device layer of AlN, InN, BN, TlN or an alloyed semiconductor of these.

While the example of forming the grooves 21 on the main surface having the a-plane ((11-20) plane) of the n-type GaN substrate and crystal growing the light-emitting device layer 12 has been shown in the light-emitting diode chip according to the aforementioned first embodiment, the present invention is not restricted to this but the light-emitting device layer may be formed after forming the grooves (recess portions) on a main surface perpendicular to a (000±1) plane of the n-type GaN substrate such as an m-plane ((1-100) plane), for example.

While the example of utilizing voluntary formation of the cracks 51 on the underlayer 50 by utilizing difference between the lattice constants of the n-type GaN substrate 81 and the underlayer 50 has been shown in the light-emitting diode chip according to the aforementioned fourth embodiment, the present invention is not restricted to this but cracks, positions of which are controlled by forming skipped shaped scribing cracks on the underlayer on the n-type GaN substrate, may be formed similarly to the aforementioned third embodiment.

While the example of using the GaN substrate as the substrate has been shown in the light-emitting diode chip according to each of the aforementioned first to fifth and seventeenth embodiment and the nitride-based semiconductor laser device according to each of the aforementioned sixth to sixteenth embodiments, the present invention is not restricted to this but an r-plane ((1-102) plane) sapphire substrate formed by previously growing a nitride-based semiconductor having a main surface having an a-plane ((11-20) plane) or an a-plane SiC substrate or an m-plane SiC substrate formed by previously growing a nitride-based semiconductor having a main surface having an a-plane or an m-plane ((1-100) plane) may be used, for example. Alternatively, a LiAlO₂ or LiGaO₂ substrate formed by previously growing the aforementioned nonpolar nitride-based semiconductor may be employed.

While the example of employing the n-type GaN substrate as the base substrate and forming the underlayer made of AlGaN on the n-type GaN substrate has been shown in the light-emitting diode chip according to each of the aforementioned second to fourth embodiments and the nitride-based semiconductor laser device according to each of the aforementioned sixth to tenth, thirteenth, fifteenth and sixteenth embodiments, the present invention is not restricted to this but an InGaN substrate may be employed as the base substrate, and the underlayer made of GaN or AlGaN may be formed on the InGaN substrate.

While the example of utilizing voluntary formation of the cracks on the underlayer by utilizing difference between the lattice constants of the n-type GaN substrate and the underlayer has been shown in the light-emitting diode chip according to each of the aforementioned second to fourth embodiments and the nitride-based semiconductor laser device according to each of the aforementioned sixth to eighth embodiments, the present invention is not restricted to this but scribing cracks may be formed only in both ends (regions corresponding to ends of the n-type GaN substrate in the direction B) of the underlayer in the direction B. Also according to this structure, cracks extending in the direction B can be introduced starting from the scribing cracks on the both ends.

While the example of forming the scribing cracks 70 for crack guide on the underlayer 50 in a skipped manner (at intervals of about 50 μm) has been shown in the light-emitting diode chip according to the aforementioned third embodiment, the present invention is not restricted to this but the scribing cracks may be formed in the both ends (regions corresponding to the ends of the n-type GaN substrate 61) in the direction B (see FIG. 12) of the underlayer 50. Also according to this structure, cracks extending in the direction B can be introduced starting from the scribing cracks on the both ends.

While the example of forming the semiconductor laser device layer 12 on the main surface having the m-plane ((1-100) plane) of the n-type GaN substrate has been shown in the surface emission type nitride-based semiconductor laser device according to the aforementioned seventh embodiment, the present invention is not restricted to this but a plane perpendicular to a (000±1) plane of the n-type GaN substrate such as an a-plane ((11-20) plane) may be a maim surface in forming the semiconductor laser device layer, for example.

While the example of voluntarily forming the cracks on the underlayer by utilizing difference between the lattice constants of the n-type GaN substrate and the underlayer has been shown in the surface emission type nitride-based semiconductor laser device according to each of the aforementioned sixth to eighth, fifteenth and sixteenth embodiments, the present invention is not restricted to this but cracks, positions of which are controlled by forming skipped shaped scribing cracks on the underlayer on the n-type GaN substrate, may be formed similarly to the aforementioned modification of the thirteenth embodiment.

While the example of employing the (000-1) plane of the two facets formed in forming the semiconductor laser device layer 112 as the reflection surface (180c) has been shown in the surface emission type nitride-based semiconductor laser device according to the aforementioned ninth embodiment, the present invention is not restricted to this but the surface emission type nitride-based semiconductor laser device may be formed by employing the (11-22) facet of the semiconductor laser device layer 112 as the reflection surface similarly to the aforementioned modification of the eighth embodiment.

While the example where the (1-101) facet of the semiconductor laser device layer 112 is the light-emitting surface 240a and the (−110-1) facet is the light-reflecting surface 240b has been shown in the nitride-based semiconductor laser device according to the aforementioned twelfth embodiment, the present invention is not restricted to this but the (−110-1) facet may be the light-emitting surface and the (1-101) facet may be the light-reflecting surface.

While the example where the (11-22) facet of the semiconductor laser device layer is the light-emitting surface 240a and the (−1-12-2) facet is the light-reflecting surface has been shown in the nitride-based semiconductor laser device according to each of the aforementioned thirteenth and sixteenth embodiments, the present invention is not restricted to this but the (−1-12-2) facet may be the light-emitting surface and the (11-22) facet may be the light-reflecting surface.

While the example of forming the scribing cracks 280 for crack guide on the underlayer 140 in a skipped manner has been shown in the nitride-based semiconductor laser device according to the aforementioned modification of the thirteenth embodiment, the present invention is not restricted to this but the scribing cracks may be formed in the both ends (regions corresponding to the ends of the n-type GaN substrate 261) in the direction B (see FIG. 32) of the underlayer 140. Also according to this structure, cracks extending in the direction B can be introduced starting from the scribing cracks on the both ends.

While the example of forming the semiconductor laser device layer on the main surface having the m-plane of the n-type GaN substrate has been shown in the manufacturing process of the nitride-based semiconductor laser device according to each of the aforementioned fourteenth and fifteenth embodiments, the present invention is not restricted to this but a plane perpendicular to a (000±1) plane of the n-type GaN substrate such as an a-plane ((11-20) plane) may be a maim surface in forming the semiconductor laser device layer, for example.

While the example where the (000-1) facet of the semiconductor laser device layer 312 is the light-emitting surface and the (0001) facet is the light-reflecting surface has been shown in the manufacturing process of the nitride-based semiconductor laser device according to each of the aforementioned fourteenth and fifteenth embodiments, the present invention is not restricted to this but the (0001) facet may be the light-emitting surface and the (000-1) facet may be the light-reflecting surface.

While the example of utilizing voluntary formation of the cracks on the underlayer by utilizing difference between the lattice constants of the n-type GaN substrate and the underlayer has been shown in the manufacturing process of the nitride-based semiconductor laser device according to each of the aforementioned fifteenth and sixteenth embodiments, the present invention is not restricted to this but scribing cracks may be formed only in both ends (regions corresponding to ends of the n-type GaN substrate 351 in the [11-20] direction) of the underlayer 352 (see FIG. 52) in the [11-20] direction. Also according to this structure, cracks extending in the [11-20] direction can be introduced starting from the scribing cracks on the both ends.

While the example of forming the ridge guided semiconductor laser where the upper cladding layer having the ridge is formed on the planar active layer and the dielectric blocking layer is formed on the side surfaces of the ridge has been shown in the semiconductor laser device according to each of the aforementioned sixth to sixteenth embodiments, the present invention is not restricted to this but a ridge guided semiconductor laser having a blocking layer of a semiconductor, a semiconductor laser of an embedded heterostructure (BH) or a gain guided semiconductor laser prepared by forming a current blocking layer having an striped opening on a planar upper cladding layer may be formed.

1. A nitride-based semiconductor light-emitting diode comprising:
a substrate formed with a recess portion on a main surface; and
a nitride-based semiconductor layer having a light-emitting layer on said main surface and including a first side surface having a (000-1) plane formed to start from a first inner side surface of said recess portion and a second side surface formed at a region opposite to said first side surface with said light-emitting layer therebetween to start from a second inner side surface of said recess portion on said main surface.

2. The nitride-based semiconductor light-emitting diode according to claim 1, wherein
said first inner side surface includes the (000-1) plane.

3. The nitride-based semiconductor light-emitting diode according to claim 1, wherein
said first and second side surfaces have crystal growth facets of said nitride-based semiconductor layer.

4. The nitride-based semiconductor light-emitting diode according claim 1, wherein
said second side surface has a {A+B, A, −2A−B, 2A+B} plane (A and B satisfy A≧0 and B≧0, and at least either one of A and B is a nonzero integer).

5. The nitride-based semiconductor light-emitting diode according claim 1, wherein
said substrate is formed by a nitride-based semiconductor.

6. The nitride-based semiconductor light-emitting diode according claim 1, wherein
at least either said first or second side surface forms an obtuse angle with respect to said main surface.

7. The nitride-based semiconductor light-emitting diode according claim 1, wherein
said substrate includes a base substrate and an underlayer made of AlGaN formed on said base substrate,
C₁ and C₂ satisfy relation of C₁>C₂, where lattice constants of said base substrate and said underlayer are C₁ and C₂ respectively, and
said first and second side surfaces are formed to start from respective inner side surfaces, formed to extend substantially parallel to a (0001) plane of said underlayer and said main surface, of a crack.

8. A nitride-based semiconductor laser device comprising:
a nitride-based semiconductor device layer formed on a main surface of a substrate and having a light-emitting layer;
a first cavity facet formed at an end including said light-emitting layer of said nitride-based semiconductor device layer; and
a reflection surface formed at a region opposed to said first cavity facet, having a (000-1) plane or a {A+B, A, −2A−B, 2A+B} plane (A and B satisfy A≧0 and B≧0, and at least either one of A and B is a nonzero integer) extending to be inclined at a prescribed angle with respect to at least said main surface.

9. The nitride-based semiconductor laser device according to claim 8, wherein said substrate has a recess portion formed on said main surface, and
said reflection surface has a crystal growth facet of said nitride-based semiconductor device layer formed to start from an inner side surface of said recess portion.

10. The nitride-based semiconductor laser device according to claim 8, further comprising a second cavity facet formed at an end opposite to said first cavity facet and extending in a direction substantially perpendicular to said main surface.

11. The nitride-based semiconductor laser device according claim 8, wherein
said substrate is formed by a nitride-based semiconductor.

12. The nitride-based semiconductor laser device according claim 8, wherein
a laser beam emitted from said first cavity facet is introduced into an optical sensor for a monitor of said laser beam by changing an emission direction to a direction intersecting with an emission direction of said laser beam from said light-emitting layer, by said reflection surface.

13. The nitride-based semiconductor laser device according claim 8, being a surface emission type laser, wherein
an emission direction of a laser beam emitted from said first cavity facet is changed to a direction intersecting with an emission direction of said laser beam from said light-emitting layer, by said reflection surface.

14. A method of forming a nitride-based semiconductor layer, comprising steps of:
forming a recess portion on a main surface of a substrate; and
forming a nitride-based semiconductor layer having a first side surface having a (000-1) plane starting from a first inner side surface of said recess portion on said main surface.

15. The method of forming a nitride-based semiconductor layer according to claim 14, wherein
said step of forming said nitride-based semiconductor layer includes a step of forming said nitride-based semiconductor layer having a second side surface starting from a second inner side surface of said recess portion on a region opposed to said first side surface.

16. The method of forming a nitride-based semiconductor layer according to claim 14, wherein
said first inner side surface of said recess portion includes the (000-1) plane.

17. The method of forming a nitride-based semiconductor layer according to claim 15, wherein
said first and second side surfaces have crystal growth facets of said nitride-based semiconductor layer.

18. The method of forming a nitride-based semiconductor layer according to claim 15, wherein
said second side surface has a {A+B, A, −2A−B, 2A+B} plane (A and B satisfy A≧0 and B≧0, and at least either one of A and B is a nonzero integer).

19. The method of forming a nitride-based semiconductor layer according to claim 14, wherein
said substrate is formed by a nitride-based semiconductor.

20. The method of forming a nitride-based semiconductor layer according to claim 15, wherein
either said first or second side surface is substantially perpendicular to said main surface.

21. The method of forming a nitride-based semiconductor layer according to claim 15, wherein
at least either said first or second side surface forms an obtuse angle with respect to a main surface of said nitride-based semiconductor layer.

22. The method of forming a nitride-based semiconductor layer according to claim 14, wherein
said substrate includes a base substrate and an underlayer made of AlGaN formed on said base substrate, and
C₁ and C₂ satisfy relation of C₁>C₂, where lattice constants of said base substrate and said underlayer are C₁ and C₂ respectively.

23. A method of manufacturing a nitride-based semiconductor light-emitting diode, comprising steps of:
forming recess portions on a main surface of a substrate; and
forming a nitride-based semiconductor layer on said main surface by having a light-emitting layer on said main surface and by including first side surfaces having (000-1) planes starting from first inner side surfaces of said recess portions and second side surfaces starting from second inner side surfaces of said recess portions on regions opposed to said first side surfaces on said main surface.

24. A method of manufacturing a nitride-based semiconductor laser device, comprising steps of:
forming a first cavity facet on an end of a nitride-based semiconductor device layer formed on a main surface of a substrate and having a light-emitting layer;
forming a reflection surface on a region opposed to said first cavity facet, by a (000-1) plane or a {A+B, A, −2A−B, 2A+B} plane (A and B satisfy A≧0 and B≧0, and at least either one of A and B is a nonzero integer) extending to be inclined at a prescribed angle with respect to said main surface; and
forming a second cavity facet extending in a direction substantially perpendicular to said main surface on an end opposite to said first cavity facet.

25. The method of forming a nitride-based semiconductor laser device according to claim 24, wherein
said step of forming said first cavity facet and said step of forming said second cavity facet include a step of forming at least either said first cavity facet or said second cavity facet by crystal growth of said nitride-based semiconductor device layer and a step of forming at least either said second cavity facet or said first cavity facet by etching.
